(19) United States
(12) Patent Application Publication
(10) Pub. No.: US 2005/0202173 A1
(43) Pub. Date: Sep. 15, 2005

(54) Diamond synthesis

(76) Inventor: Randell L. Mills, Cranbury, NJ (US)

Correspondence Address: MANELLI DENISON & SELTER, 2000 M STREET NW SUITE 700, WASHINGTON, DC, 20036-3307, US

(21) Appl. No.: 10/513,026

(22) PCT Filed: Apr. 30, 2003
(86) PCT No.: PCT/US03/13412

§ 371 Date: Nov. 1, 2004

Related U.S. Application Data
(60) Provisional application No. 60/376,546, filed on May 1, 2002.
(60) Provisional application No. 60/390,439, filed on Jun. 24, 2002.
(60) Provisional application No. 60/399,739, filed on Aug. 1, 2002.
(60) Provisional application No. 60/462,705, filed on Apr. 15, 2003.

(51) Int. Cl. C23C 16/00; H05H 1/24

(52) U.S. Cl. 427/249.7; 427/569; 427/249.8; 118/723 R

(57) ABSTRACT

The present invention relates to a cell, system, and methods to form diamond from carbon in a plasma formed or assisted by the catalysis of atomic hydrogen to lower energy states.

This application claims priority to U.S. Ser. Nos. 60/376,546, filed May 1, 2002; 60/390,439, filed Jun. 24, 2002; 60/399,739, filed Aug. 1, 2002; and 60/462,705 filed Apr. 15, 2003, the complete disclosures of which are incorporated herein by reference.

### 1. FIELD OF THE INVENTION

This invention relates to a plasma cell diamond reactor and method of making diamond. The plasma cell comprises a cell for the catalysis of atomic hydrogen to form novel hydrogen species and/or compositions of matter comprising new forms of hydrogen. The reaction may be maintained by a microwave or glow discharge plasma of hydrogen and a source of catalyst. The catalysis of hydrogen may cause the plasma to become highly energetic to facilitate diamond synthesis.

### 2. BACKGROUND OF THE INVENTION

2.1 Hydrinos

A hydrogen atom having a binding energy given by

$$Binding Energy = \frac{13.6 eV}{{( \frac{1}{p} )}^{2}} \qquad ( 1 )$$

where p is an integer greater than 1, preferably from 2 to 200, is disclosed in R. Mills, The Grand Unified Theory of Classical Quantum Mechanics, January 2000 Edition, BlackLight Power, Inc., Cranbury, N.J., Distributed by Amazon.com (“'00 Mills GUT”), provided by BlackLight Power, Inc., 493 Old Trenton Road, Cranbury, N.J., 08512; R. Mills, The Grand Unified Theory of Classical Quantum Mechanics, September 2001 Edition, BlackLight Power, Inc., Cranbury, N.J., Distributed by Amazon.com (“'01 Mills GUT”), provided by BlackLight Power, Inc., 493 Old Trenton Road, Cranbury, N.J., 08512 R. Mills, The Grand Unified Theory of Classical Quantum Mechanics, January 2003 Edition posted at www.blacklightpower.com; R. Mills, J. Sankar, A. Voigt, J. He, P. Ray, B. Dhandapani, “Role of Atomic Hydrogen Density and Energy in Low Power CVD Synthesis of Diamond Films”, JACS, in preparation; R. Mills, B. Dhandapani, M. Nansteel, J. He, P. Ray, “Liquid-Nitrogen-Condensable Molecular Hydrogen Gas Isolated from a Catalytic Plasma Reaction”, J. Phys. Chem. B, submitted; R. L. Mills, P. Ray, J. He, B. Dhandapani, M. Nansteel, “Novel Spectral Series from Helium-Hydrogen Evenson Microwave Cavity Plasmas that Matched Fractional-Principal-Quantum-Energy-Level Atomic and Molecular Hydrogen”, Plasma Devices and Operations, submitted; R. L. Mills, P. Ray, R. M. Mayo, Highly Pumped Inverted Balmer and Lyman Populations, New Journal of Physics, submitted; R. L. Mills, P. Ray, J. Dong, M. Nansteel, R. M. Mayo, B. Dhandapani, X. Chen, “Comparison of Balmer α Line Broadening and Power Balances of Helium-Hydrogen Plasma Sources”, International Journal of Energy Research, submitted; R. Mills, P. Ray, M. Nansteel, R. M. Mayo, “Comparison of Water-Plasma Sources of Stationary Inverted Balmer and Lyman Populations for a CW HI Laser”, J. Appl. Spectroscopy, in preparation; R Mills, J. Sankar, A. Voigt, J. He, P. Ray, B. Dhandapani, “Synthesis and Characterization of Diamond Films from MPCVD of an Energetic Argon-Hydrogen Plasma and Methane”, J. of Materials Research, to be submitted; R. Mills, P. Ray, B. Dhandapani, W. Good, P. Jansson, M. Nansteel, J. He, A. Voigt, “Spectroscopic and NMR Identification of Novel Hydride Ions in Fractional Quantum Energy States Formed by an Exothermic Reaction of Atomic Hydrogen with Certain Catalysts”, J. Phys. Chem. A, submitted; R. L. Mills, The Fallacy of Feynman's Argument on the Stability of the Hydrogen Atom According to Quantum Mechanics, Am. J. Phys., submitted; R. Mills, J. He, B. Dhandapani, P. Ray, “Comparison of Catalysts and Microwave Plasma Sources of Vibrational Spectral Emission of Fractional-Rydberg-State Hydrogen Molecular Ion”, Canadian Journal of Physics, submitted; R. L. Mills, P. Ray, J. Dong, M. Nansteel, B. Dhandapani, J. He, “Vibrational Spectral Emission of Fractional-Principal-Quantum-Energy-Level Molecular Hydrogen”, Bulletin of the Chemical Society of Japan, submitted; J. Phillips, R. L. Mills, X. Chen, “Water Bath Calorimetric Study of Excess Heat in ‘Resonance Transfer’ Plasmas”, Journal of Applied Physics, submitted; R. L. Mills, P. Ray, B. Dhandapani, X. Chen, “Comparison of Catalysts and Microwave Plasma Sources of Spectral Emission of Fractional-Principal-Quantum-Energy-Level Atomic and Molecular Hydrogen”, Journal of Applied Spectroscopy, submitted; R. L. Mills, B. Dhandapani, M. Nansteel, J. He, P. Ray, “Novel Liquid-Nitrogen-Condensable Molecular Hydrogen Gas”, Acta Physica Polonica A, submitted; R. L. Mills, P. C. Ray, R. M. Mayo, M. Nansteel, B. Dhandapani, J. Phillips, “Spectroscopic Study of Unique Line Broadening and Inversion in Low Pressure Microwave Generated Water Plasmas”, Physics of Plasmas, submitted; R. L. Mills, P. Ray, B. Dhandapani, J. He, “Energetic Helium-Hydrogen Plasma Reaction”, AIAA Journal, submitted; R. L. Mills, M. Nansteel, P. C. Ray, “Bright Hydrogen-Light and Power Source due to a Resonant Energy Transfer with Strontium and Argon Ions”, Vacuum, submitted; R. L. Mills, P. Ray, B. Dhandapani, J. Dong, X. Chen, “Power Source Based on Helium-Plasma Catalysis of Atomic Hydrogen to Fractional Rydberg States”, Contributions to Plasma Physics, submitted; R. Mills, J. He, A. Echezuria, B Dhandapani, P. Ray, “Comparison of Catalysts and Plasma Sources of Vibrational Spectral Emission of Fractional-Rydberg-State Hydrogen Molecular Ion”, European Journal of Physics D, submitted; R. L. Mills, J. Sankar, A. Voigt, J. He, B. Dhandapani, “Spectroscopic Characterization of the Atomic Hydrogen Energies and Densities and Carbon Species During Helium-Hydrogen-Methane Plasma CVD Synthesis of Diamond Films”, Chemistry of Materials, Vol. 15, (2003), pp. 1313-1321; R. Mills, P. Ray, R. M. Mayo, “Stationary Inverted Balmer and Lyman Populations for a CW HI Water-Plasma Laser”, IEEE Transactions on Plasma Science, submitted; R. L. Mills, P. Ray, B. Dhandapani, J. He, “Extreme Ultraviolet Spectroscopy of Helium-Hydrogen Plasma”, J. Phys. B, submitted; R. L. Mills, P. Ray, “Spectroscopic Evidence for a Water-Plasma Laser”, Europhysics Letters, submitted; R. Mills, P. Ray, R. M. Mayo, “Spectroscopic Evidence for CW H I Lasing in a Water-Plasma”, J. of Applied Physics, submitted; R. L. Mills, J. Sankar, A. Voigt, J. He, B. Dhandapani, “Low Power MPCVD of Diamond Films on Silicon Substrates”, Journal of Vacuum Science & Technology A, submitted; R. L. Mills, X. Chen, P. Ray, J. He, B. Dhandapani, “Plasma Power Source Based on a Catalytic Reaction of Atomic Hydrogen Measured by Water Bath Calorimetry”, Thermochimica Acta, submitted; R. L. Mills, A. Voigt, B. Dhandapani, 3; He, “Synthesis and Spectroscopic Identification of Lithium Chloro Hydride”, Materials Characterization, submitted; R. L. Mills, B. Dhandapani, J. He, “Highly Stable Amorphous Silicon Hydride”, Solar Energy Materials & Solar Cells, in press; R. L. Mills, J. Sankar, A. Voigt, J. He, B. Dhandapani, “Synthesis of HDLC Films from Solid Carbon”, Thin Solid Films, submitted; R. Mills, P. Ray, R. M. Mayo, “The Potential for a Hydrogen Water-Plasma Laser”, Applied Physics Letters, Vol. 82, No. 11, (2003), pp. 1679-1681; R. L. Mills, “Classical Quantum Mechanics”, Physics Essays, submitted; R. L. Mills, P. Ray, “Spectroscopic Characterization of Stationary Inverted Lyman Populations and Free-Free and Bound-Free Emission of Lower-Energy State Hydride Ion Formed by a Catalytic Reaction of Atomic Hydrogen and Certain Group I Catalysts”, Journal of Quantitative Spectroscopy and Radiative Transfer, in press; R. M. Mayo, R. Mills, “Direct Plasmadynamic Conversion of Plasma Thermal Power to Electricity for Microdistributed Power Applications”, 40th Annual Power Sources Conference, Cherry Hill, N.J., Jun. 10-13, (2002), pp. 1-4; R. Mills, P. Ray, R. M. Mayo, “Chemically-Generated Stationary Inverted Lyman Population for a CW Ea Laser”, European J of Phys. D, submitted; R. L. Mills, P. Ray, “Stationary Inverted Lyman Population Formed from Incandescently Heated Hydrogen Gas with Certain Catalysts”, J. Phys. D, Applied Physics, submitted; RP Mills, “A Maxwellian Approach to Quantum Mechanics Explains the Nature of Free Electrons in Superfluid Helium”, Foundations of Science, submitted; R. Mills and M. Nansteel, P. Ray, “Bright Hydrogen-Light Source due to a Resonant Energy Transfer with Strontium and Argon Ions”, New Journal of Physics, Vol. 4, (2002), pp. 70.1-70.28; R Mills, P. Ray, R. M. Mayo, “CW HI Laser Based on a Stationary Inverted Lyman Population Formed from Incandescently Heated Hydrogen Gas with Certain Group I Catalysts”, IEEE Transactions on Plasma Science, in press; R. L. Mills, P. Ray, J. Dong, M. Nansteel, B. Dhandapani, J. He, “Spectral Emission of Fractional-Principal-Quantum-Energy-Level Atomic and Molecular Hydrogen”, Vibrational Spectroscopy, (2003), Vol. 31, No. 2, pp. 195-213; R. L. Mills, P. Ray, E. Dayalan, B. Dhandapani, J. He, “Comparison of Excessive Balmer α Line Broadening of Inductively and Capacitively Coupled RF, Microwave, and Glow Discharge Hydrogen Plasmas with Certain Catalysts”, IEEE Transactions on Plasma Science, June, (2003); R. M. Mayo, R. Mills, M. Nansteel, “Direct Plasmadynamic Conversion of Plasma Thermal Power to Electricity”, IEEE Transactions on Plasma Science, October, (2002), Vol. 30, No. 5, pp. 2066-2073; H. Conrads, R. Mills, Th. Wrubel, “Emission in the Deep Vacuum Ultraviolet from a Plasma Formed by Incandescently Heating Hydrogen Gas with Trace Amounts of Potassium Carbonate”, Plasma Sources Science and Technology, in press; R. L. Mills, P. Ray, “Stationary Inverted Lyman Population and a Very Stable Novel Hydride Formed by a Catalytic Reaction of Atomic Hydrogen and Certain Catalysts”, International Journal of Engineering Science, submitted; R. L. Mills, J. He, P. Ray, B. Dhandapani, X. Chen, “Synthesis and Characterization of a Highly Stable Amorphous Silicon Hydride as the Product of a Catalytic Helium-Hydrogen Plasma Reaction”, Int. J. Hydrogen Energy, in press; R. L. Mills, A. Voigt, B. Dhandapani, J. He, “Synthesis and Characterization of Lithium Chloro Hydride”, Int. J. Hydrogen Energy, submitted; R. L. Mills, P. Ray, “Substantial Changes in the Characteristics of a Microwave Plasma Due to Combining Argon and Hydrogen”, New Journal of Physics, www.njp.org, Vol. 4, (2002), pp. 22.1-22.17; R. L. Mills, P. Ray, “A Comprehensive Study of Spectra of the Bound-Free Hyperfine Levels of Novel Hydride Ion H⁻(½), Hydrogen, Nitrogen, and Air”, Int. J. Hydrogen Energy, (2003), Vol. 28, No. 8, pp. 825-871; R. L. Mills, E. Dayalan, “Novel Alkali and Alkaline Earth Hydrides for High Voltage and High Energy Density Batteries”, Proceedings of the 17^{th} Annual Battery Conference on Applications and Advances, California State University, Long Beach, Calif., (Jan. 15-18, 2002), pp. 1-6; R. M. Mayo, R. Mills, M. Nansteel, “On the Potential of Direct and MHD Conversion of Power from a Novel Plasma Source to Electricity for Microdistributed Power Applications”, IEEE Transactions on Plasma Science, August, (2002), Vol. 30, No. 4, pp. 1568-1578; R. Mills, P. C. Ray, R. M. Mayo, M. Nansteel, W. Good, P. Jansson, B. Dhandapani, J. He, “Stationary Inverted Lyman Populations and Free-Free and Bound-Free Emission of Lower-Energy State Hydride Ion Formed by an Exothermic Catalytic Reaction of Atomic Hydrogen and Certain Group I Catalysts”, European Physical Journal-Applied Physics, submitted; R. Mills, E. Dayalan, P. Ray, B. Dhandapani, J. He, “Highly Stable Novel Inorganic Hydrides from Aqueous Electrolysis and Plasma Electrolysis”, Electrochimica Acta, Vol. 47, No. 24, (2002), pp. 3909-3926; R. L. Mills, P. Ray, B. Dhandapani, R. M. Mayo, J. He, “Comparison of Excessive Balmer α Line Broadening of Glow Discharge and Microwave Hydrogen Plasmas with Certain Catalysts”, J. of Applied Physics, (2002), Vol. 92, No. 12, pp. 7008-7022; R. L. Mills, P. Ray, B. Dhandapani, J. He, “Emission Spectroscopic Identification of Fractional Rydberg States of Atomic Hydrogen Formed by a Catalytic Helium-Hydrogen Plasma Reaction”, Vacuum, submitted; R. L. Mills, P. Ray, B. Dhandapani, M. Nansteel, X. Chen, J. He, “New Power Source from Fractional Rydberg States of Atomic Hydrogen”, Optics Communications, submitted; R. L. Mills, P. Ray, B. Dhandapani, M. Nansteel, X. Chen, J. He, “Spectroscopic Identification of Transitions of Fractional Rydberg States of Atomic Hydrogen”, J. of Quantitative Spectroscopy and Radiative Transfer, in press; R. L. Mills, P. Ray, B. Dhandapani, M. Nansteel, X. Chen, J. He, “New Power Source from Fractional Quantum Energy Levels of Atomic Hydrogen that Surpasses Internal Combustion”, J Mol. Struct., Vol. 643, No. 1-3, (2002), pp. 43-54; R. L. Mills, P. Ray, “Spectroscopic Identification of a Novel Catalytic Reaction of Rubidium Ion with Atomic Hydrogen and the Hydride Ion Product”, Int. J. Hydrogen Energy, Vol. 27, No. 9, (2002), pp. 927-935; R. Mills, J. Dong, W. Good, P. Ray, J. He, B. Dhandapani, “Measurement of Energy Balances of Noble Gas-Hydrogen Discharge Plasmas Using Calvet Calorimetry”, Int. J. Hydrogen Energy, Vol. 27, No. 9, (2002), pp. 967-978; R. L. Mills, A. Voigt, P. Ray, M. Nansteel, B. Dhandapani, “Measurement of Hydrogen Balmer Line Broadening and Thermal Power Balances of Noble Gas-Hydrogen Discharge Plasmas”, Int. J. Hydrogen Energy, Vol. 27, No. 6, (2002), pp. 671-685; R. Mills, P. Ray, “Vibrational Spectral Emission of Fractional-Principal-Quantum-Energy-Level Hydrogen Molecular Ion”, Int. J. Hydrogen Energy, Vol. 27, No. 5, (2002), pp. 533-564; R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, (2002), Vol. 27, No. 3, pp. 301-322; R. Mills, P. Ray, “Spectroscopic Identification of a Novel Catalytic Reaction of Potassium and Atomic Hydrogen and the Hydride Ion Product”, Int. J. Hydrogen Energy, Vol. 27, No. 2, (2002), pp. 183-192; R. Mills, “BlackLight Power Technology-A New Clean Hydrogen Energy Source with the Potential for Direct Conversion to Electricity”, Proceedings of the National Hydrogen Association, 12 th Annual U.S. Hydrogen Meeting and Exposition, Hydrogen: The Common Thread, The Washington Hilton and Towers, Washington DC, (Mar. 6-8, 2001), pp. 671-697; R. Mills, W. Good, A. Voigt, Jinquan Dong, “Minimum Heat of Formation of Potassium Iodo Hydride”, Int. J. Hydrogen Energy, Vol. 26, No. 11, (2001), pp. 1199-1208; R. Mills, “Spectroscopic Identification of a Novel Catalytic Reaction of Atomic Hydrogen and the Hydride Ion Product”, Int. J. Hydrogen Energy, Vol. 26, No. 10, (2001), pp. 1041-1058; R. Mills, N. Greenig, S. Hicks, “Optically Measured Power Balances of Glow Discharges of Mixtures of Argon, Hydrogen, and Potassium, Rubidium, Cesium, or Strontium Vapor”, Int. J. Hydrogen Energy, Vol. 27, No. 6, (2002), pp. 651-670; R. Mills, “The Grand Unified Theory of Classical Quantum Mechanics”, Global Foundation, Inc. Orbis Scientiae entitled The Role of Attractive and Repulsive Gravitational Forces in Cosmic Acceleration of Particles The Origin of the Cosmic Gamma Ray Bursts, (29th Conference on High Energy Physics and Cosmology Since 1964) Dr. Behram N. Kursunoglu, Chairman, Dec. 14-17, 2000, Lago Mar Resort, Fort Lauderdale, Fla., Kluwer Academic/Plenum Publishers, New York, pp. 243-258; R. Mills, “The Grand Unified Theory of Classical Quantum Mechanics”, Int. J. Hydrogen Energy, Vol. 27, No. 5, (2002), pp. 565-590; R. Mills and M. Nansteel, P. Ray, “Argon-Hydrogen-Strontium Discharge Light Source”, IEEE Transactions on Plasma Science, Vol. 30, No. 2, (2002), pp. 639-653; R. Mills, B. Dhandapani, M. Nansteel, J. He, A. Voigt, “Identification of Compounds Containing Novel Hydride Ions by Nuclear Magnetic Resonance Spectroscopy”, Int. J. Hydrogen Energy, Vol. 26, No. 9, (2001), pp. 965-979; R. Mills, “BlackLight Power Technology-A New Clean Energy Source with the Potential for Direct Conversion to Electricity”, Global Foundation International Conference on “Global Warming and Energy Policy”, Dr. Behram N. Kursunoglu, Chairman, Fort Lauderdale, Fla., Nov. 26-28, 2000, Kluwer Academic/Plenum Publishers, New York, pp. 187-202; R. Mills, “The Nature of Free Electrons in Superfluid Helium—a Test of Quantum Mechanics and a Basis to Review its Foundations and Make a Comparison to Classical Theory”, Int. J. Hydrogen Energy, Vol. 26, No. 10, (2001), pp. 1059-1096; R. Mills, M. Nansteel, and Y. Lu, “Excessively Bright Hydrogen-Strontium Plasma Light Source Due to Energy Resonance of Strontium with Hydrogen”, J. of Plasma Physics, Vol. 69, No. 2, (2003); R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943; R. Mills, “Observation of Extreme Ultraviolet Emission from Hydrogen-KI Plasmas Produced by a Hollow Cathode Discharge”, Int. J. Hydrogen Energy, Vol. 26, No. 6, (2001), pp. 579-592; R. Mills, “Temporal Behavior of Light-Emission in the Visible Spectral Range from a Ti-K2CO3-H-Cell”, Int. J. Hydrogen Energy, Vol. 26, No. 4, (2001), pp. 327-332; R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, Vol. 26, No. 7, July, (2001), pp. 749-762; R. Mills, M. Nansteel, and Y. Lu, “Observation of Extreme Ultraviolet Hydrogen Emission from Incandescently Heated Hydrogen Gas with Strontium that Produced an Anomalous Optically Measured Power Balance”, Int. J. Hydrogen Energy, Vol. 26, No. 4, (2001), pp. 309-326; R. Mills, B. Dhandapani, N. Greenig, J. He, “Synthesis and Characterization of Potassium lodo Hydride”, Int. J. of Hydrogen Energy, Vol. 25, Issue 12, December, (2000), pp. 1185-1203; R. Mills, “Novel Inorganic Hydride”, Int. J. of Hydrogen Energy, Vol. 25, (2000), pp. 669-683; R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367; R. Mills, “Highly Stable Novel Inorganic Hydrides”, Journal of New Materials for Electrochemical Systems, in press; R. Mills, “Novel Hydrogen Compounds from a Potassium Carbonate Electrolytic Cell”, Fusion Technology, Vol. 37, No. 2, March, (2000), pp. 157-182; R. Mills, “The Hydrogen Atom Revisited”, Int. J. of Hydrogen Energy, Vol. 25, Issue 12, December, (2000), pp. 1171-1183; Mills, R., Good, W., “Fractional Quantum Energy Levels of Hydrogen”, Fusion Technology, Vol. 28, No. 4, November, (1995), pp. 1697-1719; Mills, R., Good, W., Shaubach, R., “Dihydrino Molecule Identification”, Fusion Technology, Vol. 25, 103 (1994); R. Mills and S. Kneizys, Fusion Technol. Vol. 20, 65 (1991); V. Noninski, Fusion Technol., Vol. 21, 163 (1992); Niedra, J., Meyers, I., Fralick, G. C., and Baldwin, R., “Replication of the Apparent Excess Heat Effect in a Light Water-Potassium Carbonate-Nickel Electrolytic Cell, NASA Technical Memorandum 107167, February, (1996). pp. 1-20.; Niedra, J., Baldwin, R., Meyers, I., NASA Presentation of Light Water Electrolytic Tests, May 15, 1994.; and in prior PCT applications PCT/US00/20820; PCT/US00/20819; PCT/US99/17171; PCT/US99/17129; PCT/US 98/22822; PCT/US98/14029; PCT/US96/07949; PCT/US94/02219; PCT/US91/08496; PCT/US90/01998; and prior U.S. patent applications Ser. No. 09/225,687, filed on Jan. 6, 1999; Ser. No. 60/095,149, filed Aug. 3, 1998; Ser. No. 60/101,651, filed Sep. 24, 1998; Ser. No. 60/105,752, filed Oct. 26, 1998; Ser. No. 60/113,713, filed Dec. 24, 1998; Ser. No. 60/123,835, filed Mar. 11, 1999; Ser. No. 60/130,491, filed Apr. 22, 1999; Ser. No. 60/141,036, filed Jun. 29, 1999; Ser. No. 09/009,294 filed Jan. 20, 1998; Ser. No. 09/111,160 filed Jul. 7, 1998; Ser. No. 09/111,170 filed Jul. 7, 1998; Ser. No. 09/111,016 filed Jul. 7, 1998; Ser. No. 09/111,003 filed Jul. 7, 1998; Ser. No. 09/110,694 filed Jul. 7, 1998; Ser. No. 09/110,717 filed Jul. 7, 1998; Ser. No. 60/053,378 filed Jul. 22, 1997; Ser. No. 60/068,913 filed Dec. 29, 1997; Ser. No. 60/090,239 filed Jun. 22, 1998; Ser. No. 09/009,455 filed Jan. 20, 1998; Ser. No. 09/110,678 filed Jul. 7, 1998; Ser. No. 60/053,307 filed Jul. 22, 1997; Ser. No. 60/068,918 filed Dec. 29, 1997; Ser. No. 60/080,725 filed Apr. 3, 1998; Ser. No. 09/181,180 filed Oct. 28, 1998; Ser. No. 60/063,451 filed Oct. 29, 1997; Ser. No. 09/008,947 filed Jan. 20, 1998; Ser. No. 60/074,006 filed Feb. 9, 1998; Ser. No. 60/080,647 filed Apr. 3, 1998; Ser. No. 09/009,837 filed Jan. 20, 1998; Ser. No. 08/822,170 filed Mar. 27, 1997; Ser. No. 08/592,712 filed Jan. 26, 1996; Ser. No. 08/467,051 filed on Jun. 6, 1995; Ser. No. 08/416,040 filed on Apr. 3, 1995; Ser. No. 08/467,911 filed on Jun. 6, 1995; Ser. No. 08/107,357 filed on Aug. 16, 1993; Ser. No. 08/075,102 filed on Jun. 11, 1993; Ser. No. 07/626,496 filed on Dec. 12, 1990; Ser. No. 07/345,628 filed Apr. 28, 1989; Ser. No. 07/341,733 filed Apr. 21, 1989 the entire disclosures of which are all incorporated herein by reference (hereinafter “Mills Prior Publications”).

The binding energy of an atom, ion, or molecule, also known as the ionization energy, is the energy required to remove one electron from the atom, ion or molecule. A hydrogen atom having the binding energy given in Eq. (1) is hereafter referred to as a hydrino atom or hydrino. The designation for a hydrino of radius

$$\frac{{a}_{H}}{p} ,$$

where α_{H} is the radius of an ordinary hydrogen atom and p is an integer, is

$$H [ \frac{{a}_{H}}{p} ] .$$

A hydrogen atom with a radius α_{H} is hereinafter referred to as “ordinary hydrogen atom” or “normal hydrogen atom.” Ordinary atomic hydrogen is characterized by its binding energy of 13.6 eV.

Hydrinos are formed by reacting an ordinary hydrogen atom with a catalyst having a net enthalpy of reaction of about
m·27.2 eV (2a)
where m is an integer. This catalyst has also been referred to as an energy hole or source of energy hole in Mills earlier filed Patent Applications. It is believed that the rate of catalysis is increased as the net enthalpy of reaction is more closely matched to m·27.2 eV. It has been found that catalysts having a net enthalpy of reaction within ±10%, preferably ±5%, of m·27.2 eV are suitable for most applications.

In another embodiment, the catalyst to form hydrinos has a net enthalpy of reaction of about
m/2·27.2 eV (2b)
where m is an integer greater that one. It is believed that the rate of catalysis is increased as the net enthalpy of reaction is more closely matched to m/2·27.2 eV. It has been found that catalysts having a net enthalpy of reaction within ±10%, preferably ±5%, of m/2·27.2 eV are suitable for most applications.

A catalyst of the present invention may provide a net enthalpy of m·27.2 eV where m is an integer or m/2·27.2 eV where m is an integer greater than one by undergoing a transition to a resonant excited state energy level with the energy transfer from hydrogen. For example, He⁺ absorbs 40.8 eV during the transition from the n=1 energy level to the n=2 energy level which corresponds to 3/2·27.2 eV (m=3 in Eq. (2b)). This energy is resonant with the difference in energy between the p=2 and the p=1 states of atomic hydrogen given by Eq. (1). Thus He⁺ may serve as a catalyst to cause the transition between these hydrogen states.

A catalyst of the present invention may provide a net enthalpy of m·27.2 eV where m is an integer or m/2·27.2 eV where m is an integer greater than one by becoming ionized during resonant energy transfer. For example, the third ionization energy of argon is 40.74 eV; thus, Ar²⁺ absorbs 40.8 eV during the ionization to Ar³⁺ which corresponds to 3/2·27.2 eV (m=3 in Eq. (2b)). This energy is resonant with the difference in energy between the p=2 and the p=1 states of atomic hydrogen given by Eq. (1). Thus Ar²⁺ may serve as a catalyst to cause the transition between these hydrogen states.

This catalysis releases energy from the hydrogen atom with a commensurate decrease in size of the hydrogen atom, rₙ=na_{H}. For example, the catalysis of H(n=1) to H(n=½) releases 40.8 eV, and the hydrogen radius decreases from

$${a}_{H} to \frac{1}{2} {a}_{H} .$$

A catalytic system is provided by the ionization of t electrons from an atom each to a continuum energy level such that the sum of the ionization energies of the t electrons is approximately m×27.2 eV where m is an integer. One such catalytic system involves potassium metal. The first, second, and third ionization energies of potassium are 4.34066 eV, 31.63 eV, 45.806 eV, respectively [D. R. Lide, CRC Handbook of Chemistry and Physics, 78 th Edition, CRC Press, Boca Raton, Fla., (1997), p. 10-214 to 10-216]. The triple ionization (t=3) reaction of K to K³⁺, then, has a net enthalpy of reaction of 81.7426 eV, which is equivalent to m=3 in Eq. (2a).

$$\begin{matrix}81.7426 eV + K ( m ) + H [ \frac{{a}_{H}}{p} ] -> {K}^{3 +} + 3 {e}^{-} + H [ \frac{{a}_{H}}{( p + 3 )} ] + [ {( p + 3 )}^{2} - {p}^{2} ] \times 13.6 eV & ( 3 ) \\ {K}^{3 +} + 3 {e}^{-} -> K ( m ) + 81.7426 eV & ( 4 )\end{matrix}$$

And, the overall reaction is

$$H [ \frac{{a}_{H}}{p} ] -> H [ \frac{{a}_{H}}{( p + 3 )} ] + [ {( p + 3 )}^{2} - {p}^{2} ] \times 13.6 eV \qquad ( 5 )$$

Rubidium ion (Rb⁺) is also a catalyst because the second ionization energy of rubidium is 27.28 eV. In this case, the catalysis reaction is

$$27.28 eV + {Rb}^{+} + H [ \frac{{a}_{H}}{p} ] -> {Rb}^{2 +} + {e}^{-} + H [ \frac{{a}_{H}}{( p + 1 )} ] + [ {( p + 1 )}^{2} - {p}^{2} ] \times 13.6 eV \qquad ( 6 )$$

Rb²⁺+e³¹ →Rb⁺+27.28 eV (7)
And, the overall reaction is

$$H [ \frac{{a}_{H}}{p} ] -> H [ \frac{{a}_{H}}{( p + 1 )} ] + [ {( p + 1 )}^{2} - {p}^{2} ] \times 13.6 eV \qquad ( 8 )$$

Strontium ion (Sr⁺) is also a catalyst since the second and third ionization energies of strontium are 11.03013 eV and 42.89 eV, respectively. The ionization reaction of Sr⁺ to Sr³⁺, (t=2), then, has a net enthalpy of reaction of 53.92 eV, which is equivalent to m=2 in Eq. (2a).

$$53.92 eV + {Sr}^{+} + H [ \frac{{a}_{H}}{p} ] -> {Sr}^{3 +} + 2 {e}^{-} + H [ \frac{{a}_{H}}{( p + 2 )} ] + [ {( p + 2 )}^{2} - {p}^{2} ] \times 13.6 eV \qquad ( 9 )$$

Sr³⁺+2e⁻→Sr⁺+53.92 eV (10)
And, the overall reaction is

$$H [ \frac{{a}_{H}}{p} ] -> H [ \frac{{a}_{H}}{( p + 2 )} ] + [ {( p + 2 )}^{2} - {p}^{2} ] \times 13.6 eV \qquad ( 11 )$$

Helium ion (He⁺) is also a catalyst because the second ionization energy of helium is 54.417 eV. In this case, the catalysis reaction is

$$54.417 eV + {He}^{+} + H [ \frac{{a}_{H}}{p} ] -> {He}^{2 +} + {ⅇ}^{-} + H [ \frac{{a}_{H}}{( p + 2 )} ] + [ {( p + 2 )}^{2} - {p}^{2} ] X13 .6 eV \qquad ( 12 )$$

He²⁺+e⁻→He⁺+54.417 eV (13)
And, the overall reaction is

$$H [ \frac{{a}_{H}}{p} ] -> H [ \frac{{a}_{H}}{( p + 2 )} ] + [ {( p + 2 )}^{2} - {p}^{2} ] X13 .6 eV \qquad ( 14 )$$

Argon ion is a catalyst. The second ionization energy is 27.63 eV.

$$27.63 eV + {Ar}^{+} + H [ \frac{{a}_{H}}{p} ] -> {Ar}^{2 +} + {ⅇ}^{-} + H [ \frac{{a}_{H}}{( p + 1 )} ] + [ {( p + 1 )}^{2} - {p}^{2} ] X13 .6 eV \qquad ( 15 )$$

Ar²⁺+e⁻→Ar⁺+27.63 eV (16)
And, the overall reaction is

$$H [ \frac{{a}_{H}}{p} ] -> H [ \frac{{a}_{H}}{( p + 1 )} ] + [ {( p + 1 )}^{2} - {p}^{2} ] X13 .6 eV \qquad ( 17 )$$

A neon ion and a proton can also provide a net enthalpy of a multiple of that of the potential energy of the hydrogen atom. The second ionization energy of neon is 40.96 eV, and H⁺ releases 13.6 eV when it is reduced to H. The combination of reactions of Ne⁺ to Ne²⁺ and H⁺ to H, then, has a net enthalpy of reaction of 27.36 eV, which is equivalent to m=1 in Eq. (2a).

$$\begin{matrix}27.36 eV + {Ne}^{+} + {H}^{+} + H [ \frac{{a}_{H}}{p} ] -> H + {Ne}^{2 +} + H [ \frac{{a}_{H}}{( p + 1 )} ] + [ {( p + 1 )}^{2} - {p}^{2} ] X13 .6 eV & ( 18 ) \\ H + {Ne}^{2 +} -> {H}^{+} + {Ne}^{+} + 27.36 eV & ( 19 )\end{matrix}$$

And, the overall reaction is

$$H [ \frac{{a}_{H}}{p} ] -> H [ \frac{{a}_{H}}{( p + 1 )} ] + [ {( p + 1 )}^{2} - {p}^{2} ] X13 .6 eV \qquad ( 20 )$$

A neon ion can also provide a net enthalpy of a multiple of that of the potential energy of the hydrogen atom. Ne⁺ has an excited state Ne^{+*}of 27.2 eV (46.5 nm) which provides a net enthalpy of reaction of 27.2 eV, which is equivalent to m=1 in Eq. (2a).

$$27.2 eV + {Ne}^{+} + H [ \frac{{a}_{H}}{p} ] -> {Ne}^{+ *} + H [ \frac{{a}_{H}}{( p + 1 )} ] + [ {( p + 1 )}^{2} - {p}^{2} ] X13 .6 eV \qquad ( 21 )$$

Ne^{+*}→Ne⁺+27.2 eV (22)
And, the overall reaction is

$$H [ \frac{{a}_{H}}{p} ] -> H [ \frac{{a}_{H}}{( p + 1 )} ] + [ {( p + 1 )}^{2} - {p}^{2} ] X13 .6 eV \qquad ( 23 )$$

The first neon excimer continuum Ne₂* may also provide a net enthalpy of a multiple of that of the potential energy of the hydrogen atom. The first ionization energy of neon is 21.56454 eV, and the first neon excimer continuum Ne₂* has an excited state energy of 15.92 eV. The combination of reactions of Ne₂* to 2Ne⁺, then, has a net enthalpy of reaction of 27.21 eV, which is equivalent to m=1 in Eq. (2a).

$$27.21 eV + {Ne}_{2}^{*} + H [ \frac{{a}_{H}}{p} ] -> 2 {Ne}^{+} + H [ \frac{{a}_{H}}{( p + 1 )} ] + [ {( p + 1 )}^{2} - {p}^{2} ] X13 .6 eV \qquad ( 24 )$$

2Ne⁺→Ne₂*+27.21 eV (25)
And, the overall reaction is

$$H [ \frac{{a}_{H}}{p} ] -> H [ \frac{{a}_{H}}{( p + 1 )} ] + [ {( p + 1 )}^{2} - {p}^{2} ] X13 .6 eV \qquad ( 26 )$$

Similarly for helium, the helium excimer continuum to shorter wavelengths He₂* may also provide a net enthalpy of a multiple of that of the potential energy of the hydrogen atom. The first ionization energy of helium is 24.58741 eV, and the helium excimer continuum He₂* has an excited state energy of 21.97 eV. The combination of reactions of He₂* to 2He⁺, then, has a net enthalpy of reaction of 27.21 eV, which is equivalent to m=1 in Eq. (2a).

$$27.21 eV + {He}_{2}^{*} + H [ \frac{{a}_{H}}{p} ] -> 2 {He}^{+} + H [ \frac{{a}_{H}}{( p + 1 )} ] + [ {( p + 1 )}^{2} - {p}^{2} ] X13 .6 eV \qquad ( 27 )$$

2He⁺→He₂*+27.21 eV (28)
And, the overall reaction is

$$H [ \frac{{a}_{H}}{p} ] -> H [ \frac{{a}_{H}}{( p + 1 )} ] + [ {( p + 1 )}^{2} - {p}^{2} ] X13 .6 eV \qquad ( 29 )$$

Atomic hydrogen in sufficient concentration may serve as a catalyst since the ionization energy of hydrogen is 13.6 eV. Two atoms fulfill the catalyst criterion—a chemical or physical process with an enthalpy change equal to an integer multiple of 27.2 eV since together they ionize at 27.2 eV. Thus, the transition cascade for the pth cycle of the hydrogen-type atom,

$$H [ \frac{{a}_{H}}{p} ] ,$$

with two hydrogen atoms,

$$H [ \frac{{a}_{H}}{1} ] ,$$

as the catalyst is represented by

$$\begin{matrix}27.21 eV + 2 H [ \frac{{a}_{H}}{1} ] + H [ \frac{{a}_{H}}{p} ] -> 2 {H}^{+} + 2 {ⅇ}^{-} + H [ \frac{{a}_{H}}{( p + 1 )} ] + [ {( p + 1 )}^{2} - {p}^{2} ] X13 .6 eV & ( 30 ) \\ 2 {H}^{+} + 2 {ⅇ}^{-} -> 2 H [ \frac{{a}_{H}}{1} ] + 27.21 eV & ( 31 )\end{matrix}$$

And, the overall reaction is

$$H [ \frac{{a}_{H}}{p} ] -> H [ \frac{{a}_{H}}{( p + 1 )} ] + [ {( p + 1 )}^{2} - p ] X13 .6 eV \qquad ( 32 )$$

A nitrogen molecule can also provide a net enthalpy of a multiple of that of the potential energy of the hydrogen atom. The bond energy of the nitrogen molecule is 9.75 eV, and the first and second ionization energies of the nitrogen atom are 14.53414 eV and 29.6013 eV, respectively. The combination of reactions of N₂ to 2N and N to N²⁺, then, has a net enthalpy of reaction of 53.9 eV, which is equivalent to m=2 in Eq. (2a).

$$\begin{matrix}53.9 eV + {N}_{2} + H [ \frac{{a}_{H}}{p} ] -> N + {N}^{2 +} + H [ \frac{{a}_{H}}{( p + 2 )} ] + [ {( p + 2 )}^{2} - {p}^{2} ] X13 .6 eV & ( 33 ) \\ N + {N}^{2 +} -> {N}_{2} + 53.9 eV & ( 34 )\end{matrix}$$

And, the overall reaction is

$$H [ \frac{{a}_{H}}{p} ] \to H [ \frac{{a}_{H}}{( p + 2 )} ] + [ {( p + 2 )}^{2} - {p}^{2} ] \times 13.6 eV \qquad ( 35 )$$

A carbon molecule can also provide a net enthalpy of a multiple of that of the potential energy of the hydrogen atom. The bond energy of the carbon molecule is 6.29 eV, and the first and through the sixth ionization energies of a carbon atom are 11.2603 eV, 24.38332 eV, 47.8878 eV, 64.4939 eV, and 392.087 eV, respectively. The combination of reactions of C₂ to 2C and C to C⁵⁺, then, has a net enthalpy of reaction of 546.40232 eV, which is equivalent to m=20 in Eq. (2a).

$$\begin{matrix}546.4 eV + {C}_{2} + H [ \frac{{a}_{H}}{p} ] \to C + {C}^{5 +} + H [ \frac{{a}_{H}}{( p + 20 )} ] + [ {( p + 20 )}^{2} - {p}^{2} ] \times 13.6 eV & ( 36 ) \\ C + {C}^{5 +} \to {C}_{2} + 546.4 eV & ( 37 )\end{matrix}$$

And, the overall reaction is

$$H [ \frac{{a}_{H}}{p} ] \to H [ \frac{{a}_{H}}{( p + 20 )} ] + [ {( p + 20 )}^{2} - {p}^{2} ] \times 13.6 eV \qquad ( 38 )$$

An oxygen molecule can also provide a net enthalpy of a multiple of that of the potential energy of the hydrogen atom. The bond energy of the oxygen molecule is 5.165 eV, and the first and second ionization energies of an oxygen atom are 13.61806 eV and 35.11730eV, respectively. The combination of reactions of O₂ to 2O and O to O²⁺, then, has a net enthalpy of reaction of 53.9 eV, which is equivalent to m=2 in Eq. (2a).

$$\begin{matrix}53.9 eV + {O}_{2} + H [ \frac{{a}_{H}}{p} ] -> O + {O}^{2 +} + H [ \frac{{a}_{H}}{( p + 2 )} ] + [ {( p + 2 )}^{2} - {p}^{2} ] X13 .6 eV & ( 39 ) \\ O + {O}^{2 +} -> {O}_{2} + 53.9 eV & ( 40 )\end{matrix}$$

And, the overall reaction is

$$H [ \frac{{a}_{H}}{p} ] -> H [ \frac{{a}_{H}}{( p + 2 )} ] + [ {( p + 2 )}^{2} - {p}^{2} ] X13 .6 eV \qquad ( 41 )$$

An oxygen molecule can also provide a net enthalpy of a multiple of that of the potential energy of the hydrogen atom by an alternative reaction. The bond energy of the oxygen molecule is 5.165 eV, and the first through the third ionization energies of an oxygen atom are 13.61806 eV, 35.11730 eV, and 54.9355 eV, respectively. The combination of reactions of O₂ to 2O and O to O³⁺, then, has a net enthalpy of reaction of 108.83 eV, which is equivalent to m=4 in Eq. (2a).

$$\begin{matrix}108.83 eV + {O}_{2} + H [ \frac{{a}_{H}}{p} ] -> O + {O}^{3 +} + H [ \frac{{a}_{H}}{( p + 4 )} ] + [ {( p + 4 )}^{2} - {p}^{2} ] X13 .6 eV & ( 42 ) \\ O + {O}^{3 +} -> {O}_{2} + 108.83 eV & ( 43 )\end{matrix}$$

And, the overall reaction is

$$H [ \frac{{a}_{H}}{p} ] \to H [ \frac{{a}_{H}}{( p + 4 )} ] + [ {( p + 4 )}^{2} - {p}^{2} ] \times 13.6 eV \qquad ( 44 )$$

An oxygen molecule can also provide a net enthalpy of a multiple of that of the potential energy of the hydrogen atom by an alternative reaction. The bond energy of the oxygen molecule is 5.165 eV, and the first through the fifth ionization energies of an oxygen atom are 13.61806 eV, 35.11730 eV, 54.9355 eV, 77.41353 eV, and 113.899 eV, respectively. The combination of reactions of O₂ to 2O and O to O⁵⁺, then, has a net enthalpy of reaction of 300.15 eV, which is equivalent to m=11 in Eq. (2a).

$$\begin{matrix}300.15 eV + {O}_{2} + H [ \frac{{a}_{H}}{p} ] \to O + {O}^{5 +} + H [ \frac{{a}_{H}}{( p + 11 )} ] + [ {( p + 11 )}^{2} - {p}^{2} ] \times 13.6 eV & ( 45 ) \\ O + {O}^{5 +} \to {O}_{2} + 300.15 eV & ( 46 )\end{matrix}$$

And, the overall reaction is

$$H [ \frac{{a}_{H}}{p} ] \to H [ \frac{{a}_{H}}{( p + 11 )} ] + [ {( p + 11 )}^{2} - {p}^{2} ] \times 13.6 eV \qquad ( 47 )$$

In addition to nitrogen, carbon, and oxygen molecules which are exemplary catalysts, other molecules may be catalysts according to the present invention wherein the energy to break the molecular bond and the ionization of t electrons from an atom from the dissociated molecule to a continuum energy level is such that the sum of the ionization energies of the t electrons is approximately m·27.2 eV where t and m are each an integer. The bond energies and the ionization energies may be found in standard sources such as D. R Linde, CRC Handbook of Chemistry and Physics, 79 th Edition, CRC Press, Boca Raton, Fla., (1999), p. 9-51 to 9-69 and David R. Linde, CRC Handbook of Chemistry and Physics, 79 th Edition, CRC Press, Boca Raton, Fla., (1998-9), p. 10-175 to p. 10-177, respectively. Thus, further molecular catalysts which provide a positive enthalpy of m·27.2 eV to cause release of energy from atomic hydrogen may be determined by one skilled in the art.

Molecular hydrogen catalysts capable of providing a net enthalpy of reaction of approximately m×27.2 eV where m is an integer to produce hydrino whereby the molecular bond is broken and t electrons are ionized from a corresponding free atom of the molecule are given infra. The bonds of the molecules given in the first column are broken and the atom also given in the first column is ionized to provide the net enthalpy of reaction of m×27.2 eV given in the eleventh column where m is given in the twelfth column. The energy of the bond which is broken given by Linde [D. R. Lide, CRC Handbook of Chemistry and Physics, 79 th Edition, CRC Press, Boca Raton, Fla., (1999), p. 9-51 to 9-69] which is herein incorporated by reference is given in the 2nd column, and the electrons which are ionized are given with the ionization potential (also called ionization energy or binding energy). The ionization potential of the n th electron of the atom or ion is designated by IPₙ and is given by Linde [D. R. Lide, CRC Handbook of Chemistry and Physics, 79 th Edition, CRC Press, Boca Raton, Fla., (1998-9), p. 10-175 to p. 10-177] which is herein incorporated by reference. For example, the bond energy of the oxygen molecule, BE=5.165 eV, is given in the 2nd column, and the first ionization potential, IP₁=13.61806 eV, and the second ionization potential, IP₂=35.11730 eV, are given in the third and fourth columns, respectively. The combination of reactions of O₂ to 2O and O to O²⁺, then, has a net enthalpy of reaction of 53.9 eV, as given in the eleventh column, and m=2 in Eq. (2a) as given in the twelfth column.

TABLE 1
Molecular Hydrogen Catalysts

| Catalyst | BE | IP1 | IP2 | IP3 | IP4 | IP5 | IP6 | IP7 | IP8 | Enthalpy | m |
|---|---|---|---|---|---|---|---|---|---|---|---|
| C₂/C | 6.26 | 11.2603 | 24.38332 | 47.8878 | 64.4939 | 392.087 | | | | 546.4 | 20 |
| N₂/N | 9.75 | 14.53414 | 29.6013 | | | | | | | 53.9 | 2 |
| O₂/O | 5.165 | 13.61806 | 35.11730 | | | | | | | 54.26 | 2 |
| O₂/O | 5.165 | 13.61806 | 35.11730 | 54.9355 | | | | | | 108.83 | 4 |
| O₂/O | 5.165 | 13.61806 | 35.11730 | 54.9355 | 77.41353 | 113.899 | | | | 300.15 | 11 |
| CO₂/O | 5.52 | 13.61806 | 35.11730 | | | | | | | 54.26 | 2 |
| CO₂/O | 5.52 | 13.61806 | 35.11730 | 54.9355 | | | | | | 109.19 | 4 |
| CO₂/O | 5.52 | 13.61806 | 35.11730 | 54.9355 | 77.41353 | 113.8990 | | | | 300.5 | 11 |
| NO₂/O | 3.16 | 13.61806 | 35.11730 | 54.9355 | 77.41353 | 113.8990 | | | | 298.14 | 11 |
| NO₃/O | 2.16 | 13.61806 | 35.11730 | 54.9355 | 77.41353 | 113.8990 | 138.1197 | | | 435.26 | 16 |

In an embodiment, a molecular catalyst such as nitrogen is combined with another catalyst such as He⁺ (Eqs. (12-14)) or Ar⁺ (Eqs. (15-17)). In an embodiment of a catalyst combination of argon and nitrogen, the percentage of nitrogen is within the range 1-10%. In an embodiment of a catalyst combination of argon and nitrogen, the source of hydrogen atoms is a hydrogen halide such as HF.

The energy given off during catalysis is much greater than the energy lost to the catalyst. The energy released is large as compared to conventional chemical reactions. For example, when hydrogen and oxygen gases undergo combustion to form water

$${H}_{2} ( g ) + \frac{1}{2} {O}_{2} ( g ) \to {H}_{2} O ( l ) \qquad ( 48 )$$

the known enthalpy of formation of water is ΔH_{f}=−286 kJ/mole or 1.48 eV per hydrogen atom. By contrast, each (n=1 ) ordinary hydrogen atom undergoing catalysis releases a net of 40.8 eV. Moreover, further catalytic transitions may occur:

$$n = \frac{1}{2} \to \frac{1}{3} , \frac{1}{3} \to \frac{1}{4} , \frac{1}{4} \to \frac{1}{5} ,$$

and so on. Once catalysis begins, hydrinos autocatalyze further in a process called disproportionation. This mechanism is similar to that of an inorganic ion catalysis. But, hydrino catalysis should have a higher reaction rate than that of the inorganic ion catalyst due to the better match of the enthalpy to m·27.2 eV.

### 2.2 Dihydrino Molecular Ion, Dihydrino Molecule, and Hydrino Hydride Ion

The theory of lower-energy hydrogen molecular ions, molecules, and hydride ions are given in Mills '03 GUT in Chps. 12 and 7 which are incorporated by reference. H(1/p) may react with a proton to form a molecular ion H₂(1/p)⁺ that has a bond energy and vibrational levels that are p² times those of the molecular ion comprising uncatalyzed atomic hydrogen where p is an integer. E_{T}, the total energy of the hydrogen molecular H₂(1/p)⁺, is
E_{T}=13.6 eV(−4p²ln 3+p²+2p²ln 3)=−p²16.28 eV (49)
The bond dissociation energy, E_{D}, is the difference between the total energy of the corresponding hydrogen atom or hydrino atom and E_{T}.

$$\begin{matrix}{E}_{D} = E ( H ⌊ \frac{{a}_{H}}{p} ⌋ ) - {E}_{T} \\ = - {p}^{2} 13.6 + {p}^{2} 16.28 eV \\ = {p}^{2} 2.68 eV\end{matrix} \qquad ( 50 )$$

H₂(1/p)⁺ has been observed spectroscopically [R. Mills, P. Ray, “Vibrational Spectral Emission of Fractional-Principal-Quantum-Energy-Level Hydrogen Molecular Ion”, Int. J. Hydrogen Energy, Vol. 27, No. 5, (2002), pp. 533-564; R. Mills, J. He, A. Echezuria, B Dhandapani, P. Ray, “Comparison of Catalysts and Plasma Sources of Vibrational Spectral Emission of Fractional-Rydberg-State Hydrogen Molecular Ion”, European Journal of Physics D, submitted]. For example, the catalysis reaction product H(¼) was predicted to further react to form a new molecular ion H₂(¼)⁺ with the emission of a vibrational series from its transition state. The emission including both Stokes and antiStokes-like branches is given by the previously derived formula [R. Mills, J. He, A. Echezuria, B Dhandapani, P. Ray, “Comparison of Catalysts and Plasma Sources of Vibrational Spectral Emission of Fractional-Rydberg-State Hydrogen Molecular Ion”, European Journal of Physics D, submitted]:
E_{D+vib}=4²E_{D H}_{₂}_{⁺}±υ*2²E_{vib H}_{₂}_{⁺}_{(υ=0→υ=1)}, υ*=0,1,2,3, . . . (51)
In Eq. (51), E_{D H}_{₂}_{⁺} and E_{vib H}_{₂}_{⁺}_{(υ=0→υ=1)} are the experimental bond and vibrational energies of H₂⁺, respectively. Extreme ultraviolet (EUV) spectroscopy was recorded on microwave discharges of helium with 10% hydrogen in the range 10-65 nm. The predicted emission (Eq. (51)) was observed at the longer wavelengths for υ*=0 to υ*=20 and at the shorter wavelengths for υ*=0 to υ*=3. A peak at 28.93 nm matched the predicted bond energy of the molecular ion, 42.88 eV.

The diatomic molecule H₂(1/p) may form by reaction of the corresponding fractional Rydb erg state atoms H(1/p)
2H(1/p)→H₂(1/p) (52)
where each energy level corresponds to a fractional quantum number that is the reciprocal of an integer p. The central field of fractional Rydberg state H₂(1/p) is p times that of ordinary H₂, the corresponding total, bond, and vibrational energies are p² those of H₂, and the internuclear distance is

$$2 {c}^{′} = \frac{\sqrt{2} {a}_{o}}{p} \qquad ( 53 )$$

E_{T}, the total energy of the molecule H₂(1/p), is

$$\begin{matrix}{E}_{T} = - 13.6 eV [ ( 2 {p}^{2} \sqrt{2} - {p}^{2} \sqrt{2} + \frac{{p}^{2} \sqrt{2}}{2} ) \\ ln \frac{\sqrt{2} + 1}{\sqrt{2} - 1} - {p}^{2} \sqrt{2} ] \\ = - {p}^{2} 31.63 eV\end{matrix} \qquad ( 54 )$$

where −31.63 eV is the total energy of H₂. The experimental bond energy of the hydrogen molecule [P. W. Atkins, Physical Chemistry, Second Edition, W. H. Freeman, San Francisco, (1982), p. 589] is
E_{D}=4.4783 eV (55)
The theoretical bond energies of hydrogen type-type molecules H₂(1/p) are
E_{D}=p²4.4783 eV (56)

Dihydrino gas has been cryogenically isolated [R. Mills, B. Dhandapani, M. Nansteel, J. He, P. Ray, “Liquid-Nitrogen-Condensable Molecular Hydrogen Gas Isolated from a Catalytic Plasma Reaction”, J. Phys. Chem. B, submitted which is herein incorporated by reference in its entirety]. Extreme ultraviolet (EUV) spectroscopy was recorded on microwave discharges of helium with 2% hydrogen. Novel emission lines were observed with energies of q·13.6 eV where q=1,2,3,4,6,7,8,9,11 or these discrete energies less 21.2 eV corresponding to inelastic scattering of these photons by helium atoms due to excitation of He (1S²) to He (1s¹2p¹). These lines matched H(1/p), fractional Rydberg states of atomic hydrogen, formed by a resonant nonradiative energy transfer to He⁺. Corresponding emission due to the reaction 2H(½)→H₂(½) with vibronic coupling at

$${E}_{D + vib} = {p}^{2} {E}_{D {H}_{2}} \pm ( \frac{{υ}^{*}}{3} ) {E}_{vib {H}_{2} ( υ = 0 -> υ = 1 )} ,$$

υ*=1,2,3 . . . was observed at the longer wavelengths for υ*=2 to υ*=32 and at the shorter wavelengths for υ*=1 to υ*=16 where E_{D H}_{₂} and E_{vib H}_{₂}_{(υ=0→υ=1)} are the experimental bond and vibrational energies of H₂, respectively. Fraction-principal-quantum-level molecular hydrogen H₂(1/p) gas was isolated by liquefaction using an high-vacuum (10^{31 6} torr) capable, liquid nitrogen cryotrap and was characterized by gas chromatography (GC), mass spectroscopy (MS), visible and EUV optical emission spectroscopy (OES), and ¹H NMR of the condensable gas dissolved in CDCl₃. Novel peaks were observed by cryogenic gas chromatography performed on the condensable gas which was highly pure hydrogen by MS and had a higher ionization energy than H₂. A unique EBV emission spectrum was observed by OES. The observation that the novel EUV emission spectrum shifted with deuterium substitution in a region where no hydrogen emission has ever been observed unequivocally confirmed the existence of lower-energy molecular hydrogen. Contaminants and exotic helium-hydrogen species were eliminated as the source of the reaction and condensed gas plasma emission spectra. Upfield shifted NMR peaks were observed at 3.22 and 3.47 ppm compared to that of H₂ at 4.63 ppm.

The hydrino hydride ion of the present invention can be formed by the reaction of an electron source with a hydrino, that is, a hydrogen atom having a binding energy of about

$$\frac{13.6 eV}{{n}^{2}} ,$$

where

$$n = \frac{1}{p}$$

and p is an integer greater than 1. The hydrino hydride ion is represented by H⁻(n=1/p) or H⁻(1/p):

$$\begin{matrix}H [ \frac{{a}_{H}}{p} ] + {ⅇ}^{-} -> {H}^{-} ( n = 1 / p ) & ( 57 a ) \\ H [ \frac{{a}_{H}}{p} ] + {ⅇ}^{-} -> {H}^{-} ( 1 / p ) & ( 57 b )\end{matrix}$$

The hydrino hydride ion is distinguished from an ordinary hydride ion comprising an ordinary hydrogen nucleus and two electrons having a binding energy of about 0.8 eV. The latter is hereafter referred to as “ordinary hydride ion” or “normal hydride ion” The hydrino hydride ion comprises a hydrogen nucleus including proteum, deuterium, or tritium, and two indistinguishable electrons at a binding energy according to Eq. (58).

The binding energy of a novel hydrino hydride ion can be represented by the following formula:

$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {ⅇ}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) \qquad ( 58 )$$

where p is an integer greater than one, s=½, π is pi, [symbol] is Planck's constant bar, μₒ is the permeability of vacuum, mₑ is the mass of the electron, μₑ is the reduced electron mass given by

$${μ}_{e} = \frac{{m}_{e} {m}_{p}}{\frac{{m}_{e}}{\sqrt{\frac{3}{4}}} + {m}_{p}}$$

where mₚ is the mass of the proton, α_{H} is the radius of the hydrogen atom,
αₒ is the Bohr radius, and e is the elementary charge. The radii are given by

$${r}_{2} = {r}_{1} = {a}_{0} ( 1 + \sqrt{s ( s + 1 )} ) s = \frac{1}{2} \qquad ( 59 )$$

The binding energies of the hydrino hydride ion, H⁻(n=1/p) as a function of p, where p is an integer, are shown in TABLE 2.

TABLE 2
The representative binding energy of the hydrino hydride ion
H⁻(n = 1/p) as a function of p, Eq. (58).

| | r₁ | Binding | Wavelength |
|---|---|---|---|
| Hydride Ion | (α₀)^{a} | Energy (eV)^{b} | (nm) |
| H⁻(n = 1) | 1.8660 | 0.7542 | 1644 |
| H⁻(n = 1/2) | 0.9330 | 3.047 | 406.9 |
| H⁻(n = 1/3) | 0.6220 | 6.610 | 187.6 |
| H⁻(n = 1/4) | 0.4665 | 11.23 | 110.4 |
| H⁻(n = 1/5) | 0.3732 | 16.70 | 74.23 |
| H⁻(n = 1/6) | 0.3110 | 22.81 | 54.35 |
| H⁻(n = 1/7) | 0.2666 | 29.34 | 42.25 |
| H⁻(n = 1/8) | 0.2333 | 36.09 | 34.46 |
| H⁻(n = 1/9) | 0.2073 | 42.84 | 28.94 |
| H⁻(n = 1/10) | 0.1866 | 49.38 | 25.11 |
| H⁻(n = 1/11) | 0.1696 | 55.50 | 22.34 |
| H⁻(n = 1/12) | 0.1555 | 60.98 | 20.33 |
| H⁻(n = 1/13) | 0.1435 | 65.63 | 18.89 |
| H⁻(n = 1/14) | 0.1333 | 69.22 | 17.91 |
| H⁻(n = 1/15) | 0.1244 | 71.55 | 17.33 |
| H⁻(n = 1/16) | 0.1166 | 72.40 | 17.12 |
| H⁻(n = 1/17) | 0.1098 | 71.56 | 17.33 |
| H⁻(n = 1/18) | 0.1037 | 68.83 | 18.01 |
| H⁻(n = 1/19) | 0.0982 | 63.98 | 19.38 |
| H⁻(n = 1/20) | 0.0933 | 56.81 | 21.82 |
| H⁻(n = 1/21) | 0.0889 | 47.11 | 26.32 |
| H⁻(n = 1/22) | 0.0848 | 34.66 | 35.76 |
| H⁻(n = 1/23) | 0.0811 | 19.26 | 64.36 |
| H⁻(n = 1/24) | 0.0778 | 0.6945 | 1785 |

^{a}Equation (59)
^{b}Equation (58)

The existence of novel alkaline and alkaline earth hydride and halido-hydrides were 40 also previously identified by large distinct upfield ¹H NMR resonances compared to the NMR peaks of the corresponding ordinary hydrides [R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367; R. Mills, B. Dhandapani, N. Greenig, J. He, “Synthesis and Characterization of Potassium Iodo Hydride”, Int. J. of Hydrogen Energy, Vol. 25, Issue 12, December, (2000), pp. 1185-1203; R. Mills, B. Dhandapani, M. Nansteel, J. He, A. Voigt, “Identification of Compounds Containing Novel Hydride Ions by Nuclear Magnetic Resonance Spectroscopy”, Int. J. Hydrogen Energy, Vol. 26, No. 9, (2001), pp. 965-979; R. Mills, P. Ray, B. Dhandapani, W. Good, P. Jansson, M. Nansteel, J. He, A. Voigt, “Spectroscopic and NMR Identification of Novel Hydride Ions in Fractional Quantum Energy States Formed by an Exothermic Reaction of Atomic Hydrogen with Certain Catalysts”, J. Phys. Chem. A, submitted.]. Using a number of analytical techniques such as XPS and time-of-flight-secondary-mass-spectroscopy (ToF-SIMS) as well as NMR, the hydrogen content was assigned to H⁻(1/p), novel high-binding-energy hydride ions in stable fractional principal quantum states [R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367; R. Mills, B. Dhandapani, N. Greenig, J. He, “Synthesis and Characterization of Potassium Iodo Hydride”, Int. J. of Hydrogen Energy, Vol. 25, Issue 12, December, (2000), pp. 1185-1203; R. L. Mills, B. Dhandapani, J. He, “Highly Stable Amorphous Silicon Hydride”, Solar Energy Materials & Solar Cells, in press; R. Mills, P. Ray, B. Dhandapani, W. Good, P. Jansson, M. Nansteel, J. He, A. Voigt, “Spectroscopic and NMR Identification of Novel Hydride Ions in Fractional Quantum Energy States Formed by an Exothermic Reaction of Atomic Hydrogen with Certain Catalysts”, J. Phys. Chem. A, submitted]. The synthesis reactions typically involve metal ion catalysts. For example, Rb⁺ to Rb²⁺ and 2K⁺ to K+K²⁺ each provide a reaction with a net enthalpy equal to the potential energy of atomic hydrogen. It was reported previously [R. L. Mills, P. Ray, “A Comprehensive Study of Spectra of the Bound-Free Hyperfine Levels of Novel Hydride Ion H⁻(½), Hydrogen, Nitrogen, and Air”, Int. J. Hydrogen Energy, (2003), Vol. 28, No. 8, pp. 825-871] that the presence of these gaseous ions with thermally dissociated hydrogen formed a hydrogen plasma with hydrogen atom energies of 17 and 12 eV respectively, compared to 3 eV for a hydrogen microwave plasma. The energetic catalytic reaction involves a resonance energy transfer between hydrogen atoms and Rb⁺ or 2K⁺ to form a very stable novel hydride ion H⁻(½). Its predicted binding energy of 3.0468 eV was observed by high resolution visible spectroscopy as a continuum threshold at 406.82 nm, and a structured, strong emission peak was observed at 407.1 nm corresponding to the fine structure and hyperfine structure of H(½). From the electron g factor, bound-free hyperfine structure lines of H⁻(½) were predicted with energies E_{HF} given by E_{HF}=j²3.00213×10⁻⁵ +3.0563 eV (j is an integer) as an inverse Rydberg-type series from 3.0563 eV to 3.1012 eV—the hydride binding energy peak with the fine structure plus one and five times the spin-pairing energy, respectively. The high resolution visible plasma emission spectra in the region of 399.5 to 406.0 nm matched the predicted emission lines for j=1 to j=39 with the series edge at 399.63 nm up to 1 part in 10⁵.

### 2.3 Hydrogen Plasma

Developed sources that provide a suitable intensity hydrogen plasmas are high voltage discharges, synchrotron devices, inductively coupled plasma generators, and magnetically confined plasmas. In contrast to the high electric fields, power densities, and temperatures of prior sources, an intense hydrogen plasma is generated at low gas temperatures (e.g. ≈10³ K) with a very low field (1V/cm) from atomic hydrogen and certain atomized elements or certain gaseous ions which singly or multiply ionize at integer multiples of the potential energy of atomic hydrogen, m·27.2 eV [R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943 which is incorporated by reference]. The so-called resonant transfer or rt-plasma of one embodiment of the present invention forms by a resonant energy transfer mechanism involving the species providing a net enthalpy of a multiple of 27.2 eV and atomic hydrogen. In further embodiments comprise microwave, RF, and DC field driven plasmas.

### 2.4 Diamond Synthesis

Diamond has some of the most extreme physical properties of any material such as outstanding mechanical strength, optical transparency, high thermal conductivity, high electron mobility, and unique chemical properties. Thus, a variety of possible applications are envisioned for diamond materials. Yet, its practical use in applications has been limited due to its scarcity, expense, and immalleability. The development of techniques for depositing thin films of synthetic diamonds on a variety of substrates has enabled the exploitation of diamond's superlative properties in many new and exciting applications. These include cutting tools, thermal management of integrated circuits, optical windows, high temperature electronics, surface acoustic wave (SAW) filters, field emission displays, electrochemical sensors, composite reinforcement, microchemical devices and sensors, and particle detectors. But, the fundamental impediment facing the technology at the present is insufficient growth rate of high-quality diamond.

Deposition of carbon from a source such as a hydrocarbon, solid carbon or a carbon-containing precursor in the present of the catalysis of atomic hydrogen to form lower-energy-hydrogen species is a means of the present invention to form diamond, diamond films, and related materials at high rates.

### II. SUMMARY OF THE INVENTION

An object of the present invention is to generate power and novel hydrogen species and compositions of matter comprising new forms of hydrogen via the catalysis of atomic hydrogen.

Another objective of the present invention is to generate a plasma and a source of light such as high energy light, extreme ultraviolet light and ultraviolet light, and energetic particles such as fast hydrogen atoms (fast H) via the catalysis of atomic hydrogen.

Another objective of the present invention is to synthesize diamond, diamond films, and related materials from carbon and carbon precursors using the unique properties and chemical species formed during the catalysis of atomic hydrogen to lower-energy states.

### 1. Catalysis of Hydrogen to Form Novel Hydrogen Species and Compositions of Matter Comprising New Forms of Hydrogen

The above objectives and other objectives are achieved by the present invention comprising a power source and diamond synthesis reactor. The power source and diamond synthesis reactor comprises a cell for the catalysis of atomic hydrogen to form novel hydrogen species and compositions of matter comprising new forms of hydrogen. The novel hydrogen compositions of matter comprise:

(a) at least one neutral, positive, or negative hydrogen species (hereinafter “increased binding energy hydrogen species”) having a binding energy
(i) greater than the binding energy of the corresponding ordinary hydrogen species, or
(ii) greater than the binding energy of any hydrogen species for which the corresponding ordinary hydrogen species is unstable or is not observed because the ordinary hydrogen species' binding energy is less than thermal energies at ambient conditions (standard temperature and pressure, STP), or is negative; and

(b) at least one other element. The compounds of the invention are hereinafter referred to as “increased binding energy hydrogen compounds”.

By “other element” in this context is meant an element other than an increased binding energy hydrogen species. Thus, the other element can be an ordinary hydrogen species, or any element other than hydrogen. In one group of compounds, the other element and the increased binding energy hydrogen species are neutral. In another group of compounds, the other element and increased binding energy hydrogen species are charged such that the other element provides the balancing charge to form a neutral compound. The former group of compounds is characterized by molecular and coordinate bonding; the latter group is characterized by ionic bonding.

Also provided are novel compounds and molecular ions comprising (a) at least one neutral, positive, or negative hydrogen species (hereinafter “increased binding energy hydrogen species”) having a total energy
(i) greater than the total energy of the corresponding ordinary hydrogen species, or
(ii) greater than the total energy of any hydrogen species for which the corresponding ordinary hydrogen species is unstable or is not observed because the ordinary hydrogen species' total energy is less than thermal energies at ambient conditions, or is negative; and

(b) at least one other element.

The total energy of the hydrogen species is the sum of the energies to remove all of the electrons from the hydrogen species. The hydrogen species according to the present invention has a total energy greater than the total energy of the corresponding ordinary hydrogen species. The hydrogen species having an increased total energy according to the present invention is also referred to as an “increased binding energy hydrogen species” even though some embodiments of the hydrogen species having an increased total energy may have a first electron binding energy less that the first electron binding energy of the corresponding ordinary hydrogen species. For example, the hydride ion of Eq. (58) for p=24 has a first binding energy that is less than the first binding energy of ordinary hydride ion, while the total energy of the hydride ion of Eq. (58) for p=24 is much greater than the total energy of the corresponding ordinary hydride ion.

Also provided are novel compounds and molecular ions comprising

(a) a plurality of neutral, positive, or negative hydrogen species (hereinafter “increased binding energy hydrogen species”) having a binding energy
(i) greater than the binding energy of the corresponding ordinary hydrogen species, or
(ii) greater than the binding energy of any hydrogen species for which the corresponding ordinary hydrogen species is unstable or is not observed because the ordinary hydrogen species' binding energy is less than thermal energies at ambient conditions or is negative; and

(b) optionally one other element. The compounds of the invention are hereinafter referred to as “increased binding energy hydrogen compounds”.

The increased binding energy hydrogen species can be formed by reacting one or more hydrino atoms with one or more of an electron, hydrino atom, a compound containing at least one of said increased binding energy hydrogen species, and at least one other atom, molecule, or ion other than an increased binding energy hydrogen species.

Also provided are novel compounds and molecular ions comprising

(a) a plurality of neutral, positive, or negative hydrogen species (hereinafter “increased binding energy hydrogen species”) having a total energy
(i) greater than the total energy of ordinary molecular hydrogen, or
(ii) greater than the total energy of any hydrogen species for which the corresponding ordinary hydrogen species is unstable or is not observed because the ordinary hydrogen species' total energy is less than thermal energies at ambient conditions or is negative; and

(b) optionally one other element. The compounds of the invention are hereinafter referred to as “increased binding energy hydrogen compounds”. The total energy of the increased total energy hydrogen species is the sum of the energies to remove all of the electrons from the increased total energy hydrogen species. The total energy of the ordinary hydrogen species is the sum of the energies to remove all of the electrons from the ordinary hydrogen species. The increased total energy hydrogen species is referred to as an increased binding energy hydrogen species, even though some of the increased binding energy hydrogen species may have a first electron binding energy less than the first electron binding energy of ordinary molecular hydrogen. However, the total energy of the increased binding energy hydrogen species is much greater than the total energy of ordinary molecular hydrogen.

In one embodiment of the invention, the increased binding energy hydrogen species can be Hₙ, and Hₙ⁻ where n is a positive integer, or Hₙ⁺ where n is a positive integer greater than one. Preferably, the increased binding energy hydrogen species is Hₙ and Hₙ⁻ where n is an integer from one to about 1×10⁶, more preferably one to about 1×10⁴, even more preferably one to about 1×10², and most preferably one to about 10, and Hₙ⁺ where n is an integer from two to about 1×10⁶, more preferably two to about 1×10⁴, even more preferably two to about 1×10², and most preferably two to about 10. A specific example of Hₙ⁻ is H₁₆⁻.

In an embodiment of the invention, the increased binding energy hydrogen species can be Hₙ^{m-} where n and m are positive integers and Hₙ^{m+} where n and m are positive integers with m<n. Preferably, the increased binding energy hydrogen species is Hₙ^{m-} where n is an integer from one to about 1×10⁶, more preferably one to about 1×10⁴, even more preferably one to about 1×10², and most preferably one to about 10 and m is an integer from one to 100, one to ten, and Hₙ^{m+} where n is an integer from two to about 1×10⁶, more preferably two to about 1×10⁴, even more preferably two to about 1×10², and most preferably two to about 10 and m is one to about 100, preferably one to ten.

According to a preferred embodiment of the invention, a compound is provided, comprising at least one increased binding energy hydrogen species selected from the group consisting of (a) hydride ion having a binding energy according to Eq. (58) that is greater than the binding of ordinary hydride ion (about 0.8 eV) for p=2 up to 23, and less for p=24 (“increased binding energy hydride ion” or “hydrino hydride ion”); (b) hydrogen atom having a binding energy greater than the binding energy of ordinary hydrogen atom (about 13.6 eV) (“increased binding energy hydrogen atom” or “hydrino”); (c) hydrogen molecule having a first binding energy greater than about 15.3 eV (“increased binding energy hydrogen molecule” or (“dihydrino”); and (d) molecular hydrogen ion having a binding energy greater than about 16.3 eV (“increased binding energy molecular hydrogen ion” or “dihydrino molecular ion”).

The compounds of the present invention are capable of exhibiting one or more unique properties which distinguishes them from the corresponding compound comprising ordinary hydrogen, if such ordinary hydrogen compound exists. The unique properties include, for example, (a) a unique stoichiometry; (b) unique chemical structure; (c) one or more extraordinary chemical properties such as conductivity, melting point, boiling point, density, and refractive index; (d) unique reactivity to other elements and compounds; (e) enhanced stability at room temperature and above; and/or (t) enhanced stability in air and/or water. Methods for distinguishing the increased binding energy hydrogen-containing compounds from compounds of ordinary hydrogen include: 1.) elemental analysis, 2.) solubility, 3.) reactivity, 4.) melting point, 5.) boiling point, 6.) vapor pressure as a function of temperature, 7.) refractive index, 8.) X-ray photoelectron spectroscopy (XPS), 9.) gas chromatography, 10.) X-ray diffraction (XRD), 11.) calorimetry, 12.) infrared spectroscopy (IR), 13.) Raman spectroscopy, 14.) Mossbauer spectroscopy, 15.) extreme ultraviolet (EUV) emission and absorption spectroscopy, 16.) ultraviolet (UV) emission and absorption spectroscopy, 17.) visible emission and absorption spectroscopy, 18.) nuclear magnetic resonance spectroscopy, 19.) gas phase mass spectroscopy of a heated sample (solids probe and direct exposure probe quadrapole and magnetic sector mass spectroscopy), 20.) time-of-flight-secondary-ion-mass-spectroscopy (TOFSIMS), 21.) electrospray-ionization-time-of-flight-mass-spectroscopy (ESITOFMS), 22.) thermogravimetric analysis (TGA), 23.) differential thermal analysis (DTA), 24.) differential scanning calorimetry (DSC), 25.) liquid chromatography/mass spectroscopy (LCMS), and/or 26.) gas chromatography/mass spectroscopy (GCMS).

According to the present invention, a hydrino hydride ion (H⁻) having a binding energy according to Eq. (58) that is greater than the binding of ordinary hydride ion (about 0.8 eV) for p=2 up to 23, and less for p=24 (H⁻) is provided. For p=2 to p=24 of Eq. (58), the hydride ion binding energies are respectively 3, 6.6, 11.2, 16.7, 22.8, 29.3, 36.1, 42.8, 49.4, 55.5, 61.0, 65.6, 69.2, 71.6, 72.4, 71.6, 68.8, 64.0, 56.8, 47.1, 34.7, 19.3, and 0.69 eV. Compositions comprising the novel hydride ion are also provided.

Novel compounds are provided comprising one or more hydrino hydride ions and one or more other elements. Such a compound is referred to as a hydrino hydride compound.

Ordinary hydrogen species are characterized by the following binding energies (a) hydride ion, 0.754 eV (“ordinary hydride ion”); (b) hydrogen atom (“ordinary hydrogen atom”), 13.6 eV; (c) diatomic hydrogen molecule, 15.46 eV (“ordinary hydrogen molecule”); (d) hydrogen molecular ion, 16.3 eV (“ordinary hydrogen molecular ion”); and (e) H₃⁺, 22.6 eV (“ordinary trihydrogen molecular ion”). Herein, with reference to forms of hydrogen, “normal” and “ordinary” are synonymous.

According to a further preferred embodiment of the invention, a compound is provided comprising at least one increased binding energy hydrogen species such as (a) a hydrogen atom having a binding energy of about

$$\frac{13.6 eV}{{( \frac{1}{p} )}^{2}} ,$$

preferably within ±10%, more preferably ±5%, where p is an integer, preferably an integer from 2 to 200; (b) a hydride ion (H⁻) having a binding energy of about

$$\frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {ⅇ}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) ,$$

preferably within ±10%, more preferably ±5%, where p is an integer, preferably an integer from 2 to 200; (c) H₄⁺(1/p); (d) a trihydrino molecular ion, H₃⁺(1/p), having a binding energy of about

$$\frac{22.6}{{( \frac{1}{p} )}^{2}} eV$$

preferably within ±10%, more preferably ±5%, where p is an integer, preferably an integer from 2 to 200; (e) a dihydrino having a binding energy of about

$$\frac{15.3}{{( \frac{1}{p} )}^{2}} eV$$

preferably within ±10%, more preferably ±5%, where p is an integer, preferably and integer from 2 to 200; (f) a dihydrino molecular ion with a binding energy of about

$$\frac{16.3}{{( \frac{1}{p} )}^{2}} eV$$

preferably within ±10%, more preferably ±5%, where p is an integer, preferably an integer from 2 to 200.

According to one embodiment of the invention wherein the compound comprises a negatively charged increased binding energy hydrogen species, the compound further comprises one or more cations, such as a proton, ordinary H₂⁺, or ordinary H₃⁺.

A method is provided for preparing compounds comprising at least one increased binding energy hydride ion. Such compounds are hereinafter referred to as “hydrino hydride compounds”. The method comprises reacting atomic hydrogen with a catalyst having a net enthalpy of reaction of about

$$\frac{m}{2} \cdot 27 eV ,$$

where m is an integer greater than 1, preferably an integer less than 400, to produce an increased binding energy hydrogen atom having a binding energy of about

$$\frac{13.6 eV}{{( \frac{1}{p} )}^{2}}$$

where p is an integer, preferably an integer from 2 to 200. A further product of the catalysis is energy. The increased binding energy hydrogen atom can be reacted with an electron source, to produce an increased binding energy hydride ion. The increased binding energy hydride ion can be reacted with one or more cations to produce a compound comprising at least one increased binding energy hydride ion.

### 2. Hydrogen Power and Plasma Cell and Diamond Reactor

The invention is also directed to a reactor for producing increased binding energy hydrogen compounds of the invention, such as dihydrino molecules and hydrino hydride compounds and diamond. A further product of the catalysis is energy. Such a reactor is hereinafter referred to as a “hydrino hydride reactor”, “hydrogen reactor”, or “hydrogen cell”. The hydrogen reactor comprises a cell for making hydrinos. The cell for making hydrinos may take the form of a gas cell, a gas discharge cell, a plasma torch cell, or microwave power cell, for example. These exemplary cells which are not meant to be exhaustive are disclosed in Mills Prior Publications. Each of these cells comprises: a source of atomic hydrogen; at least one of a solid, molten, liquid, or gaseous catalyst for making hydrinos; and a vessel for reacting hydrogen and the catalyst for making hydrinos. As used herein and as contemplated by the subject invention, the term “hydrogen”, unless specified otherwise, includes not only proteum (¹H), but also deuterium (²H) and tritium (³H).

The reactors described herein as “hydrogen reactors” are capable of producing not only hydrinos, but also the other increased binding energy hydrogen species and compounds of the present invention. Hence, the designation “hydrogen reactors” should not be understood as being limiting with respect to the nature of the increased binding energy hydrogen species or compound produced.

According to one aspect of the present invention, novel compounds are formed from hydrino hydride ions and cations wherein the cell further comprises an electron source. Electrons from the electron source contact the hydrinos and react to form hydrino hydride ions. The reactor produces hydride ions having the binding energy of Eq. (58). The cation may be from an added reductant, or a cation present in the cell (such as a cation comprising the catalyst).

In an embodiment, a plasma forms in the hydrogen cell as a result of the energy released from the catalysis of hydrogen. Water vapor may be added to the plasma to increase the hydrogen concentration as shown by Kikuchi et al. [J. Kikuchi, M. Suzuki, H. Yano, and S. Fujimura, Proceedings SPIE-The International Society for Optical Engineering, (1993), 1803 (Advanced Techniques for Integrated Circuit Processing II), pp. 70-76] which is herein incorporated by reference.

### 3. Catalysts

3.1 Atom and Ion Catalysts

In an embodiment, a catalytic system is provided by the ionization of t electrons from a participating species such as an atom, an ion, a molecule, and an ionic or molecular compound to a continuum energy level such that the sum of the ionization energies of the t electrons is approximately m×27.2 eV where m is an integer. One such catalytic system involves cesium. The first and second ionization energies of cesium are 3.89390 eV and 23.15745 eV, respectively. The double ionization (t=2 ) reaction of Cs to Cs²⁺, then, has a net enthalpy of reaction of 27.05135 eV, which is equivalent to m=1 in Eq. (2a).

$$\begin{matrix}27.05135 eV + Cs ( m ) + H [ \frac{{a}_{H}}{p} ] -> {Cs}^{2 +} + 2 {ⅇ}^{-} + H [ \frac{{a}_{H}}{( p + 1 )} ] + [ {( p + 1 )}^{2} - {p}^{2} ] X13 .6 eV & ( 60 ) \\ {Cs}^{2 +} + 2 {ⅇ}^{-} -> Cs ( m ) + 27.05135 eV & ( 61 )\end{matrix}$$

And, the overall reaction is

$$H [ \frac{{a}_{H}}{p} ] -> H [ \frac{{a}_{H}}{( p + 1 )} ] + [ {( p + 1 )}^{2} - {p}^{2} ] X13 .6 eV \qquad ( 62 )$$

Thermal energies may broaden the enthalpy of reaction. The relationship between kinetic energy and temperature is given by

$${E}_{kinetic} = \frac{3}{2} kT \qquad ( 63 )$$

For a temperature of 1200 K, the thermal energy is 0.16 eV, and the net enthalpy of reaction provided by cesium metal is 27.21 eV which is an exact match to the desired energy.

Hydrogen catalysts capable of providing a net enthalpy of reaction of approximately m×27.2 eV where m is an integer to produce hydrino whereby t electrons are ionized from an atom or ion are given infra. A further product of the catalysis is energy and plasma. The atoms or ions given in the first column are ionized to provide the net enthalpy of reaction of m×27.2 eV given in the tenth column where m is given in the eleventh column. The electrons which are ionized are given with the ionization potential (also called ionization energy or binding energy). The ionization potential of the n th electron of the atom or ion is designated by IPₙ and is given by Linde [D. R. Lide, CRC Handbook of Chemistry and Physics, 78 th Edition, CRC Press, Boca Raton, Fla., (1997), p. 10-214 to 10-216] which is herein incorporated by reference. That is for example, Cs+3.89390 eV→Cs⁺+e⁻ and Cs⁺+23.15745 eV→Cs²⁺+e⁻. The first ionization potential, IP₁=3.89390 eV, and the second ionization potential, P₂=23.15745 eV, are given in the second and third columns, respectively. The net enthalpy of reaction for the double ionization of Cs is 27.05135 eV as given in the tenth column, and m=1 in Eq. (2a) as given in the eleventh column.

TABLE 3
Hydrogen Ion or Atom Catalysts

| Catalyst | IP1 | IP2 | IP3 | IP4 | IP5 | IP6 | IP7 | IP8 | Enthalpy | m |
|---|---|---|---|---|---|---|---|---|---|---|
| Li | 5.39172 | 75.6402 | | | | | | | 81.032 | 3 |
| Be | 9.32263 | 18.2112 | | | | | | | 27.534 | 1 |
| Ar | 15.75962 | 27.62967 | 40.74 | | | | | | 84.12929 | 3 |
| Ar | 15.75962 | 27.62967 | 40.74 | 59.81 | 75.02 | | | | 218.95929 | 8 |
| Ar | 15.75962 | 27.62967 | 40.74 | 59.81 | 75.02 | 91.009 | 124.323 | | 434.29129 | 16 |
| K | 4.34066 | 31.63 | 45.806 | | | | | | 81.777 | 3 |
| Ca | 6.11316 | 11.8717 | 50.9131 | 67.27 | | | | | 136.17 | 5 |
| Ti | 6.8282 | 13.5755 | 27.4917 | 43.267 | 99.3 | | | | 190.46 | 7 |
| V | 6.7463 | 14.66 | 29.311 | 46.709 | 65.2817 | | | | 162.71 | 6 |
| Cr | 6.76664 | 16.4857 | 30.96 | | | | | | 54.212 | 2 |
| Mn | 7.43402 | 15.64 | 33.668 | 51.2 | | | | | 107.94 | 4 |
| Fe | 7.9024 | 16.1878 | 30.652 | | | | | | 54.742 | 2 |
| Fe | 7.9024 | 16.1878 | 30.652 | 54.8 | | | | | 109.54 | 4 |
| Co | 7.881 | 17.083 | 33.5 | 51.3 | | | | | 109.76 | 4 |
| Co | 7.881 | 17.083 | 33.5 | 51.3 | 79.5 | | | | 189.26 | 7 |
| Ni | 7.6398 | 18.1688 | 35.19 | 54.9 | 76.06 | | | | 191.96 | 7 |
| Ni | 7.6398 | 18.1688 | 35.19 | 54.9 | 76.06 | 108 | | | 299.96 | 11 |
| Cu | 7.72638 | 20.2924 | | | | | | | 28.019 | 1 |
| Zn | 9.39405 | 17.9644 | | | | | | | 27.358 | 1 |
| Zn | 9.39405 | 17.9644 | 39.723 | 59.4 | 82.6 | 108 | 134 | 174 | 625.08 | 23 |
| As | 9.8152 | 18.633 | 28.351 | 50.13 | 62.63 | 127.6 | | | 297.16 | 11 |
| Se | 9.75238 | 21.19 | 30.8204 | 42.945 | 68.3 | 81.7 | 155.4 | | 410.11 | 15 |
| Kr | 13.9996 | 24.3599 | 36.95 | 52.5 | 64.7 | 78.5 | | | 271.01 | 10 |
| Kr | 13.9996 | 24.3599 | 36.95 | 52.5 | 64.7 | 78.5 | 111 | | 382.01 | 14 |
| Rb | 4.17713 | 27.285 | 40 | 52.6 | 71 | 84.4 | 99.2 | | 378.66 | 14 |
| Rb | 4.17713 | 27.285 | 40 | 52.6 | 71 | 84.4 | 99.2 | 136 | 514.66 | 19 |
| Sr | 5.69484 | 11.0301 | 42.89 | 57 | 71.6 | | | | 188.21 | 7 |
| Nb | 6.75885 | 14.32 | 25.04 | 38.3 | 50.55 | | | | 134.97 | 5 |
| Mo | 7.09243 | 16.16 | 27.13 | 46.4 | 54.49 | 68.8276 | | | 220.10 | 8 |
| Mo | 7.09243 | 16.16 | 27.13 | 46.4 | 54.49 | 68.8276 | 125.664 | 143.6 | 489.36 | 18 |
| Pd | 8.3369 | 19.43 | | | | | | | 27.767 | 1 |
| Sn | 7.34381 | 14.6323 | 30.5026 | 40.735 | 72.28 | | | | 165.49 | 6 |
| Te | 9.0096 | 18.6 | | | | | | | 27.61 | 1 |
| Te | 9.0096 | 18.6 | 27.96 | | | | | | 55.57 | 2 |
| Cs | 3.8939 | 23.1575 | | | | | | | 27.051 | 1 |
| Ce | 5.5387 | 10.85 | 20.198 | 36.758 | 65.55 | | | | 138.89 | 5 |
| Ce | 5.5387 | 10.85 | 20.198 | 36.758 | 65.55 | 77.6 | | | 216.49 | 8 |
| Pr | 5.464 | 10.55 | 21.624 | 38.98 | 57.53 | | | | 134.15 | 5 |
| Sm | 5.6437 | 11.07 | 23.4 | 41.4 | | | | | 81.514 | 3 |
| Gd | 6.15 | 12.09 | 20.63 | 44 | | | | | 82.87 | 3 |
| Dy | 5.9389 | 11.67 | 22.8 | 41.47 | | | | | 81.879 | 3 |
| Pb | 7.41666 | 15.0322 | 31.9373 | | | | | | 54.386 | 2 |
| Pt | 8.9587 | 18.563 | | | | | | | 27.522 | 1 |
| He+ | | 54.4178 | | | | | | | 54.418 | 2 |
| Na+ | | 47.2864 | 71.6200 | 98.91 | | | | | 217.816 | 8 |
| Rb+ | | 27.285 | | | | | | | 27.285 | 1 |
| Fe3+ | | | | 54.8 | | | | | 54.8 | 2 |
| Mo2+ | | | 27.13 | | | | | | 27.13 | 1 |
| Mo4+ | | | | | 54.49 | | | | 54.49 | 2 |
| In3+ | | | | 54 | | | | | 54 | 2 |
| Ar+ | | 27.62967 | | | | | | | 27.62967 | 1 |
| Sr+ | | 11.03 | 42.89 | | | | | | 53.92 | 2 |

In an embodiment, each of the catalysts Rb⁺, K⁺/K⁺, and Sr⁺ maybe formed from the corresponding metal by ionization. The source of ionization may be UV light or a plasma. At least one of a source of UV light and a plasma may be provided by the catalysis of hydrogen with a one or more hydrogen catalysts given in TABLES 1 and 3. The catalysts may also be formed from the corresponding metal by reaction with hydrogen to form the corresponding alkali hydride or by ionization at a hot filament which may also serve to dissociate molecular hydrogen to atomic hydrogen. The hot filament may be a refractory metal such as tungsten or molybdenum operated within a high temperature range such as 1000 to 2800° C.

A catalyst of the present invention can be an increased binding energy hydrogen compound having a net enthalpy of reaction of about

$$\frac{m}{2} \cdot 27 eV ,$$

where m is an integer greater than 1, preferably an integer less than 400, to produce an increased binding energy hydrogen atom having a binding energy of about

$$\frac{13.6 eV}{{( \frac{1}{p} )}^{2}}$$

where p is an integer, preferably an integer from 2 to 200.

In another embodiment of the catalyst of the present invention, hydrinos are formed by reacting an ordinary hydrogen atom with a catalyst having a net enthalpy of reaction of about

$$\frac{m}{2} \cdot 27.2 eV \qquad ( 64 )$$

where m is an integer. It is believed that the rate of catalysis is increased as the net enthalpy of reaction is more closely matched to

$$\frac{m}{2} \cdot 27.2 eV .$$

It has been found that catalysts having a net enthalpy of reaction within ±10%, preferably

$$\pm 5 \% , of \frac{m}{2} \cdot 27.2 eV$$

are suitable for most applications.
In an embodiment, catalysts are identified by the formation of a rt-plasma at low voltage as described in Mills publication R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943 which is incorporated by reference. In another embodiment, a means of identifying catalysts and monitoring the catalytic rate comprises a high resolution visible spectrometer with resolution preferable in the range 1 to 0.01 Å. The identity of a catalysts and the rate of catalysis may be determined by the degree of Doppler broadening of the hydrogen Balmer lines.

3.2 Hydrino Catalysts

In a process called disproportionation, lower-energy hydrogen atoms, hydrinos, can act as catalysts because each of the metastable excitation, resonance excitation, and ionization energy of a hydrino atom is m×27.2 eV. The transition reaction mechanism of a first hydrino atom affected by a second hydrino atom involves the resonant coupling between the atoms of m degenerate multipoles each having 27.21 eV of potential energy [Mills, The Grand Unified Theory of Classical Quantum Mechanics, September 2001 Edition, Chps. 5 and 6, BlackLight Power, Inc., Cranbury, N.J., Distributed by Amazon.com; R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, Vol. 27, No. 3, pp. 301-322]. The energy transfer of m×27.2 eV from the first hydrino atom to the second hydrino atom causes the central field of the first atom to increase by m and its electron to drop m levels lower from a radius of

$$\frac{{a}_{H}}{p}$$

to a radius of

$$\frac{{a}_{H}}{p + m} .$$

The second interacting lower-energy hydrogen is either excited to a metastable state, excited to a resonance state, or ionized by the resonant energy transfer. The resonant transfer may occur in multiple stages. For example, a nonradiative transfer by multipole coupling may occur wherein the central field of the first increases by m, then the electron of the first drops m levels lower from a radius of

$$\frac{{a}_{H}}{p}$$

to a radius of

$$\frac{{a}_{H}}{p + m}$$

with further resonant energy transfer. The energy transferred by multipole coupling may occur by a mechanism that is analogous to photon absorption involving an excitation to a virtual level. Or, the energy transferred by multipole coupling during the electron transition of the first hydrino atom may occur by a mechanism that is analogous to two photon absorption involving a first excitation to a virtual level and a second excitation to a resonant or continuum level [B. J. Thompson, Handbook of Nonlinear Optics, Marcel Dekker, Inc., New York, (1996), pp. 497-548; Y. R. Shen, The Principles of Nonlinear Optics, John Wiley & Sons, New York, (1984), pp. 203-210; B. de Beauvoir, F. Nez, L. Julien, B. Cagnac, F. Biraben, D. Touahri, L. Hilico, O. Acef, A. Clairon, and J. J. Zondy, Physical Review Letters, Vol. 78, No. 3, (1997), pp. 440-443]. The transition energy greater than the energy transferred to the second hydrino atom may appear as a photon in a vacuum medium.

The transition of

$$H [ \frac{{a}_{H}}{p} ] to H [ \frac{{a}_{H}}{p + m} ]$$

induced by a multipole resonance transfer of m·27.21 eV and a transfer of [(p′)²−(p′−m′)²]×13.6 eV−m·27.2 eV with a resonance state

$$H [ \frac{{a}_{H}}{{p}^{′} + {m}^{′}} ]$$

excited in

$$H [ \frac{{a}_{H}}{{p}^{′}} ]$$

is represented by

$$H [ \frac{{a}_{H}}{{p}^{′}} ] + H [ \frac{{a}_{H}}{p} ] -> H [ \frac{{a}_{H}}{{p}^{′} - {m}^{′}} ] + H [ \frac{{a}_{H}}{p + m} ] + [ ( {( p + m )}^{2} - {p}^{2} ) - ( {p}^{′2} - {( {p}^{′} - {m}^{′} )}^{2} ) ] \times 13.6 eV \qquad ( 65 )$$

where p, p′, m, and m′ are integers.

Hydrinos may be ionized during a disproportionation reaction by the resonant energy transfer. A hydrino atom with the initial lower-energy state quantum number p and radius

$$\frac{{a}_{H}}{p}$$

may undergo a transition to the state with lower-energy state quantum number (p+m) and radius

$$( \frac{{a}_{H}}{p + m} )$$

by reaction with a hydrino atom with the initial lower-energy state quantum number m′, initial radius

$$\frac{{a}_{H}}{{m}^{′}} ,$$

and final radius α_{H} that provides a net enthalpy of m×27.2 eV. Thus, reaction of hydrogen-type atom,

$$H [ \frac{{a}_{H}}{p} ] ,$$

with the hydrogen-type atom,

$$H [ \frac{{a}_{H}}{{m}^{′}} ] ,$$

that is ionized by the resonant energy transfer to cause a transition reaction is represented by

$$\begin{matrix}m \times 27.21 eV + H [ \frac{{a}_{H}}{{m}^{′}} ] + H [ \frac{{a}_{H}}{p} ] -> {H}^{+} + {e}^{-} + H [ \frac{{a}_{H}}{( p + m )} ] + [ {( p + m )}^{2} - {p}^{2} - ( {m}^{′2} - 2 m ) ] \times 13.6 eV & ( 66 ) \\ {H}^{+} + {e}^{-} -> H [ \frac{{a}_{H}}{1} ] + 13.6 eV & ( 67 )\end{matrix}$$

And, the overall reaction is

$$H [ \frac{{a}_{H}}{{m}^{′}} ] + H [ \frac{{a}_{H}}{p} ] -> H [ \frac{{a}_{H}}{1} ] + H [ \frac{{a}_{H}}{( p + m )} ] + [ 2 pm + {m}^{2} - {m}^{′2} ] \times 13.6 eV + 13.6 eV \qquad ( 68 )$$

### 4. Adjustment of Catalysis Rate

It is believed that the rate of catalysis is increased as the net enthalpy of reaction is more closely matched to m·27.2 eV where m is an integer. An embodiment of the hydrogen reactor for producing increased binding energy hydrogen compounds of the invention further comprises an electric or magnetic field source. The electric or magnetic field source may be adjustable to control the rate of catalysis. Adjustment of the electric or magnetic field provided by the electric or magnetic field source may alter the continuum energy level of a catalyst whereby one or more electrons are ionized to a continuum energy level to provide a net enthalpy of reaction of approximately m×27.2 eV. The alteration of the continuum energy may cause the net enthalpy of reaction of the catalyst to more closely match m·27.2 eV. Preferably, the electric field is within the range of 0.01-10⁶ V/m, more preferably 0.1-10⁴ V/m, and most preferably 1-10³ V/m. Preferably, the magnetic flux is within the range of 0.01-50 T. A magnetic field may have a strong gradient. Preferably, the magnetic flux gradient is within the range of 10⁻⁴-10² Tcm⁻¹ and more preferably 10⁻³-1 Tcm⁻¹.

In an embodiment, the electric field E and magnetic field B are orthogonal to cause an EXB electron drift. The EXB drift may be in a direction such that energetic electrons produced by hydrogen catalysis dissipate a minimum amount of power due to current flow in the direction of the applied electric field which may be adjustable to control the rate of hydrogen catalysis.

In an embodiment of the energy cell, a magnetic field confines the electrons to a region of the cell such that interactions with the wall are reduced, and the electron energy is increased. The field may be a solenoidal field or a magnetic mirror field. The field may be adjustable to control the rate of hydrogen catalysis.

In an embodiment, the electric field such as a radio frequency field produces minimal current. In another embodiment, a gas which may be inert such as a noble gas is added to the reaction mixture to decrease the conductivity of the plasma produced by the energy released from the catalysis of hydrogen. The conductivity is adjusted by controlling the pressure of the gas to achieve an optimal voltage that controls the rate of catalysis of hydrogen. In another embodiment, a gas such as an inert gas may be added to the reaction mixture which increases the percentage of atomic hydrogen versus molecular hydrogen.

For example, the cell may comprise a hot filament that dissociates molecular hydrogen to atomic hydrogen and may further heat a hydrogen dissociator such as transition elements and inner transition elements, iron, platinum, palladium, zirconium, vanadium, nickel, titanium, Sc, Cr, Mn, Co, Cu, Zn, Y, Nb, Mo, Tc, Ru, Rh, Ag, Cd, La, Hf, Ta, W, Re, Os, Ir, Au, Hg, Ce, Pr, Nd, Pm, Sm, Eu, Gd, Th, Dy, Ho, Er, Tm, Vb, Lu, Th, Pa, U, activated charcoal (carbon), and intercalated Cs carbon (graphite). The filament may further supply an electric field in the cell of the reactor. The electric field may alter the continuum energy level of a catalyst whereby one or more electrons are ionized to a continuum energy level to provide a net enthalpy of reaction of approximately m×27.2 eV. In another embodiment, an electric field is provided by electrodes charged by a variable voltage source. The rate of catalysis may be controlled by controlling the applied voltage which determines the applied field which controls the catalysis rate by altering the continuum energy level.

In another embodiment of the hydrogen reactor, the electric or magnetic field source ionizes an atom or ion to provide a catalyst having a net enthalpy of reaction of approximately m×27.2 eV. For examples, potassium metal is ionized to K⁺, rubidium metal is ionized to Rb⁺, or strontium metal is ionized to Sr+to provide the catalyst. The electric field source may be a hot filament whereby the hot filament may also dissociate molecular hydrogen to atomic hydrogen.

### 5. Noble Gas Catalysts and Products

In an embodiment of the hydrogen power and plasma cell, reactor, and power converter comprising an energy cell for the catalysis of atomic hydrogen to form novel hydrogen species and compositions of matter comprising new forms of hydrogen of the present invention, the catalyst comprises a mixture of a first catalyst and a source of a second catalyst. In an embodiment, the first catalyst produces the second catalyst from the source of the second catalyst. In an embodiment, the energy released by the catalysis of hydrogen by the first catalyst produces a plasma in the energy cell. The energy ionizes the source of the second catalyst to produce the second catalyst. The second catalyst may be one or more ions produced in the absence of a strong electric field as typically required in the case of a glow discharge. The weak electric field may increase the rate of catalysis of the second catalyst such that the enthalpy of reaction of the catalyst matches m×27.2 eV to cause hydrogen catalysis. In embodiments of the energy cell, the first catalyst is selected from the group of catalyst given in TABLES 1 and 3 such as potassium and strontium, the source of the second catalyst is selected from the group of helium and argon and the second catalyst is selected from the group of He⁺ and Ar⁺ wherein the catalyst ion is generated from the corresponding atom by a plasma created by catalysis of hydrogen by the first catalyst. For examples, 1.) the energy cell contains strontium and argon wherein hydrogen catalysis by strontium produces a plasma containing Ar⁺ which serves as a second catalyst (Eqs. (15-17)) and 2.) the energy cell contains potassium and helium wherein hydrogen catalysis by potassium produces a plasma containing He⁺ which serves as a second catalyst (Eqs. (12-14)). In an embodiment, the pressure of the source of the second catalyst is in the range of about 1 millitorr to about one atmosphere. The hydrogen pressure is in the range of about 1 millitorr to about one atmosphere. In a preferred embodiment, the total pressure is in the range of about 0.5 torr to about 2 torr. In an embodiment, the ratio of the pressure of the source of the second catalyst to the hydrogen pressure is greater than one. In a preferred embodiment, hydrogen is about 0.1% to about 99%, and the source of the second catalyst comprises the balance of the gas present in the cell. More preferably, the hydrogen is in the range,of about 1% to about 5% and the source of the second catalyst is in the range of about 95% to about 99%. Most preferably, the hydrogen is about 5% and the source of the second catalyst is about 95%. These pressure ranges are representative examples and a skilled person will be able to practice this invention using a desired pressure to provide a desired result.

In an embodiment of the power cell and power converter the catalyst comprises at least one selected from the group of He⁺, Ne⁺, and Ar⁺ wherein the ionized catalyst ion is generated from the corresponding atom by a plasma created by methods such as a glow discharge or inductively couple microwave discharge. Preferably, the corresponding reactor such as a discharge cell or hydrogen plasma torch reactor has a region of low electric field strength such that the enthalpy of reaction of the catalyst matches m×27.2 eV to cause hydrogen catalysis. In one embodiment, the reactor is a discharge cell having a hollow anode as described by Kuraica and Konjevic [Kuraica, M., Konjevic, N., Physical Review A, Volume 46, No. 7, October (1992), pp. 4429-4432]. In another embodiment, the reactor is a discharge cell having a hollow cathode such as a central wire or rod anode and a concentric hollow cathode such as a stainless or nickel mesh. In a preferred embodiment, the cell is a microwave cell wherein the catalyst is formed by a microwave plasma.

In an embodiment of the plasma cell wherein the catalyst is a cation such as at least one selected from the group of He⁺ and Ar⁺ an increased binding energy hydrogen compound, iron hydrino hydride, is formed as hydrino atoms react with iron present in the cell. The source of iron may be from a stainless steel cell. In another embodiment, an additional catalyst such as strontium, cesium, or potassium is present.

### 6. Plasma and Light Source from Hydrogen Catalysis

Typically the emission of vacuum ultraviolet light from hydrogen gas is achieved using discharges at high voltage, synchrotron devices, high power inductively coupled plasma generators, or a plasma is created and heated to extreme temperatures by RF coupling (e.g. >10⁶ K) with confinement provided by a toroidal magnetic field. Observation of intense extreme ultraviolet (EUV) emission at low temperatures (e.g. ≈10³ K) from atomic hydrogen generated at a tungsten filament that heated a titanium dissociator and certain gaseous atom or ion catalysts of the present invention vaporized by filament heating has been reported previously [R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943]. Potassium, cesium, and strontium atoms and Rb⁺ ionize at integer multiples of the potential energy of atomic hydrogen formed the low temperature, extremely low voltage plasma called a resonance transfer or rt-plasma having strong EUV emission. Similarly, the ionization energy of Ar⁺ is 27.63 eV, and the emission intensity of the plasma generated by atomic strontium increased significantly with the introduction of argon gas only when Ar⁺ emission was observed [R. Mills, “Spectroscopic Identification of a Novel Catalytic Reaction of Atomic Hydrogen and the Hydride Ion Product”, Int. J. Hydrogen Energy, Vol. 26, No. 10, (2001), pp. 1041-1058]. In contrast, the chemically similar atoms, sodium, magnesium and barium, do not ionize at integer multiples of the potential energy of atomic hydrogen did not form a plasma and caused no emission.

For further characterization, the width of the 656.3 nm Balmer α line emitted from microwave and glow discharge plasmas of hydrogen alone, strontium or magnesium with hydrogen, or helium, neon, argon, or xenon with 10% hydrogen was recorded with a high resolution visible spectrometer [R. L. Mills, P. Ray, B. Dhandapani, R. M. Mayo, J. He, “Comparison of Excessive Balmer α Line Broadening of Glow Discharge and Microwave Hydrogen Plasmas with Certain Catalysts”, J. of Applied Physics, (2002), Vol. 92, No. 12, pp. 7008-7022.]. It was found that the strontium-hydrogen microwave plasma showed a broadening similar to that observed in the glow discharge cell of 27-33 eV; whereas, in both sources, no broadening was observed for magnesium-hydrogen. With noble-gas hydrogen mixtures, the trend of broadening with the particular noble gas was the same for both sources, but the magnitude of broadening was dramatically different. The microwave helium-hydrogen and argon-hydrogen plasmas showed extraordinary broadening corresponding to an average hydrogen atom temperature of 110-130 eV and 180-210 eV, respectively. The corresponding results from the glow discharge plasmas were 30-35 eV and 33-38 eV, respectively. Whereas, plasmas of pure hydrogen, neon-hydrogen, krypton-hydrogen, and xenon-hydrogen maintained in either source showed no excessive broadening corresponding to an average hydrogen atom temperature of ≈3 eV. In the case of the helium-hydrogen mixture and argon-hydrogen mixture microwave plasmas, the electron temperature Tₑ was measured from the ratio of the intensity of the He 501.6 nm line to that of the He 492.2 line and the ratio of the intensity of the Ar 104.8 nm line to that of the Ar 420.06 nm line, respectively. Similarly, the average electron temperature for helium-hydrogen and argon-hydrogen plasmas were high, 28,000 K and 11,600 K, respectively, whereas, the corresponding temperatures of helium and argon alone were only 6800 K and 4800 K, respectively. Stark broadening or acceleration of charged species due to high fields (e.g. over 10 kV/cm) can not be invoked to explain the microwave results since no high field was observationally present. Rather, the results may be explained by a resonant energy transfer between atomic hydrogen and atomic strontium, Ar⁺, or He²⁺ which ionize at an integer multiple of the potential energy of atomic hydrogen.

A preferred embodiment of the power cell produces a plasma and may also comprise a light source of at least one of extreme ultraviolet, ultraviolet, visible, infrared, microwave, or radio wave radiation.

The light source of the present invention may comprise at least one of the gas, gas discharge, plasma torch, or microwave plasma cell wherein ions or excimers are effectively formed that serve as catalysts from a source of catalyst such as He⁺, He₂*, Ne₂*, Ne⁺, Ne⁺/H⁺ or Ar⁺ catalysts from helium, helium, neon, neon-hydrogen mixture, and argon gases, respectively. The light may be largely monochromatic light such as line emission of the Lyman series such as Lyman α or Lyman β.

### 7. Energy Reactor

An energy reactor 50, in accordance with the invention, is shown in FIG. 1 and comprises a vessel 52 which contains an energy reaction mixture 54, a heat exchanger 60, and a power converter such as a steam generator 62 and turbine 70. The heat exchanger 60 absorbs heat released by the catalysis reaction, when the reaction mixture, comprised of hydrogen and a catalyst reacts to form lower-energy hydrogen. The heat exchanger exchanges heat with the steam generator 62 which absorbs heat from the exchanger 60 and produces steam. The energy reactor 50 further comprises a turbine 70 which receives steam from the steam generator 62 and supplies mechanical power to a power generator 80 which converts the steam energy into electrical energy, which can be received by a load 90 to produce work or for dissipation.

The energy reaction mixture 54 comprises an energy releasing material 56 including a source of hydrogen isotope atoms or a source of molecular hydrogen isotope, and a source of catalyst 58 which resonantly remove approximately m×27.21 eV to form lower-energy atomic hydrogen and approximately m×48.6 eV to form lower-energy molecular hydrogen where m is an integer wherein the reaction to lower energy states of hydrogen occurs by contact of the hydrogen with the catalyst. For example, He⁺ fulfills the catalyst criterion—a chemical or physical process with an enthalpy change equal to an integer multiple of 27.2 eV since it ionizes at 54.417 eV which is 2·27.2 eV. The catalysis releases energy in a form such as heat and lower-energy hydrogen isotope atoms and/or molecules.

The source of hydrogen can be hydrogen gas, dissociation of water including thermal dissociation, electrolysis of water, hydrogen from hydrides, or hydrogen from metal-hydrogen solutions. In all embodiments, the source of catalysts can be one or more of an electrochemical, chemical, photochemical, thermal, free radical, sonic, or nuclear reaction(s) or inelastic photon or particle scattering reaction(s). In the latter two cases, the present invention of an energy reactor comprises a particle source 75b and/or photon source 75a to supply the catalyst. In these cases, the net enthalpy of reaction supplied corresponds to a resonant collision by the photon or particle. In a preferred embodiment of the energy reactor shown in FIG. 1, atomic hydrogen is formed from molecular hydrogen by a photon source 75a such as a microwave source or a UV source.

The photon source may also produce photons of at least one energy of approximately m×27.21 eV,

$$\frac{m}{2} \times 27.21 eV ,$$

or 40.8 eV causes the hydrogen atoms undergo a transition to a lower energy state. In another preferred embodiment, a photon source 75a producing photons of at least one energy of approximately m×48.6 eV, 95.7 eV, or m×31.94 eV causes the hydrogen molecules to undergo a transition to a lower energy state. In all reaction mixtures, a selected external energy device 75, such as an electrode may be used to supply an electrostatic potential or a current (magnetic field) to decrease the activation energy of the reaction. In another embodiment, the mixture 54, further comprises a surface or material to dissociate and/or absorb atoms and/or molecules of the energy releasing material 56. Such surfaces or materials to dissociate and/or absorb hydrogen, deuterium, or tritium comprise an element, compound, alloy, or mixture of transition elements and inner transition elements, iron, platinum, palladium, zirconium, vanadium, nickel, titanium, Sc, Cr, Mn, Co, Cu, &n, Y, Nb, Mo, Tc, Ru, Rh, Ag, Cd, La, Hf, Ta, W, Re, Os, Ir, Au, Hg, Ce, Pr, Nd, Pm, Sm, Eu, Gd, Th, Dy, Ho, Er, Tm, Vb, Lu, Th, Pa, U, activated charcoal (carbon), and intercalated Cs carbon (graphite).

In an embodiment, a catalyst is provided by the ionization of t electrons from an atom or ion to a continuum energy level such that the sum of the ionization energies of the t electrons is approximately m×27.2 eV where t and m are each an integer. A catalyst may also be provided by the transfer of t electrons between participating ions. The transfer of t electrons from one ion to another ion provides a net enthalpy of reaction whereby the sum of the ionization energy of the electron donating ion minus the ionization energy of the electron accepting ion equals approximately m×27.2 eV where t and m are each an integer.

In a preferred embodiment, a source of hydrogen atom catalyst comprises a catalytic material 58, that typically provide a net enthalpy of approximately m×27.21 eV plus or minus 1 eV. In a preferred embodiment, a source of hydrogen molecule catalysts comprises a catalytic material 58, that typically provide a net enthalpy of reaction of approximately m×48. 6 eV plus or minus 5 eV. The catalysts include those given in TABLES 1 and 3 and the atoms, ions, molecules, and hydrinos described in Mills Prior Publications which are incorporated herein by reference.

A further embodiment is the vessel 52 containing a catalysts in the molten, liquid, gaseous, or solid state and a source of hydrogen including hydrides and gaseous hydrogen. In the case of a reactor for catalysis of hydrogen atoms, the embodiment further comprises a means to dissociate the molecular hydrogen into atomic hydrogen including an element, compound, alloy, or mixture of transition elements, inner transition elements, iron, platinum, palladium, zirconium, vanadium, nickel, titanium, Sc, Cr, Mn, Co, Cu, Zn, Y, Nb, Mo, Tc, Ru, Rh, Ag, Cd, La, Hf, Ta, W, Re, Os, Ir, Au, Hg, Ce, Pr, Nd, Pm, Sm, Eu, Gd, Th, Dy, Ho, Er, Tm, Vb, Lu, Th, Pa, U, activated charcoal (carbon), and intercalated Cs carbon (graphite) or electromagnetic radiation including UV light provided by photon source 75. Alternatively, the hydrogen is dissociated in a plasma.

The present invention of an electrolytic cell energy reactor, plasma electrolysis reactor, barrier electrode reactor, RF plasma reactor, pressurized gas energy reactor, gas discharge energy reactor, microwave cell energy reactor, and a combination of a glow discharge cell and a microwave and or RF plasma reactor of the present invention comprises: a source of hydrogen; one of a solid, molten, liquid, and gaseous source of catalyst; a vessel containing hydrogen and the catalyst wherein the reaction to form lower-energy hydrogen occurs by contact of the hydrogen with the catalyst; and a means for removing the lower-energy hydrogen product. The present energy invention is further described in Mills Prior Publications which are incorporated herein by reference.

In a preferred embodiment, the catalysis of hydrogen produces a plasma. The plasma may also be at least partially maintained by a microwave generator wherein the microwaves are tuned by a tunable microwave cavity, carried by a waveguide, and are delivered to the reaction chamber though an RF transparent window or antenna. The microwave frequency may be selected to efficiently form atomic hydrogen from molecular hydrogen. It may also effectively form ions or excimers that serve as catalysts from a source of catalyst such as He⁺, He₂*, Ne₂*, Ne⁺/H⁺ or Ar⁺ catalysts from helium, helium, neon, neon-hydrogen mixture, and argon gases, respectively. In an embodiment, the cell provides a catalyst for a source of catalyst such as He⁺, Ar⁺, and Ne⁺ from helium, argon, and neon gas, respectively. In embodiments, cell types may be combined for based on specific functions. For example, a glow discharge cell which is very effective at producing catalyst for a source of catalyst such as He⁺, Ar⁺, and Ne⁺ from helium, argon, and neon gas, respectively, may be combined with a reactor such as a microwave reactor that is well suited for the production of atomic hydrogen to react with the catalyst.

### 8. Hydrogen Microwave Plasma and Power Cell and Diamond Reactor

A hydrogen microwave plasma and power cell and reactor of the present invention for the catalysis of atomic hydrogen to form increased-binding-energy-hydrogen species and increased-binding-energy-hydrogen compounds comprises a vessel having a chamber capable of containing a vacuum or pressures greater than atmospheric, a source of atomic hydrogen, a source of microwave power to form a plasma, and a catalyst capable of providing a net enthalpy of reaction of m/2·27.2±0.5 eV where m is an integer, preferably m is an integer less than 400. The source of microwave power may comprise a microwave generator, a tunable microwave cavity, waveguide, and an antenna. Alternatively, the cell may further comprise a means to at least partially convert the power for the catalysis of atomic hydrogen to microwaves to maintain the plasma.

### 9. Hydrogen Capacitively and Inductively Coupled RF Plasma and Power Cell and Diamond Reactor

A hydrogen Capacitively and/or inductively coupled radio frequency (RF) plasma and power cell and reactor of the present invention for the catalysis of atomic hydrogen to form increased-binding-energy-hydrogen species and increased-binding-energy-hydrogen compounds comprises a vessel having a chamber capable of containing a vacuum or pressures greater than atmospheric, a source of atomic hydrogen, a source of RF power to form a plasma, and a catalyst capable of providing a net enthalpy of reaction of m/2·27.2±0.5 eV where m is an integer, preferably m is an integer less than 400. The cell may further comprise at least two electrodes and an RF generator wherein the source of RF power may comprise the electrodes driven by the RF generator. Alternatively, the cell may further comprise a source coil which may be external to a cell wall which permits RF power to couple to the plasma formed in the cell, a conducting cell wall which may be grounded and a RF generator which drives the coil which may inductively and/or capacitively couple RF power to the cell plasma.

### 10. Diamond Synthesis

A reactor of the present invention for the synthesis of diamond, hydrogenated diamond, diamond-like carbon, hydrogenated diamond-like carbon or related materials in crystalline form or as thin films comprises a hydrino hydride reactor and a source of carbon. The carbon may be at least one of the group of glassy carbon, graphitic carbon, pyrolytic carbon, atomic carbon, or hydrocarbons. In an embodiment, the carbon or carbon precursor is supplied to the reactor as a solid. The solid may be placed in the reactor, and the hydrogen catalysis reaction is carried with the carbon present. In another embodiment, the source of carbon is supplied as a gas from a gas supply line. In another embodiment, carbon is vapor deposited on a desired target such as a substrate in the presence of the hydrogen catalysis reaction. Carbon and carbon precursors such as hydrocarbons may supplied to the hydrogen catalysis reaction to form diamond by methods known to those skilled in the art such as by ion implantation, epitaxy, or vacuum deposition. In a preferred embodiment, the formation of diamond films may be by vapor deposition of carbon in the presence of a helium-hydrogen plasma or an argon-hydrogen plasma wherein He⁺ or Ar⁺ serves as a catalyst, respectively.

### III. BRIEF DESCRIPTION OF THE DRAWINGS

FIG. 1 is a schematic drawing of a power system comprising a hydrogen power and plasma cell and diamond reactor in accordance with the present invention;

FIG. 2 is a schematic drawing of a hydrogen plasma electrolytic power and plasma cell and diamond reactor in accordance with the present invention;

FIG. 3 is a schematic drawing of a hydrogen gas power and plasma cell and diamond reactor in accordance with the present invention;

FIG. 4 is a schematic drawing of a hydrogen gas discharge power and plasma cell and diamond reactor in accordance with the present invention;

FIG. 5 is a schematic drawing of a hydrogen RF barrier electrode gas discharge power and plasma cell and diamond reactor in accordance with the present invention;

FIG. 6 is a schematic drawing of a hydrogen plasma torch power and plasma cell and diamond reactor in accordance with the present invention;

FIG. 7 is a schematic drawing of another hydrogen plasma torch power and plasma cell and diamond reactor in accordance with the present invention;

FIG. 8 is a schematic drawing of a hydrogen microwave power and plasma cell and diamond reactor in accordance with the present invention, and

FIG. 9 is a schematic drawing of a microwave discharge cell diamond reactor in accordance with the present invention.

### IV. DETAILED DESCRIPTION OF THE INVENTION

The following preferred embodiments of the invention disclose numerous property ranges, including but not limited to, voltage, current, pressure, temperature, microwave power, and the like, which are merely intended as illustrative examples. Based on the detailed written description, one skilled in the art would easily be able to practice this invention within other property ranges to produce the desired result without undue experimentation.

### 1. Hydrogen Power and Plasma Cell and Diamond Reactor

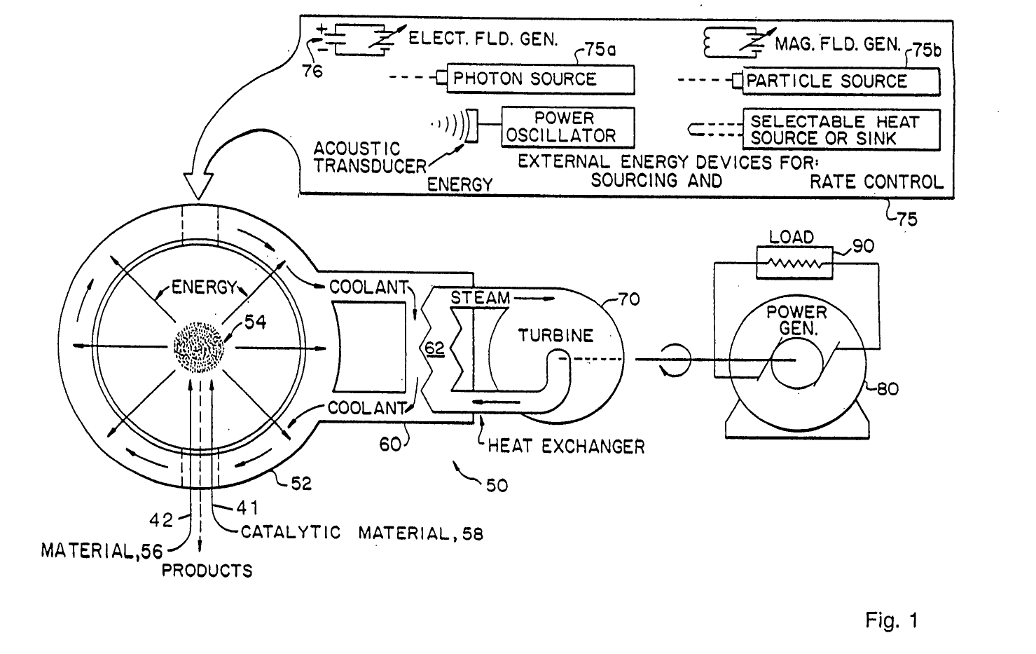

One embodiment of the present invention involves a power system comprising a hydrogen power and plasma cell and diamond reactor shown in FIG. 1. The hydrogen power and plasma cell and diamond reactor comprises a vessel 52 containing a catalysis mixture 54. The catalysis mixture 54 comprises a source of atomic hydrogen 56 supplied through hydrogen supply passage 42 and a catalyst 58 supplied through catalyst supply passage 41. Catalyst 58 has a net enthalpy of reaction of about

$$\frac{m}{2} \cdot 27.21 \pm 0.5 eV ,$$

where m is an integer, preferably an integer less than 400. The catalysis involves reacting atomic hydrogen from the source 56 with the catalyst 58 to form lower-energy hydrogen “hydrinos” and produce power. The hydrogen reactor may further include an electron source 70 for contacting hydrinos with electrons, to reduce the hydrinos to hydrino hydride ions.

The source of hydrogen can be hydrogen gas, water, ordinary hydride, or metal-hydrogen solutions. The water may be dissociated to form hydrogen atoms by, for example, thermal dissociation or electrolysis. According to one embodiment of the invention, molecular hydrogen is dissociated into atomic hydrogen by a molecular hydrogen dissociating catalyst. Such dissociating catalysts include, for example, noble metals such as palladium and platinum, refractory metals such as molybdenum and tungsten, transition metals such as nickel and titanium, inner transition metals such as niobium and zirconium, and other such materials listed in the Prior Mills Publications.

According to another embodiment of the invention, a photon source such as a microwave or UV photon source dissociates hydrogen molecules to hydrogen atoms.

In the hydrogen power and plasma cell and diamond reactor embodiments of the present invention, the means to form hydrinos can be one or more of an electrochemical, chemical, photochemical, thermal, free radical, sonic, or nuclear reaction(s), or inelastic photon or particle scattering reaction(s). In the latter two cases, the hydrogen reactor comprises a particle source 75b and/or photon source 75a as shown in FIG. 1, to supply the reaction as an inelastic scattering reaction. In one embodiment of the hydrogen reactor, the catalyst in the molten, liquid, gaseous, or solid state includes those given in TABLES 1 and 3 and those given in the Tables of the Prior Mills Publications (e.g. TABLE 4 of PCT/US90/01998 and pages 25-46, 80-108 of PCT/US94/02219).

When the catalysis occurs in the gas phase, the catalyst may be maintained at a pressure less than atmospheric, preferably in the range about 10 millitorr to about 100 torr. The atomic and/or molecular hydrogen reactant is also maintained at a pressure less than atmospheric, preferably in the range about 10 millitorr to about 100 torr. However, if desired, higher pressures even greater than atmospheric can be used.

The hydrogen power and plasma cell and diamond reactor comprises the following: a source of atomic hydrogen; at least one of a solid, molten, liquid, or gaseous catalyst for generating hydrinos; and a vessel for containing the atomic hydrogen and the catalyst. Methods and apparatus for producing hydrinos, including a listing of effective catalysts and sources of hydrogen atoms, are described in the Prior Mills Publications. Methodologies for identifying hydrinos are also described. The hydrinos so produced may react with the electrons from a reductant to form hydrino hydride ions.

The power system may further comprise a source of electric field 76 which can be used to adjust the rate of hydrogen catalysis. It may further focus ions in the cell. It may further impart a drift velocity to ions in the cell. The cell may comprise a source of microwave power, which is generally known in the art, such as traveling wave tubes, klystrons, magnetrons, cyclotron resonance masers, gyrotrons, and free electron lasers. The present power cell may be an internal source of microwaves wherein the plasma generated from the hydrogen catalysis reaction may be magnetized to produce microwaves.

1.1 Hydrogen Plasma Electrolysis Power and Plasma Cell and Diamond Reactor

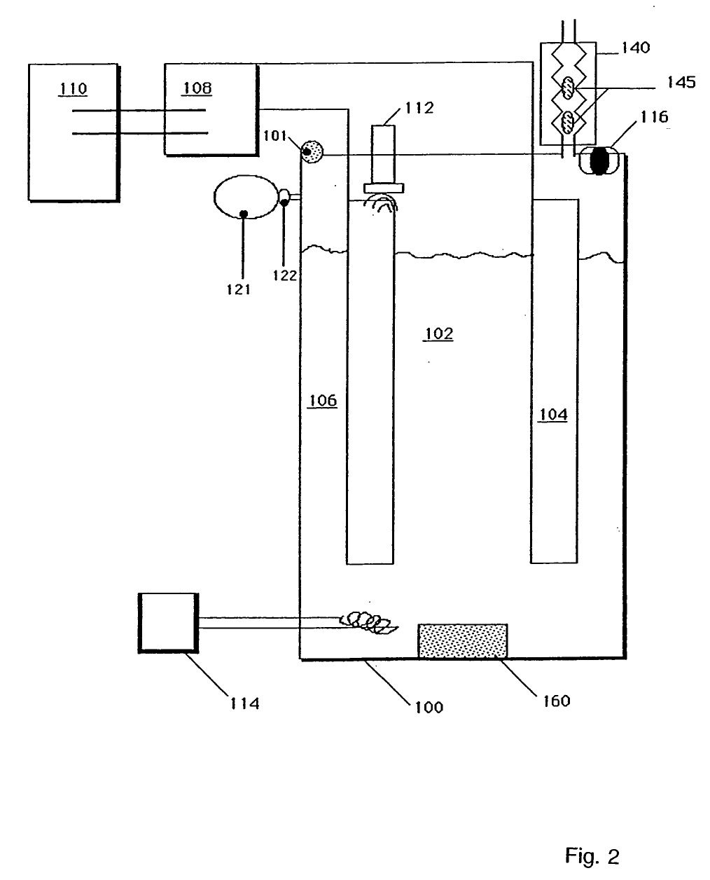

A hydrogen plasma electrolytic power cell and diamond reactor of the present invention to make lower-energy hydrogen compounds comprises an electrolytic cell forming the reaction vessel 52 of FIG. 1, including a molten electrolytic cell. The electrolytic cell 100 is shown generally in FIG. 2. An electric current is passed through the electrolytic solution 102 having a catalyst by the application of a voltage to an anode 104 and cathode 106 by the power controller 108 powered by the power supply 110. Ultrasonic or mechanical energy may also be imparted to the cathode 106 and electrolytic solution 102 by vibrating means 112. Heat can be supplied to the electrolytic solution 102 by heater 114. The pressure of the electrolytic cell 100 can be controlled by pressure regulator means 116 where the cell can be closed. The reactor further comprises a means 101 that removes the (molecular) lower-energy hydrogen such as a selective venting valve to prevent the exothermic shrinkage reaction from coming to equilibrium.

In an embodiment, the plasma electrolytic cell is further supplied with hydrogen from hydrogen source 121 where the over pressure can be controlled by pressure control means 122 and 116. An embodiment of the electrolytic cell energy reactor, comprises a reverse fuel cell geometry which removes the lower-energy hydrogen under vacuum. The reaction vessel may be closed except for a connection to a condensor 140 on the top of the vessel 100. The cell may be operated at a boil such that the steam evolving from the boiling electrolyte 102 can be condensed in the condenser 140, and the condensed water can be returned to the vessel 100. The lower-energy state hydrogen can be vented through the top of the condensor 140. In one embodiment, the condensor contains a hydrogen/oxygen recombiner 145 that contacts the evolving electrolytic gases. The hydrogen and oxygen are recombined, and the resulting water can be returned to the vessel 100. The heat released from the catalysis of hydrogen and the heat released due to the recombination of the electrolytically generated normal hydrogen and oxygen can be removed by a heat exchanger 60 of FIG. 1 which can be connected to the condensor 140.

Hydrino atoms form at the cathode 106 via contact of the catalyst of electrolyte 102 with the hydrogen atoms generated at the cathode 106. The electrolytic cell hydrogen reactor apparatus may further comprises a source of electrons in contact with the hydrinos generated in the cell, to form hydrino hydride ions. The hydrinos are reduced (i.e. gain the electron) in the electrolytic cell to hydrino hydride ions. Reduction occurs by contacting the hydrinos with other element 160 such as a consumable reductant added to the cell from an outside source. A compound may form in the electrolytic cell between the hydrino hydride ions and cations. The cations may comprise a cation of an added reductant, or a cation of the electrolyte (such as a cation comprising the catalyst).

A hydrogen plasma forming electrolytic power cell and reactor of the present invention for the catalysis of atomic hydrogen to form increased-binding-energy-hydrogen species and increased-binding-energy-hydrogen compounds comprises a vessel, a cathode, an anode, an electrolyte, a high voltage electrolysis power supply, and a catalyst capable of providing a net enthalpy of reaction of m/2·27.2±0.5 eV where m is an integer. Preferably m is an integer less than 400. In an embodiment, the voltage is in the range of about 10 V to 50 kV and the current density may be high such as in the range of about 1 to 100 A/cm² or higher. In an embodiment, K⁺ is reduced to potassium atom which serves as the catalyst. The cathode of the cell may be tungsten such as a tungsten rod, and the anode of cell of may be platinum. The catalysts of the cell may comprise at least one selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Sr⁺, Fe³⁺, Mo²⁺, Mo⁴⁺, and In³⁺. The catalyst of the cell of may be formed from a source of catalyst. The source of catalyst that forms the catalyst may comprise at least one selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Sr⁺, Fe³⁺, Mo²⁺, Mo⁴⁺, In³⁺ and K⁺/K⁺ alone or comprising compounds. The source of catalyst may comprise a compound that provides K⁺ that is reduced to the catalyst potassium atom during electrolysis.

The compound of formed comprises

(a) at least one neutral, positive, or negative increased binding energy hydrogen species having a binding energy
(i) greater than the binding energy of the corresponding ordinary hydrogen species, or
(ii) greater than the binding energy of any hydrogen species for which the corresponding ordinary hydrogen species is unstable or is not observed because the ordinary hydrogen species' binding energy is less than thermal energies at ambient conditions, or is negative; and

(b) at least one other element.

The increased binding energy hydrogen species may be selected from the group consisting of Hₙ, Hₙ⁻, and Hₙ⁺ where n is a positive integer, with the proviso that n is greater than 1 when H has a positive charge. The compound formed may be characterized in that the increased binding energy hydrogen species is selected from the group consisting of (a) hydride ion having a binding energy that is greater than the binding of ordinary hydride ion (about 0.8 eV) for p=2 up to 23 in which the binding energy is represented by

$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {ⅇ}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$

where p is an integer greater than one; (b) hydrogen atom having a binding energy greater than about 13.6 eV; (c) hydrogen molecule having a first binding energy greater than about 15.3 eV; and (d) molecular hydrogen ion having a binding energy greater than about 16.3 eV. The compound may be characterized in that the increased binding energy hydrogen species is a hydride ion having a binding energy of about 3, 6.6, 11.2, 16.7, 22.8, 29.3, 36.1, 42.8, 49.4, 55.5, 61.0, 65.6, 69.2, 71.6, 72.4, 71.6, 68.8, 64.0, 56.8, 47.1, 34.7, 19.3, and 0.69 eV. The compound may characterized in that the increased binding energy hydrogen species is a hydride ion having the binding energy:

$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {ⅇ}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$

where p is an integer greater than one. The compound may characterized in that the increased binding energy hydrogen species is selected from the group consisting of

(a) a hydrogen atom having a binding energy of about

$$\frac{13.6 eV}{{( \frac{1}{p} )}^{2}}$$

where p is an integer,

(b) an increased binding energy hydride ion (H⁻) having a binding energy of about

$$\frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {ⅇ}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) ;$$

(c) an increased binding energy hydrogen species H₄⁺(1/p);

(d) an increased binding energy hydrogen species trihydrino molecular ion, H₃⁺(1/p), having a binding energy of about

$$\frac{22.6}{{( \frac{1}{p} )}^{2}} eV$$

where p is an integer,

(e) an increased binding energy hydrogen molecule having a binding energy of about

$$\frac{15.3}{{( \frac{1}{p} )}^{2}} eV ; and$$

(f) an increased binding energy hydrogen molecular ion with a binding energy of about

$$\frac{16.3}{{( \frac{1}{p} )}^{2}} eV .$$

1.2 Hydrogen Gas Power and Plasma Cell and Diamond Reactor

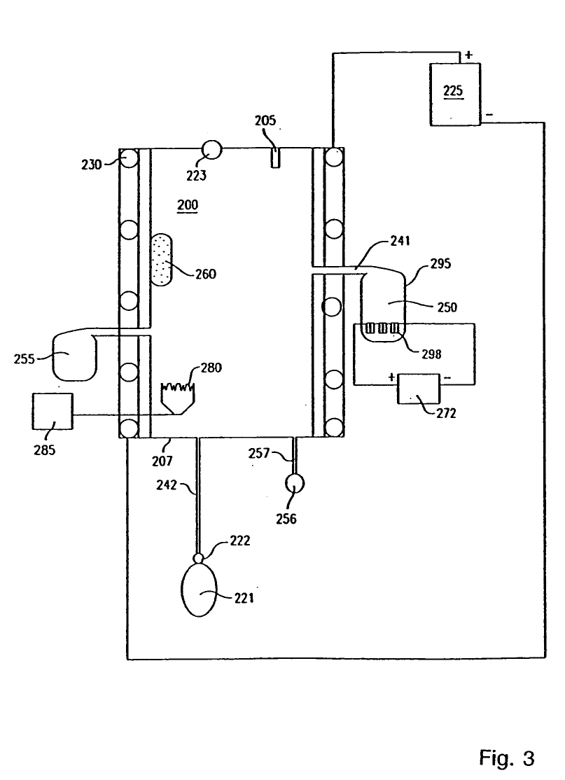

According to an embodiment of the invention, a reactor for producing hydrinos, plasma, power and diamonds may take the form of a hydrogen gas cell. A gas cell hydrogen reactor of the present invention is shown in FIG. 3. Reactant hydrinos are provided by a catalytic reaction with a catalyst such as at least one of those given in TABLES 1 and 3 and/or a by a disproportionation reaction. Catalysis may occur in the gas phase.

The reactor of FIG. 3 comprises a reaction vessel 207 having a chamber 200 capable of containing a vacuum or pressures greater than atmospheric. A source of hydrogen 221 communicating with chamber 200 delivers hydrogen to the chamber through hydrogen supply passage 242. A controller 222 is positioned to control the pressure and flow of hydrogen into the vessel through hydrogen supply passage 242. A pressure sensor 223 monitors pressure in the vessel. A vacuum pump 256 is used to evacuate the chamber through a vacuum line 257. The apparatus may further comprise a source of electrons in contact with the hydrinos to form hydrino hydride ions.

In an embodiment, the source of hydrogen 221 communicating with chamber 200 that delivers hydrogen to the chamber through hydrogen supply passage 242 is a hydrogen permeable hollow cathode of an electrolysis cell. Electrolysis of water produces hydrogen that permeates through the hollow cathode. The cathode may be a transition metal such as nickel, iron, or titanium, or a noble metal such as palladium, or platinum, or tantalum or palladium coated tantalum, or palladium coated niobium. The electrolyte may be basic and the anode may be nickel. The electrolyte may be aqueous K₂CO₃. The flow of hydrogen into the cell may be controlled by controlling the electrolysis current with an electrolysis power controller.

A catalyst 250 for generating hydrino atoms can be placed in a catalyst reservoir 295. The catalyst in the gas phase may comprise the catalysts given in TABLES 1 and 3 and those in the Mills Prior Publications. The reaction vessel 207 has a catalyst supply passage 241 for the passage of gaseous catalyst from the catalyst reservoir 295 to the reaction chamber 200. Alternatively, the catalyst may be placed in a chemically resistant open container, such as a boat, inside the reaction vessel.

The molecular and atomic hydrogen partial pressures in the reactor vessel 207, as well as the catalyst partial pressure, is preferably maintained in the range of about 10 millitorr to about 100 torr. Most preferably, the hydrogen partial pressure in the reaction vessel 207 is maintained at about 200 millitorr.

Molecular hydrogen may be dissociated in the vessel into atomic hydrogen by a dissociating material. The dissociating material may comprise, for example, a noble metal such as platinum or palladium, a transition metal such as nickel and titanium, an inner transition metal such as niobium and zirconium, or a refractory metal such as tungsten or molybdenum. The dissociating material may be maintained at an elevated temperature by the heat liberated by the hydrogen catalysis (hydrino generation) and hydrino reduction taking place in the reactor. The dissociating material may also be maintained at elevated temperature by temperature control means 230, which may take the form of a heating coil as shown in cross section in FIG. 3. The heating coil is powered by a power supply 225.

Molecular hydrogen may be dissociated into atomic hydrogen by application of electromagnetic radiation, such as UV light provided by a photon source 205, by a hot filament or grid 280 powered by power supply 285, or by the plasma generated in the cell by the catalysis reaction.

The hydrogen dissociation occurs such that the dissociated hydrogen atoms contact a catalyst which is in a molten, liquid, gaseous, or solid form to produce hydrino atoms. The catalyst vapor pressure is maintained at the desired pressure by controlling the temperature of the catalyst reservoir 295 with a catalyst reservoir heater 298 powered by a power supply 272. When the catalyst is contained in a boat inside the reactor, the catalyst vapor pressure is maintained at the desired value by controlling the temperature of the catalyst boat, by adjusting the boat's power supply.

The rate of production of hydrinos and power by the hydrogen gas cell can be controlled by controlling the amount of catalyst in the gas phase and/or by controlling the concentration of atomic hydrogen. The concentration of gaseous catalyst in vessel chamber 200 may be controlled by controlling the initial amount of the volatile catalyst present in the chamber 200. The concentration of gaseous catalyst in chamber 200 may also be controlled by controlling the catalyst temperature, by adjusting the catalyst reservoir heater 298, or by adjusting a catalyst boat heater when the catalyst is contained in a boat inside the reactor. The vapor pressure of the volatile catalyst 250 in the chamber 200 is determined by the temperature of the catalyst reservoir 295, or the temperature of the catalyst boat, because each is colder than the reactor vessel 207. The reactor vessel 207 temperature is maintained at a higher operating temperature than catalyst reservoir 295 with heat liberated by the hydrogen catalysis (hydrino generation) and hydrino reduction. The reactor vessel temperature may also be maintained by a temperature control means, such as heating coil 230 shown in cross section in FIG. 3. Heating coil 230 is powered by power supply 225. The reactor temperature further controls the reaction rates such as hydrogen dissociation and catalysis.

In an embodiment, the catalyst comprises a mixture of a first catalyst supplied from the catalyst reservoir 295 and a source of a second catalyst supplied from gas supply 221 regulated by flow controller 222. Hydrogen may also be supplied to the cell from gas supply 221 regulated by flow controller 222. The flow controller 222 may achieve a desired mixture of the source of a second catalyst and hydrogen, or the gases may be premixed in a desired ratio. In an embodiment, the first catalyst produces the second catalyst from the source of the second catalyst. In an embodiment, the energy released by the catalysis of hydrogen by the first catalyst produces a plasma in the energy cell. The energy ionizes the source of the second catalyst to produce the second catalyst. The first catalyst may be selected from the group of catalysts given in TABLES 1 and 3 such as potassium and strontium, the source of the second catalyst may be selected from the group of helium and argon and the second catalyst may be selected from the group of He⁺ and Ar⁺ wherein the catalyst ion is generated from the corresponding atom by a plasma created by catalysis of hydrogen by the first catalyst. For examples, 1.) the energy cell contains strontium and argon wherein hydrogen catalysis by strontium produces a plasma containing Ar⁺ which serves as a second catalyst (Eqs. (15-17)) and 2.) the energy cell contains potassium and helium wherein hydrogen catalysis by potassium produces a plasma containing He⁺ which serves as a second catalyst (Eqs. (12-14)). In an embodiment, the pressure of the source of the second catalyst is in the range of about 1 millitorr to about one atmosphere. The hydrogen pressure is in the range of about 1 millitorr to about one atmosphere. In a preferred embodiment, the total pressure is in the range of about 0.5 torr to about 2 torr. In an embodiment, the ratio of the pressure of the source of the second catalyst to the hydrogen pressure is greater than one. In a preferred embodiment, hydrogen is about 0.1% to about 99%, and the source of the second catalyst comprises the balance of the gas present in the cell. More preferably, the hydrogen is in the range of about 1% to about 5% and the source of the second catalyst is in the range of about 95% to about 99%. Most preferably, the hydrogen is about 5% and the source of the second catalyst is about 95%. These pressure ranges are representative examples and a skilled person will be able to practice this invention using a desired pressure to provide a desired result.

The preferred operating temperature depends, in part, on the nature of the material comprising the reactor vessel 207. The temperature of a stainless steel alloy reactor vessel 207 is preferably maintained at about 200-1200° C. The temperature of a molybdenum reactor vessel 207 is preferably maintained at about 200-1800° C. The temperature of a tungsten reactor vessel 207 is preferably maintained at about 200-3000° C. The temperature of a quartz or ceramic reactor vessel 207 is preferably maintained at about 200-1800° C.

The concentration of atomic hydrogen in vessel chamber 200 can be controlled by the amount of atomic hydrogen generated by the hydrogen dissociation material. The rate of molecular hydrogen dissociation can be controlled by controlling the surface area, the temperature, and/or the selection of the dissociation material. The concentration of atomic hydrogen may also be controlled by the amount of atomic hydrogen provided by the atomic hydrogen source 221. The concentration of atomic hydrogen can be further controlled by the amount of molecular hydrogen supplied from the hydrogen source 221 controlled by a flow controller 222 and a pressure sensor 223. The reaction rate may be monitored by windowless ultraviolet (UV) emission spectroscopy to detect the intensity of the UV emission due to the catalysis and the hydrino, dihydrino molecular ion, dihydrino molecule, hydride ion, and compound emissions.

The gas cell hydrogen reactor further comprises other element as an electron source 260 such a reductant in contact with the generated hydrinos to form hydrino hydride ions. Compounds comprising a hydrino hydride anion and a cation may be formed in the gas cell. The cation which forms the hydrino hydride compound may comprise a cation from an added reductant, or a cation present in the cell (such as the cation of the catalyst). The cell may further comprise a getter or cryotrap 255 to selectively collect the lower-energy-hydrogen species and/or the increased-binding-energy hydrogen compounds.

1.3 Hydrogen Gas Discharge Power and Plasma Cell and Diamond Reactor

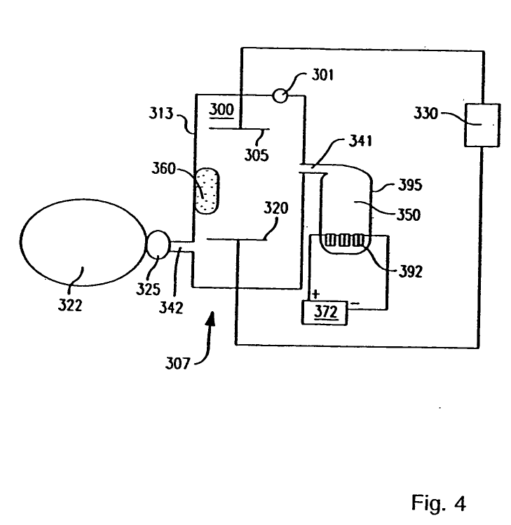

A hydrogen gas discharge power and plasma cell and diamond reactor of the present invention is shown in FIG. 4. The hydrogen gas discharge power and plasma cell and diamond reactor of FIG. 4, includes a gas discharge cell 307 comprising a hydrogen isotope gas-filled glow discharge vacuum vessel 313 having a chamber 300. A hydrogen source 322 supplies hydrogen to the chamber 300 through control valve 325 via a hydrogen supply passage 342. A catalyst is contained in catalyst reservoir 395. A voltage and current source 330 causes current to pass between a cathode 305 and an anode 320. The current may be reversible. In another embodiment, the plasma is generated with a microwave source such as a microwave generator.

In one embodiment of the hydrogen gas discharge power and plasma cell and diamond reactor, the wall of vessel 313 is conducting and serves as the anode. In another embodiment, the cathode 305 is hollow such as a hollow, nickel, aluminum, copper, tungsten, molybdenum, or stainless steel hollow cathode. In an embodiment, the cathode material may be a source of catalyst such as iron or samarium.

The cathode 305 may be coated with the catalyst for generating hydrinos and energy. The catalysis to form hydrinos and energy occurs on the cathode surface. To form hydrogen atoms for generation of hydrinos and energy, molecular hydrogen is dissociated on the cathode. To this end, the cathode is formed of a hydrogen dissociative material. Alternatively, the molecular hydrogen is dissociated by the discharge.

According to another embodiment of the invention, the catalyst for generating hydrinos and energy is in gaseous form. For example, the discharge may be utilized to vaporize the catalyst to provide a gaseous catalyst. Alternatively, the gaseous catalyst is produced by the discharge current. For example, the gaseous catalyst may be provided by a discharge in rubidium metal to form Rb⁺, strontium metal to form Sr⁺, or titanium metal to form Ti²⁺, or potassium to volatilize the metal. The gaseous hydrogen atoms for reaction with the gaseous catalyst are provided by a discharge of molecular hydrogen gas such that the catalysis occurs in the gas phase.

Another embodiment of the hydrogen gas discharge power and plasma cell and diamond reactor where catalysis occurs in the gas phase utilizes a controllable gaseous catalyst. The gaseous hydrogen atoms for conversion to hydrinos are provided by a discharge of molecular hydrogen gas. The gas discharge cell 307 has a catalyst supply passage 341 for the passage of the gaseous catalyst 350 from catalyst reservoir 395 to the reaction chamber 300. The catalyst reservoir 395 is heated by a catalyst reservoir heater 392 having a power supply 372 to provide the gaseous catalyst to the reaction chamber 300. The catalyst vapor pressure is controlled by controlling the temperature of the catalyst reservoir 395, by adjusting the heater 392 by means of its power supply 372. The reactor further comprises a selective venting valve 301.

In another embodiment of the hydrogen gas discharge power and plasma cell and diamond reactor where catalysis occurs in the gas phase utilizes a controllable gaseous catalyst. Gaseous hydrogen atoms provided by a discharge of molecular hydrogen gas. A chemically resistant (does not react or degrade during the operation of the reactor) open container, such as a tungsten or ceramic boat, positioned inside the gas discharge cell contains the catalyst. The catalyst in the catalyst boat is heated with a boat heater using by means of an associated power supply to provide the gaseous catalyst to the reaction chamber. Alternatively, the glow gas discharge cell is operated at an elevated temperature such that the catalyst in the boat is, sublimed, boiled, or volatilized into the gas phase. The catalyst vapor pressure is controlled by controlling the temperature of the boat or the discharge cell by adjusting the heater with its power supply.

The gas discharge cell may be operated at room temperature by continuously supplying catalyst. Alternatively, to prevent the catalyst from condensing in the cell, the temperature is maintained above the temperature of the catalyst source, catalyst reservoir 395 or catalyst boat. For example, the temperature of a stainless steel alloy cell is about 0-1200° C.; the temperature of a molybdenum cell is about 0-1800° C.; the temperature of a tungsten cell is about 0-3000° C.; and the temperature of a glass, quartz, or ceramic cell is about 0-1800° C. The discharge voltage may be in the range of about 1000 to about 50,000 volts. The current may be in the range of about 1 μA to about 1 A, preferably about 1 mA.

The discharge current may be intermittent or pulsed. Pulsing may be used to reduce the input power, and it may also provide a time period wherein the field is set to a desired strength by an offset voltage which may be below the discharge voltage. One application of controlling the field during the nondischarge period is to optimize the energy match between the catalyst and the atomic hydrogen. In an embodiment, the offset voltage is between, about 0.5 to about 500 V. In another embodiment, the offset voltage is set to provide a field of about 0.1 V/cm to about 50 V/cm. Preferably, the offset voltage is set to provide a field between about 1 V/cm to about 10 V/cm. The peak voltage may be in the range of about 1 V to 10 MV. More preferably, the peak voltage is in the range of about 10 V to 100 kV. Most preferably, the voltage is in the range of about 100 V to 500 V. The pulse frequency and duty cycle may also be adjusted. An application of controlling the pulse frequency and duty cycle is to optimize the power balance. In an embodiment, this is achieved by optimizing the reaction rate versus the input power. The amount of catalyst and atomic hydrogen generated by the discharge decay during the nondischarge period. The reaction rate may be controlled by controlling the amount of catalyst generated by the discharge such as Ar⁺ and the amount of atomic hydrogen wherein the concentration is dependent on the pulse frequency, duty cycle, and the rate of decay. In an embodiment, the pulse frequency is of about 0.1 Hz to about 100 MHz. In another embodiment, the pulse frequency is faster than the time for substantial atomic hydrogen recombination to molecular hydrogen. Based on anomalous plasma afterglow duration studies [R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, Vol. 26, No. 7, July, (2001), pp. 749-762; R. Mills, “Temporal Behavior of Light-Emission in the Visible Spectral Range from a Ti-K2CO3-H-Cell”, Int. J. Hydrogen Energy, Vol. 26, No. 4, (2001), pp. 327-332], preferably the frequency is within the range of about 1 to about 200 Hz. In an embodiment, the duty cycle is about 0.1% to about 95%. Preferably, the duty cycle is about 1% to about 50%.

In another embodiment, the power may be applied as an alternating current (AC). The frequency may be in the range of about 0.001 Hz to 1 GHz. More preferably the frequency is in the range of about 60 Hz to 100 MHz. Most preferably, the frequency is in the range of about 10 to 100 MHz. The system may comprises two electrodes wherein one or more electrodes are in direct contact with the plasma; otherwise, the electrodes may be separated from the plasma by a dielectric barrier. The peak voltage may be in the range of about 1 V to 10 MV. More preferably, the peak voltage is in the range of about 10 V to 100 kV. Most preferably, the voltage is in the range of about 100 V to 500 V.

The gas discharge cell apparatus further comprises other element as an electron source 360 such a reductant in contact with the generated hydrinos to form hydrino hydride ions. Compounds comprising a hydrino hydride anion and a cation may be formed in the gas cell. The cation which forms the hydrino hydride compound may comprise a cation from an added reductant, or a cation present in the cell (such as the cation of the catalyst).

In one embodiment of the gas discharge cell apparatus, alkali and alkaline earth hydrino hydrides and energy are produced in the gas discharge cell 307. In an embodiment, the catalyst reservoir 395 contains potassium, rubidium, or strontium metal which may be is ionized to K⁺, Rb⁺ or Sr⁺ catalyst, respectively. The catalyst vapor pressure in the gas discharge cell is controlled by heater 392. The catalyst reservoir 395 is heated with the heater 392 to maintain the catalyst vapor pressure proximal to the cathode 305 preferably in the pressure range 10 millitorr to 100 torr, more preferably at about 200 mtorr. In another embodiment, the cathode 305 and the anode 320 of the gas discharge cell 307 are coated with potassium, rubidium, or strontium. The catalyst is vaporized during the operation of the cell. The hydrogen supply from source 322 is adjusted with control 325 to supply hydrogen and maintain the hydrogen pressure in the 10 millitorr to 100 torr range.

In an embodiment, the electrode to provide the electric field is a compound electrode comprising multiple electrodes in series or parallel that may occupy a substantial portion of the volume of the reactor. In one embodiment, the electrode comprises multiple hollow cathodes in parallel so that the desired electric field is produced in a large volume to generate a substantial power level. One design of the multiple hollow cathodes comprises an anode and multiple concentric hollow cathodes each electrically isolated from the common anode. Another compound electrode comprises multiple parallel plate electrodes connected in series.

A preferable hollow cathode is comprised of refractory materials such as molybdenum or tungsten. A preferably hollow cathode comprises a compound hollow cathode. A preferable catalyst of a compound hollow cathode discharge cell is neon as described in R. L. Mills, P. Ray, J. Dong, M. Nansteel, B. Dhandapani, J. He, “Vibrational Spectral Emission of Fractional-Principal-Quantum-Energy-Level Atomic and Molecular Hydrogen”, Vibrational Spectroscopy, submitted which is herein incorporated by reference in its entirety. In an embodiment of the cell comprising a compound hollow cathode and neon as the source of catalyst with hydrogen, the partial pressure of neon is in the range 99.99%-90% and hydrogen is in the range 0.01-10%. Preferably the partial pressure of neon is in the range 99.9-99% and hydrogen is in the range 0.1-1%.

1.4 Hydrogen Radio Frequency (RF) Barrier Electrode Discharge Power and Plasma Cell and Diamond Reactor

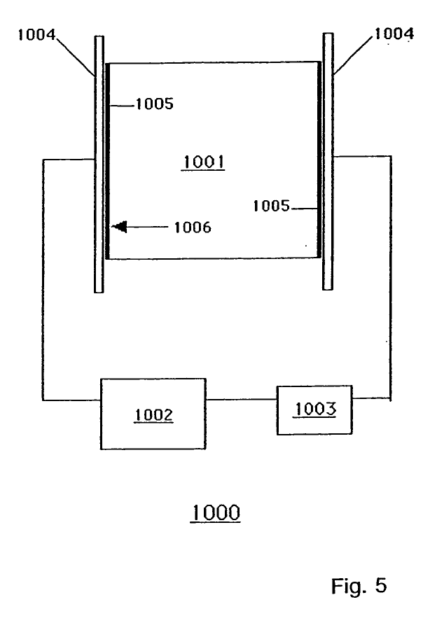

In an embodiment of the hydrogen discharge power and plasma cell and diamond reactor, at least one of the discharge electrodes is shielded by a dielectric barrier such as glass, quartz, Alumina, or ceramic in order to provide an electric field with minimum power dissipation. A radio frequency (RF) barrier electrode discharge cell system 1000 of the present invention is shown in FIG. 5. The RF power may be capacitively coupled. In an embodiment, the electrodes 1004 may be external to the cell 1001. A dielectric layer 1005 separates the electrodes from the cell wall 1006. The high driving voltage may be AC and may be high frequency. The driving circuit comprises a high voltage power source 1002 which is capable of providing RF and an impedance matching circuit 1003. The frequency is preferably in the range of about 100 Hz to about 10 GHz, more preferably, about 1 kHz to about 1 MHz, most preferably about 5-10 kHz. The voltage is preferably in the range of about 100 V to about 1 MV, more preferably about 1 kV to about 100 kV, and most preferably about 5 to about 10 kV.

1.5 Hydrogen Plasma Torch Power and Plasma Cell and Diamond Reactor

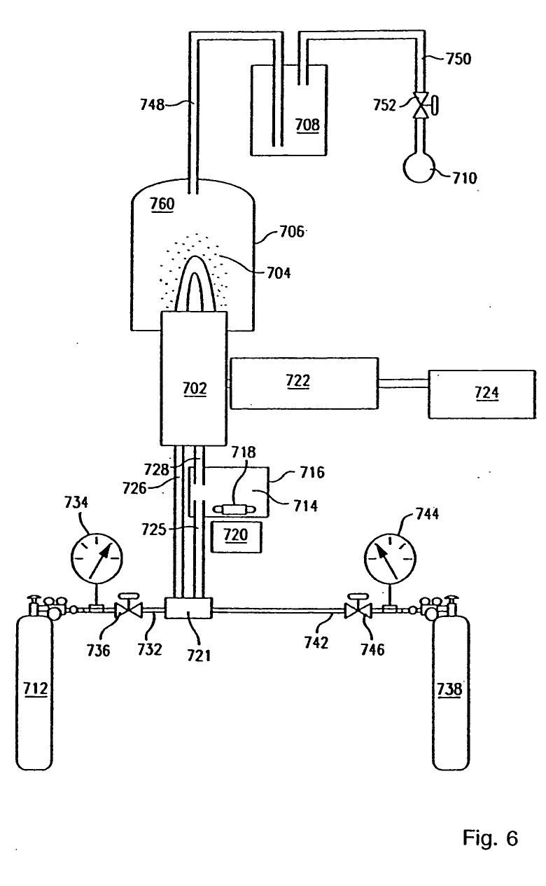

A hydrogen plasma torch power and plasma cell and diamond reactor of the present invention is shown in FIG. 6. A plasma torch 702 provides a hydrogen isotope plasma 704 enclosed by a manifold 706 and contained in plasma chamber 760. Hydrogen from hydrogen supply 738 and plasma gas from plasma gas supply 712, along with a catalyst 714 for forming hydrinos and energy, is supplied to torch 702. The plasma may comprise argon, for example. The catalyst may comprise at least one of those given in TABLES 1 and 3 or a hydrino atom to provide a disproportionation reaction. The catalyst is contained in a catalyst reservoir 716. The reservoir is equipped with a mechanical agitator, such as a magnetic stirring bar 718 driven by magnetic stirring bar motor 720. The catalyst is supplied to plasma torch 702 through passage 728. The catalyst may be generated by a microwave discharge. Preferred catalysts are He⁺ or Ar⁺ from a source such as helium gas or argon gas.

Hydrogen is supplied to the torch 702 by a hydrogen passage 726. Alternatively, both hydrogen and catalyst may be supplied through passage 728. The plasma gas is supplied to the torch by a plasma gas passage 726. Alternatively, both plasma gas and catalyst may be supplied through passage 728.

Hydrogen flows from hydrogen supply 738 to a catalyst reservoir 716 via passage 742. The flow of hydrogen is controlled by hydrogen flow controller 744 and valve 746. Plasma gas flows from the plasma gas supply 712 via passage 732. The flow of plasma gas is controlled by plasma gas flow controller 734 and valve 736. A mixture of plasma gas and hydrogen is supplied to the torch via passage 726 and to the catalyst reservoir 716 via passage 725. The mixture is controlled by hydrogen-plasma-gas mixer and mixture flow regulator 721. The hydrogen and plasma gas mixture serves as a carrier gas for catalyst particles which are dispersed into the gas stream as fine particles by mechanical agitation. The aerosolized catalyst and hydrogen gas of the mixture flow into the plasma torch 702 and become gaseous hydrogen atoms and vaporized catalyst ions (such as Rb⁺ ions from a salt of rubidium) in the plasma 704. The plasma is powered by a microwave generator 724 wherein the microwaves are tuned by a tunable microwave cavity 722. Catalysis may occur in the gas phase.

The amount of gaseous catalyst in the plasma torch can be controlled by controlling the rate at which the catalyst is aerosolized with a mechanical agitator. The amount of gaseous catalyst can also be controlled by controlling the carrier gas flow rate where the carrier gas includes a hydrogen and plasma gas mixture (e.g., hydrogen and argon). The amount of gaseous hydrogen atoms to the plasma torch can be controlled by controlling the hydrogen flow rate and the ratio of hydrogen to plasma gas in the mixture. The hydrogen flow rate and the plasma gas flow rate to the hydrogen-plasma-gas mixer and mixture flow regulator 721 can be controlled by flow rate controllers 734 and 744, and by valves 736 and 746. Mixer regulator 721 controls the hydrogen-plasma mixture to the torch and the catalyst reservoir. The catalysis rate can also be controlled by controlling the temperature of the plasma with microwave generator 724.

Hydrino atoms, dihydrino molecular ions, dihydrino molecules, and hydrino hydride ions are produced in the plasma 704. Dihydrino molecules and hydrino hydride compounds may be cryopumped onto the manifold 706, or they may flow into a trap 708 such as a cryotrap through passage 748. Trap 708 communicates with vacuum pump 710 through vacuum line 750 and valve 752. A flow to the trap 708 is effected by a pressure gradient controlled by the vacuum pump 710, vacuum line 750, and vacuum valve 752.

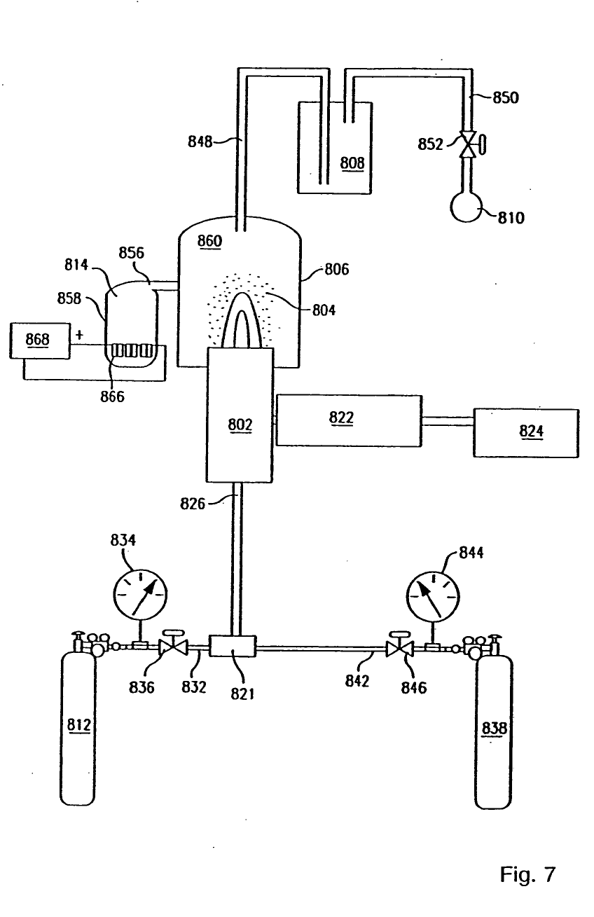

In another embodiment of the plasma torch hydrogen reactor shown in FIG. 7, at least one of plasma torch 802 or manifold 806 has a catalyst supply passage 856 for passage of the gaseous catalyst from a catalyst reservoir 858 to the plasma 804. The catalyst 814 in the catalyst reservoir 858 is heated by a catalyst reservoir heater 866 having a power supply 868 to provide the gaseous catalyst to the plasma 804. The catalyst vapor pressure can be controlled by controlling the temperature of the catalyst reservoir 858 by adjusting the heater 866 with its power supply 868. The remaining elements of FIG. 7 have the same structure and function of the corresponding elements of FIG. 6. In other words, element 812 of FIG. 7 is a plasma gas supply corresponding to the plasma gas supply 712 of FIG. 6, element 838 of FIG. 7 is a hydrogen supply corresponding to hydrogen supply 738 of FIG. 6, and so forth.

In another embodiment of the plasma torch hydrogen reactor, a chemically resistant open container such as a ceramic boat located inside the manifold contains the catalyst. The plasma torch manifold forms a cell which can be operated at an elevated temperature such that the catalyst in the boat is sublimed, boiled, or volatilized into the gas phase. Alternatively, the catalyst in the catalyst boat can be heated with a boat heater having a power supply to provide the gaseous catalyst to the plasma. The catalyst vapor pressure can be controlled by controlling the temperature of the cell with a cell heater, or by controlling the temperature of the boat by adjusting the boat heater with an associated power supply.

The plasma temperature in the plasma torch hydrogen reactor is advantageously maintained in the range of about 5,000-30,000° C. The cell may be operated at room temperature by continuously supplying catalyst. Alternatively, to prevent the catalyst from condensing in the cell, the cell temperature can be maintained above that of the catalyst source, catalyst reservoir 858 or catalyst boat. The operating temperature depends, in part, on the nature of the material comprising the cell. The temperature for a stainless steel alloy cell is preferably about 0-1200° C. The temperature for a molybdenum cell is preferably about 0-1800° C. The temperature for a tungsten cell is preferably about 0-3000° C. The temperature for a glass, quartz, or ceramic cell is preferably about 0-1800° C. Where the manifold 706 is open to the atmosphere, the cell pressure is atmospheric.

An exemplary plasma gas for the plasma torch hydrogen reactor is argon which may also serve as a source of catalyst. Exemplary aerosol flow rates are about 0.8 standard liters per minute (slm) hydrogen and about 0.15 slm argon. An exemplary argon plasma flow rate is about 5 slm. An exemplary forward input power is about 1000 W, and an exemplary reflected power is about 10-20 W.

In other embodiments of the plasma torch hydrogen reactor, the mechanical catalyst agitator (magnetic stirring bar 718 and magnetic stirring bar motor 720) is replaced with an aspirator, atomizer, or nebulizer to form an aerosol of the catalyst 714 dissolved or suspended in a liquid medium such as water. The medium is contained in the catalyst reservoir 716. Or, the aspirator, atomizer, ultrasonic dispersion means, or nebulizer injects the catalyst directly into the plasma 704. The nebulized or atomized catalyst can be carried into the plasma 704 by a carrier gas, such as hydrogen.

The hydrogen plasma torch cell further includes an electron source in contact with the hydrinos, for generating hydrino hydride ions. In the plasma torch cell, the hydrinos can be reduced to hydrino hydride ions by contacting a reductant extraneous to the operation of the cell (e.g. a consumable reductant added to the cell from an outside source). Compounds comprising a hydrino hydride anion and a cation may be formed in the cell. The cation which forms the hydrino hydride compound may comprise a cation of other element, an oxidized species such as a reductant, or a cation present in the plasma (such as a cation of the catalyst).

### 2. Hydrogen RF and Microwave Power and Plasma Cell and Diamond Reactor

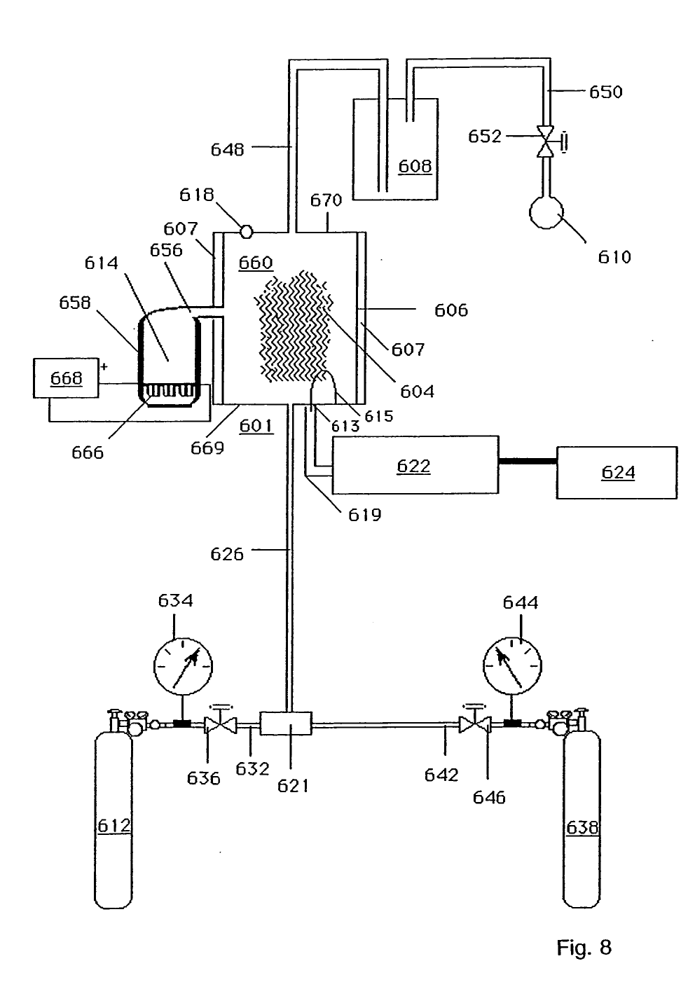

According to an embodiment of the invention, a reactor for producing power, plasma, and at least one of hydrinos, hydrino hydride ions, dihydrino molecular ions, dihydrino molecules, and diamonds may take the form of a hydrogen microwave reactor. A hydrogen microwave gas cell reactor of the present invention is shown in FIG. 8. Hydrinos are provided by a reaction with a catalyst capable of providing a net enthalpy of reaction of m/2·27.2±0.5 eV where m is an integer, preferably an integer less than 400 such as those given in TABLES 1 and 3 and/or by a disproportionation reaction wherein lower-energy hydrogen, hydrinos, serve to cause transitions of hydrogen atoms and hydrinos to lower-energy levels with the release of power. Catalysis may occur in the gas phase. The catalyst may be generated by a microwave discharge. Preferred catalysts are He⁺ or Ar⁺ from a source such as helium gas or argon gas. The catalysis reaction may provide power to form and maintain a plasma that comprises energetic ions. Microwaves that may or may not be phase bunched may be generated by ionized electrons in a magnetic field; thus, the magnetized plasma of the cell comprises an internal microwave generator. The generated microwaves may then be the source of microwaves to at least partially maintain the microwave discharge plasma.

The reactor system of FIG. 8 comprises a reaction vessel 601 having a chamber 660 capable of containing a vacuum or pressures greater than atmospheric. A source of hydrogen 638 delivers hydrogen to supply tube 642, and hydrogen flows to the chamber through hydrogen supply passage 626. The flow of hydrogen can be controlled by hydrogen 50 flow controller 644 and valve 646. In an embodiment, a source of hydrogen communicating with chamber 660 that delivers hydrogen to the chamber through hydrogen supply passage 626 is a hydrogen permeable hollow cathode of an electrolysis cell of the reactor system. Electrolysis of water produces hydrogen that permeates through the hollow cathode. The cathode may be a transition metal such as nickel, iron, or titanium, or a noble metal such as palladium, or platinum, or tantalum or palladium coated tantalum, or palladium coated niobium. The electrolyte may be basic and the anode may be nickel, platinum, or a dimensionally stable anode. The electrolyte may be aqueous K₂CO₃. The flow of hydrogen into the cell may be controlled by controlling the electrolysis current with an electrolysis power controller.

Plasma gas flows from the plasma gas supply 612 via passage 632. The flow of plasma gas can be controlled by plasma gas flow controller 634 and valve 636. A mixture of plasma gas and hydrogen can be supplied to the cell via passage 626. The mixture is controlled by hydrogen-plasma-gas mixer and mixture flow regulator 621. The plasma gas such as helium may be a source of catalyst such as He⁺ or He₂*, argon may be a source of catalyst such as Ar⁺, neon may serve as a source of catalyst such as Ne₂* or Ne⁺, and neon-hydrogen mixture may serve as a source of catalyst such as Ne⁺/H⁺. The source of catalyst and hydrogen of the mixture flow into the plasma and become catalyst and atomic hydrogen in the chamber 660.

The plasma may be powered by a microwave generator 624 wherein the microwaves are tuned by a tunable microwave cavity 622, carried by waveguide 619, and can be delivered to the chamber 660 though an RF transparent window 613 or antenna 615. Sources of microwaves known in the art are traveling wave tubes, klystrons, magnetrons, cyclotron resonance masers, gyrotrons, and free electron lasers. The waveguide or antenna may be inside or outside of the cell. In the latter case, the microwaves may penetrate the cell from the source through a window of the cell 613. The microwave window may comprise Alumina or quartz.

In another embodiment, the cell 601 is a microwave resonator cavity. In an embodiment, the source of microwave supplies sufficient microwave power density to the cell to ionize a source of catalyst such as at least one of helium, neon-hydrogen mixture, and argon gases to form a catalyst such as He⁺, Ne⁺, and Ar⁺, respectively. In such an embodiment, the microwave power source or applicator such as an antenna, waveguide, or cavity forms a nonthermal plasma wherein the species corresponding to the source of catalyst such as helium or argon atoms and ions have a higher temperature than that at thermal equilibrium. Thus, higher energy states such as ionized states of the source of catalyst are predominant over that of hydrogen compared to a corresponding thermal plasma wherein excited states of hydrogen are predominant. In an embodiment, the source of catalyst is in excess compared to the source of hydrogen atoms such that the formation of a nonthermal plasma is favored. The power supplied by the source of microwave power may be delivered to the cell such that it is dissipated in the formation of energetic electrons within about the electron mean free path. In an embodiment, the total pressure is about 0.5 to about 5 Torr and the mean electron free path is about 0.1 cm to 1 cm. In an embodiment, the dimensions of the cell are greater than the electron mean free path. In an embodiment, the cavity is at least one of the group of a reentrant cavity such as an Evenson cavity, Beenakker, McCarrol, and cylindrical cavity. In an embodiment, the cavity provides a strong electromagnetic field which may form a nonthermal plasma. The strong electromagnetic field may be due to a TM₀₁₀ mode of a cavity such as a Beenakker cavity. In a preferred embodiment, the cavity provides an E mode rather than an M mode. In a preferred embodiment, the cavity is a reentrant cavity such as an Evenson cavity that forms a plasma with an E mode. Multiple sources of microwave power may be used simultaneously. For example, the microwave plasma such as a nonthermal plasma may be maintained by multiple Evenson cavities operated in parallel to form the plasma in the microwave cell 601. The cell may be cylindrical and may comprise a quartz cell with Evenson cavities spaced along the longitudinal axis. In another embodiment, a multi slotted antenna such as a planar antenna serves as the equivalent of multiple sources of microwaves such as dipole-antenna-equivalent sources. One such embodiment is given in Y. Yasaka, D. Nozaki, M. Ando, T. Yamamoto, N. Goto, N. Ishii, T. Morimoto, “Production of large-diameter plasma using multi-slotted planar antenna,” Plasma Sources Sci. Technol., Vol. 8, (1999), pp. 530-533 which is incorporated herein by reference in its entirety.

In an embodiment, of the hydrogen microwave power and plasma cell and reactor, the output power is optimized by using a cavity such as a reentrant cavity such as an Evenson cavity and tuning the cell to an optimal voltage staging wave. In an embodiment, the reflected versus input power is tuned such that a desired voltage standing wave is obtained which optimizes or controls the output power. Typically, the ratio of the maximum voltage to the minimum voltage on the transmission line determines the voltage standing wave. In another embodiment, the cell comprises a tunable microwave cavity having a desired voltage standing wave to optimize and control the output power.

The cell may further comprise a magnet such a solenoidal magnet 607 to provide an axial magnetic field. The ions such as electrons formed by the hydrogen catalysis reaction produce microwaves to at least partially maintain the microwave discharge plasma. The microwave frequency may be selected to efficiently form atomic hydrogen from molecular hydrogen. It may also effectively form ions that serve as catalysts from a source of catalyst such as He⁺, Ne⁺, Ne⁺/H⁺, or Ar⁺ catalysts from helium, neon, neon-hydrogen mixtures, and argon gases, respectively.

The microwave frequency is preferably in the range of about 1 MHz to about 100 GHz, more preferably in the range about 50 MHz to about 10 GHz, most preferably in the range of about 75 MHz±50 MHz or about 2.4 GHz±1 GHz.

A hydrogen dissociator may be located at the wall of the reactor to increase the atomic hydrogen concentrate in the cell. The reactor may further comprise a magnetic field wherein the magnetic field may be used to provide magnetic confinement to increase the electron and ion energy to be converted into power by means such as a magnetohydrodynamic or plasmadynamic power converter.

A vacuum pump 610 may be used to evacuate the chamber 660 through vacuum lines 648 and 650. The cell may be operated under flow conditions with the hydrogen and the catalyst supplied continuously from catalyst source 612 and hydrogen source 638. The amount of gaseous catalyst may be controlled by controlling the plasma gas flow rate where the plasma gas includes a hydrogen and a source of catalyst (e.g., hydrogen and argon or helium). The amount of gaseous hydrogen atoms to the plasma may be controlled by controlling the hydrogen flow rate and the ratio of hydrogen to plasma gas in the mixture. The hydrogen flow rate and the plasma gas flow rate to the hydrogen-plasma-gas mixer and mixture flow regulator 621 are controlled by flow rate controllers 634 and 644, and by valves 636 and 646. Mixer regulator 621 controls the hydrogen-plasma mixture to the chamber 660. The catalysis rate is also controlled by controlling the temperature of the plasma with microwave generator 624.

Catalysis may occur in the gas phase. Hydrino atoms, dihydrino molecular ions, dihydrino molecules, and hydrino hydride ions are produced in the plasma 604. Dihydrino molecules and hydrino hydride compounds may be cryopumped onto the wall 606, or they may flow into a 608 such as a cryotrap through passage 648. Trap 608 communicates with vacuum pump 610 through vacuum line 650 and valve 652. A flow to the trap 608 can be effected by a pressure gradient controlled by the vacuum pump 610, vacuum line 650, and vacuum valve 652.

In another embodiment of the hydrogen microwave reactor shown in FIG. 8, the wall 606 has a catalyst supply passage 656 for passage of the gaseous catalyst from a catalyst reservoir 658 to the plasma 604. The catalyst in the catalyst reservoir 658 can be heated by a catalyst reservoir heater 666 having a power supply 668 to provide the gaseous catalyst to the plasma 604. The catalyst vapor pressure can be controlled by controlling the temperature of the catalyst reservoir 658 by adjusting the heater 666 with its power supply 668. The catalyst in the gas phase may comprise those given in TABLES 1 and 3, hydrinos, and those described in the Mills Prior Publication.

In another embodiment of the hydrogen microwave reactor, a chemically resistant open container such as a ceramic boat located inside the chamber 660 contains the catalyst. The reactor further comprises a heater that may maintain an elevated temperature. The cell can be operated at an elevated temperature such that the catalyst in the boat is sublimed, boiled, or volatilized into the gas phase. Alternatively, the catalyst in the catalyst boat can be heated with a boat heater having a power supply to provide the gaseous catalyst to the plasma. The catalyst vapor pressure can be controlled by controlling the temperature of the cell with a cell heater, or by controlling the temperature of the boat by adjusting the boat heater with an associated power supply.

In an embodiment, the hydrogen microwave reactor further comprises a structure interact with the microwaves to cause localized regions of high electric and/or magnetic field strength. A high magnetic field may cause electrical breakdown of the gases in the plasma chamber 660. The electric field may form a nonthermal plasma that increases the rate of catalysis by methods such as the formation of the catalyst from a source of catalyst. The source of catalyst may be argon, neon-hydrogen mixture, helium to form He⁺, Ne⁺, and Ar⁺, respectively. The structures and methods are equivalent to those given in the Plasma Torch Cell Hydride Reactor section of my previous PCT Application PCT/US02/06945, filed Mar. 7, 2002.

The nonthermal plasma temperature corresponding to the energetic ion and/or electron temperature as opposed to the relatively low energy thermal neutral gas temperature in the microwave cell reactor is advantageously maintained in the range of about 5,000-5,000,000° C. The cell may be operated without heating or insulation. Alternatively, in the case that the catalyst has a low volatility, the cell temperature is maintained above that of the catalyst source, catalyst reservoir 658 or catalyst boat to prevent the catalyst from condensing in the cell. The operating temperature depends, in part, on the nature of the material comprising the cell. The temperature for a stainless steel alloy cell is preferably about 0-1200° C. The temperature for a molybdenum cell is preferably about 0-1800° C. The temperature for a tungsten cell is preferably about 0-3000° C. The temperature for a glass, quartz, or ceramic cell is preferably about 0-1800° C.

The molecular and atomic hydrogen partial pressures in the chamber 660, as well as the catalyst partial pressure, is preferably maintained in the range of about 1 mtorr to about 100 atm. Preferably the pressure is in the range of about 100 mtorr to about 1 atm, more preferably the pressure is about 100 mtorr to about 20 torr.

An exemplary plasma gas for the hydrogen microwave reactor is argon. Exemplary flow rates are about 0.1 standard liters per minute (slm) hydrogen and about 1 slm argon. An exemplary forward microwave input power is about 1000 W. The flow rate of the plasma gas or hydrogen-plasma gas mixture such as at least one gas selected for the group of hydrogen, argon, helium, argon-hydrogen mixture, helium-hydrogen mixture, water vapor, ammonia is preferably about 0-1 standard liters per minute per cm³ of vessel volume and more preferably about 0.001-10 sccm per cm³ of vessel volume. In the case of an helium-hydrogen, neon-hydrogen, or argon-hydrogen mixture, preferably helium, neon, or argon is in the range of about 99 to about 1%, more preferably about 99 to about 95%. The power density of the source of plasma power is preferably in the range of about 0.01 W to about 100 W/cm³ vessel volume.

In other embodiments of the microwave reactor, the catalyst may be agitated and supplied through a flowing gas stream such as the hydrogen gas or plasma gas which may be an additional source of catalyst such as helium or argon gas. The source of catalyst may also be provided by an aspirator, atomizer, or nebulizer to form an aerosol of the source of catalyst. The catalyst which may become an aerosol may be dissolved or suspended in a liquid medium such as water. The medium may be contained in the catalyst reservoir 614. Alternatively, the aspirator, atomizer, or nebulizer may inject the source of catalyst or catalyst directly into the plasma 604. In another embodiment, the nebulized or atomized catalyst may be carried into the plasma 604 by a carrier gas, such as hydrogen, helium, neon, or argon where the helium, neon-hydrogen, or argon may be ionized to He⁺, Ne⁺, or Ar⁺, respectively, and serve as hydrogen catalysts.

Hydrogen may serve as the catalyst according to Eqs. (30-32). In an embodiment the catalysis of atomic hydrogen to form increased-binding-energy-hydrogen species is achieved with a hydrogen plasma. The cavity may be reentrant cavity such as an Evenson cavity. The hydrogen pressure may be in the range of about 1 mtorr to about 100 atm Preferably the pressure is in the range of about 100 mtorr to about 1 atm, more preferably the pressure is about 100 mtorr to about 10 torr. The microwave power density may be in the range of about 0.01 W to about 100 W/cm³ vessel volume. The hydrogen flow rate may be in the range of about 0-1 standard liters per minute per cm³ of vessel volume and more preferably about 0.001-10 sccm per cm³ of vessel volume.

The microwave cell may be interfaced with any of the converters of plasma or thermal energy to mechanical or electrical power described herein such as the magnetic mirror magnetohydrodynamic power converter, plasmadynamic power converter, or heat engine, such as a steam or gas turbine system, sterling engine, or thermionic or thermoelectric converter given in Mills Prior Publications. In addition it may be interfaced with the gyrotron, photon bunching microwave power converter, charge drift power, or photoelectric converter as disclosed in Mills Prior Publications.

The hydrogen microwave reactor further includes an electron source in contact with the hydrinos, for generating hydrino hydride ions. In the cell, the hydrinos may be reduced to hydrino hydride ions by contacting a reductant extraneous to the operation of the cell (e.g. a consumable reductant added to the cell from an outside source). In an embodiment, the microwave cell reactor further comprise a selective valve 618 for removal of lower-energy hydrogen products such as dihydrino molecules. Compounds comprising a hydrino hydride anion and a cation may be formed in the gas cell. The cation which forms the hydrino hydride compound may comprise a cation of other element, a cation of an oxidized added reductant, or a cation present in the plasma (such as a cation of the catalyst).

Metal hydrino hydrides may be formed in the microwave plasma reactor having a hydrogen plasma and a source of metal such as a source of the metals given in TABLE 3 that serve as both the catalyst and the reactant. The metal atoms may be provided by vaporization through heating. In one embodiment, the metal is vaporized from a hot filament containing the metal. The vapor pressure of the metal is maintained in the range 0.001 Torr to 100 Torr and the hydrogen plasma is maintained in the range 0.001 Torr to 100 Torr. Preferably the range for both metal and hydrogen is 0.1 Torr to 10 Torr.

### 3. Hydrogen Capacitively and Inductively Coupled RF Plasma and Power Cell and Diamond Reactor

According to an embodiment of the invention, a reactor for producing power and at least one of hydrinos, hydrino hydride ions, dihydrino molecular ions, dihydrino molecules, and diamonds may take the form of a hydrogen capacitively or inductively coupled RF power and plasma cell and diamond reactor. A hydrogen RF plasma reactor of the present invention is also shown in FIG. 8. The cell structures, systems, catalysts, and methods may be the same as those given for the microwave plasma cell reactor except that the microwave source may be replaced by a RF source 624 with an impedance matching network 622 that may drive at least one electrode and/or a coil. The RF plasma cell may further comprise two electrodes 669 and 670. The coaxial cable 619 may connect to the electrode 669 by coaxial center conductor 615. Alternatively, the coaxial center conductor 615 may connect to an external source coil which is wrapped around the cell 601 which may terminate without a connection to ground or it may connect to ground. The electrode 670 may be connected to ground in the case of the parallel plate or external coil embodiments. The parallel electrode cell may be according to the industry standard, the Gaseous Electronics Conference (GEC) Reference. Cell or modification thereof by those skilled in the art as described in G A. Hebner, K. E. Greenberg, “Optical diagnostics in the Gaseous electronics Conference Reference Cell, J. Res. Natl. Inst. Stand. Technol., Vol. 100, (1995), pp. 373-383; V. S. Gathen, J. Ropcke, T. Gans, M. Kaning, C. Lukas, H. F. Dobele, “Diagnostic studies of species concentrations in a capacitively coupled RF plasma containing CH₄—H₂—Ar,” Plasma Sources Sci. Technol., Vol. 10, (2001), pp. 530-539; P. J. Hargis, et al., Rev. Sci. Instrum., Vol. 65, (1994), p. 140; Ph. Belenguer, L. C. Pitchford, J. C. Hubinois, “Electrical characteristics of a RF-GD-OES cell,” J. Anal. At. Spectrom., Vol. 16, (2001), pp. 1-3 which are herein incorporated by reference in their entirety. The cell which comprises an external source coil such as a 13.56 MHz external source coil microwave plasma source is as given in D. Barton, J. W. Bradley, D. A. Steele, and R. D. Short, “investigating radio frequency plasmas used for the modification of polymer surfaces,” J. Phys. Chem. B, Vol. 103, (1999), pp. 4423-4430; D. T. Clark, A. J. Dilks, J. Polym. Sci. Polym. Chem. Ed., Vol. 15, (1977), p. 2321; B. D. Beake, J. S. G. Ling, G. J. Leggett, J. Mater. Chem., Vol. 8, (1998), p. 1735; R. M. France, R. D. Short, Faraday Trans. Vol. 93, No. 3, (1997), p. 3173, and R. M. France, R. D. Short, Langmuir, Vol. 14, No. 17, (1998), p. 4827 which are herein incorporated by reference in their entirety. At least one wall of the cell 601 wrapped with the external coil is at least partially transparent to the RF excitation. The RF frequency is preferably in the range of about 100 Hz to about 100 GHz, more preferably in the range about 1 kHz to about 100 MHz, most preferably in the range of about 13.56 MHz±50 MHz or about 2.4 GHz±1 GHz.

In another embodiment, an inductively coupled plasma source is a toroidal plasma system such as the Astron system of Astex Corporation described in U.S. Pat. No. 6,150,628 which is herein incorporated by reference in its entirety. In an embodiment, the field strength is high to cause a nonthermal plasma. The toroidal plasma system may comprise a primary of a transformer circuit. The primary may be driven by a radio frequency power supply. The plasma may be a closed loop which acts at as a secondary of the transformer circuit. The RF frequency is preferably in the range of about 100 Hz to about 100 GHz, more preferably in the range about 1 kHz to about 100 MHz, most preferably in the range of about 13.56 MHz±50 MHz or about 2.4 GHz±1 GHz.

In an embodiment, the plasma cell is driven by at least one of a traveling and a standing wave plasma generators such as given in Fossa [A. C. Fossa, M. Moisan, M. R. Wertheimer, “vacuum ultraviolet to visible emission from hydrogen plasma: effect of excitation frequency”, Journal of Applied Physics, Vol. 88, No. 1, (2000), pp. 20-33 which is herein incorporated by reference in its entirety].

In another embodiment, the frequency of the cell is 50 kHz and is driven by a radio frequency generator such as that given by Bzenic et. al. [S. A. Bzenic, S. B. Radovanov, S. B. Vrhovac, Z. B. Velikic, and B. M. Jelenkovic, “On the mechanism of Doppler broadening of H_{β}after dissociative excitation in hydrogen glow discharges”, Chem. Phys. Lett., Vol. 184, (1991), pp. 108-112 which is herein incorporate by reference in its entirety].

In another embodiment of the plasma cell for the production of power and lower-energy-hydrogen compounds, the cell comprises a helicon as described in Asian Particle Accelerator Conference (APAC98), March 26th—Poster Presentation 6D-061, Development of DC Accelerator Ion Sources using Helicon Plasmas p.825, G. S. Eom, I. S. Hong, Y. S. Hwang, KAIST, Taejon,

<http://accelconf.web.cern.ch/AccelConf/a98/APAC98/6D061.PDF>http://accelconf.web.cern. ch/AccelConf/a98/APAC98/6D061.PDFG which is herein incorporated by reference in its entirety.

### 4. Plasma Confinement by Spatially Controlling Catalysis

The plasma formed by the catalysis of hydrogen may be confined to a desired region of the reactor by structures and methods such as those that control the source of catalyst, the source of atomic hydrogen, or the source of an electric or magnetic field which alters the catalysis rate as given in the Adjustment of Catalysis Rate section. In an embodiment, the reactor comprises two electrodes, which provide an electric field to control the catalysis rate of atomic hydrogen. The electrodes may produce an electric field parallel to the z-axis. The electrodes may be grids oriented in a plane perpendicular to the z-axis such as grid electrodes 305 and 320 shown in FIG. 4. The space between the electrodes may define the desired region of the reactor. The electrodes may be used in any or the other reactor of the present invention to catalyze atomic hydrogen to lower-energy states such as a plasma electrolysis reactor, barrier electrode reactor, RF plasma reactor, pressurized gas energy reactor, gas discharge energy reactor, microwave cell energy reactor, and a combination of a glow discharge cell and a microwave and or RF plasma reactor.

In another embodiment, a magnetic field may confine a charged catalyst such as Ar⁺ to a desired region to selectively form a plasma as described in the Noble Gas Catalysts and Products section. In an embodiment of the cell, the reaction is maintained in a magnetic field such as a solenoidal or minimum magnetic (minimum B) field such that a second catalyst such as Ar⁺ is trapped and acquires a longer half-life. The second catalyst may be generated by a plasma formed by hydrogen catalysis using a first catalyst. By confining the plasma, the ions such as the electrons become more energetic, which increases the amount of second catalyst such as Ar⁺. The confinement also increases the energy of the plasma to create more atomic hydrogen.

In another embodiment, a hot filament which dissociates molecular hydrogen to atomic hydrogen and which may also provide an electric field that controls the rate of catalysis may be used to define the desired region in the cell. The plasma may form substantially in the region surrounding the filament wherein at least one of the atomic hydrogen concentration, the catalyst concentration, and the electric field provides a much faster rate of catalysis there than in any undesired region of the reactor.

In another embodiment, the source of atomic hydrogen such as the source of molecular hydrogen or a hydrogen dissociator may be used to determine the desired region of the reactor by providing atomic hydrogen selectively in the desired region.

In an another embodiment, the source of catalyst may determine the desired region of the reactor by providing catalyst selectively in the desired region.

In an embodiment of a microwave power cell, the plasma may be maintained in a desire region by selectively providing microwave energy to that region with at least one antenna 615 or waveguide 619 and RF window 613 shown in FIG. 8. The cell may comprise a microwave cavity which causes the plasma to be localized to the desired region.

### 5. Hydrogen Multicusp Power and Plasma Cell and Diamond Reactor

In an embodiment, the power and plasma cell and diamond reactor comprises a filament, a vacuum vessel capable of pressures above and below atmospheric, a source of atomic hydrogen, a source of catalyst to catalyze atomic hydrogen to a lower-energy state given by Eq. (1), a means to negatively bias the walls of the cell relative to the filament, and magnets to confine a plasma generated in the cell which is formed or enhanced by the catalysis reaction (rt-plasma). In an embodiment, the reactor is described in M. Pealat, J. P. E. Taran, M. Bacal, F. Hillion, J. Chem. Phys., Vol. 82, (1985), p. 45943-4953 and J. Perrin, J. P. M. Schmitt, Chem. Phys. Letts., Vol. 112, (1984), pp. 69-74 which are herein incorporated by reference in their entirety. In this case, in addition, the cell further comprises a source of catalyst to catalyze atomic hydrogen to a lower-energy state given by Eq. (1). An embodiment of the multicusp cell is shown in FIG. 3 wherein the walls are negative biased by a power supply, and magnets such as permanent magnets that enclose the cell to confine the plasma generated inside the cell 200.

### 6. Pulsed Plasma Cell Diamond Synthesis Diamond Reactor

In an embodiment, the plasma cell reactor to generate power and novel hydrogen species and compositions of matter comprising new forms of hydrogen via the catalysis of atomic hydrogen, to generate a plasma and a source of light such as high energy light, extreme ultraviolet light and ultraviolet light, via the catalysis of atomic hydrogen, and a diamond synthetic reactor of the present invention may be a microwave, plasma torch, radio frequency (RF), glow discharge, barrier electrode, plasma electrolysis, or filament cell. Each of these cells comprises: a source of atomic hydrogen; at least one of a solid, molten, liquid, or gaseous catalyst for making hydrinos; and a vessel for reacting hydrogen and the catalyst for making hydrinos. As used herein and as contemplated by the subject invention, the term “hydrogen”, unless specified otherwise, includes not only proteum (¹H), but also deuterium (²H) and tritium (³H).

The following preferred embodiments of the invention disclose numerous property ranges, including but not limited to, pressure, voltage, current, pulsing frequency, power density, peak power, duty cycle, and the like, which are merely intended as illustrative examples. Based on the detailed written description, one skilled in the art would easily be able to practice this invention within other property ranges to produce the desired result without undue experimentation.

The present invention comprises a power source to at least partially maintain the plasma in the cell. The power to maintain a plasma may be intermittent or pulsed. Pulsing may be used to reduce the input power, and it may also provide a time period wherein the field is set to a desired strength by an offset DC, audio, RF, or microwave voltage or electric and magnetic fields which may be below those required to maintain a discharge. One application of controlling the field during the low-field or nondischarge period is to optimize the energy match between the catalyst and the atomic hydrogen. The pulse frequency and duty cycle may also be adjusted. An application of controlling the pulse frequency and duty cycle is to optimize the power balance. In an embodiment, this is achieved by optimizing the reaction rate versus the input power. The amount of catalyst and atomic hydrogen generated by the discharge decay during the low-field or nondischarge period. The reaction rate may be controlled by controlling the amount of catalyst generated by the discharge such as Ar⁺ and the amount of atomic hydrogen wherein the concentration is dependent on the pulse frequency, duty cycle, and the rate of decay. In an embodiment, the pulse frequency is of about 0.1 Hz to about 100 MHz. In another embodiment, the pulse frequency is faster than the time for substantial atomic hydrogen recombination to molecular hydrogen. Based on anomalous plasma afterglow duration studies [R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, in press; R. Mills, “Temporal Behavior of Light-Emission in the Visible Spectral Range from a Ti-K2CO3-H-Cell”, Int. J. Hydrogen Energy, Vol. 26, No. 4, (2001), pp. 327-332], preferably the frequency is within the range of about 1 to about 1000 Hz. In an embodiment, the duty cycle is about 0.001% to about 95%. Preferably, the duty cycle is about 0.1% to about 50%.

The frequency of alternating power may be within the range of about 0.001 Hz to 100 GHz. More preferably the frequency is within the range of about 60 Hz to 10 GHz. Most preferably, the frequency is within the range of about 10 MHz to 10 GHz. The system may comprises two electrodes wherein one or more electrodes are in direct contact with the plasma; otherwise, the electrodes may be separated from the plasma by a dielectric barrier. The peak voltage may be within the range of about 1 V to 10 MV. More preferably, the peak voltage is within the range of about 10 V to 100 kV. Most preferably, the voltage is within the range of about 100 V to 500 V. Alternatively, the system comprises at least one antenna to deliver power to the plasma

In an embodiment of the plasma cell, the catalyst comprises at least one selected from the group of He⁺, Ne⁺, and Ar⁺ wherein the ionized catalyst ion is generated from the corresponding atom by a plasma created by methods such as a glow, inductively or capacitively coupled RF, or microwave discharge. Preferably the hydrogen pressure of the plasma cell is within the range of 1 mTorr to 10,000 Torr, more preferably the hydrogen pressure of the hydrogen microwave plasma is within the range of 10 mTorr to 100 Torr, most preferably, the hydrogen pressure of the hydrogen microwave plasma is within the range of 10 mTorr to 10 Torr.

A microwave plasma cell of the present invention for the catalysis of atomic hydrogen to form increased-binding-energy-hydrogen species and increased-binding-energy-hydrogen compounds comprises a vessel having a chamber capable of containing a vacuum or pressures greater than atmospheric, a source of atomic hydrogen, a source of microwave power to form a plasma, and a catalyst capable of providing a net enthalpy of reaction of m/2·27.2±0.5 eV where m is an integer, preferably m is an integer less than 400. Sources of microwaves known in the art are traveling wave tubes, klystrons, magnetrons, cyclotron resonance masers, gyrotrons, and free electron lasers. The power may be amplified with an amplifier. The power may be delivered by at least one of a waveguide, coaxial cable, and an antenna. A preferred embodiment of pulsed microwaves comprises a magnetron with a pulsed high voltage to the magnetron or a pulsed magnetron current that may be supplied by a pulse of electrons from an electron source such as an electron gun.

The frequency of the alternating power may be within the range of about 100 MHz to 100 GHz. More preferably, the frequency is within the range of about 100 MHz to 10 GHz.

Most preferably, the frequency is within the range of about 1 GHz to 10 GHz or about 2.4 GHz±1 GHz. In an embodiment, the pulse frequency is of about 0.1 Hz to about 100 MHz, preferably the frequency is within the range of about 10 to about 10,000 Hz, most preferably the frequency is within the range of about 100 to about 1000 Hz. In an embodiment, the duty cycle is about 0.001% to about 95%. Preferably, the duty cycle is about 0.1% to about 10%. The peak power density of the pulses into the plasma may be within the range of about 1 W/cm³ to 1 GW/cm³. More preferably, the peak power density is within the range of about 10 W/cm³ to 10 MW/cm³. Most preferably, the peak power density is within the range of about 100 W/cm³ to 10 kW/cm³. The average power density into the plasma may be within the range of about 0.001 W/cm³ to 1 kW/cm³. More preferably, the average power density is within the range of about 0.1 W/cm³ to 100 W/cm³. Most preferably, the average power density is within the range of about 1 W/cm³ to 10 W/cm³.

A capacitively and/or inductively coupled radio frequency (RF) plasma cell of the present invention for the catalysis of atomic hydrogen to form increased-binding-energy-hydrogen species and increased-binding-energy-hydrogen compounds comprises a vessel having a chamber capable of containing a vacuum or pressures greater than atmospheric, a source of atomic hydrogen, a source of RF power to form a plasma, and a catalyst capable of providing a net enthalpy of reaction of m/2·27.2±0.5 eV where m is an integer, preferably m is an integer less than 400. The cell may further comprise at least two electrodes and an RF generator wherein the source of RF power may comprise the electrodes driven by the RF generator. Alternatively, the cell may further comprise a source coil which may be external to a cell wall which permits RF power to couple to the plasma formed in the cell, a conducting cell wall which may be grounded and a RF generator which drives the coil which may inductively and/or capacitively couple RF power to the cell plasma. The RF frequency is preferably within the range of about 100 Hz to about 100 MHz, more preferably within the range about 1 kHz to about 50 MHz, most preferably within the range of about 13.56 MHz±50 MHz. In an embodiment, the pulse frequency is of about 0.1 Hz to about 100 MHz, preferably the frequency is within the range of about 10 Hz to about 10 MHz, most preferably the frequency is within the range of about 100 Hz to about 1 MHz. In an embodiment, the duty cycle is about 0.001% to about 95%. Preferably, the duty cycle is about 0.1% to about 10%. The peak power density of the pulses into the plasma may be within the range of about 1 W/cm³ to 1 GW/cm³. More preferably, the peak power density is within the range of about 10 W/cm³ to 10 MW/cm³. Most preferably, the peak power density is within the range of about 100 W/cm³ to 10 kW/cm³ . The average power density into the plasma may be within the range of about 0.001 W/cm³ to 1 kW/cm³. More preferably, the average power density is within the range of about 0.1 W/cm³ to 100 W/cm³. Most preferably, the average power density is within the range of about 1 W/cm³ to 10 W/cm³.

In another embodiment, an inductively coupled plasma source is a toroidal plasma system such as the Astron system of Astex Corporation described in U.S. Pat. No. 6,150,628 which is herein incorporated by reference in its entirety. The toroidal plasma system may comprise a primary of a transformer circuit. The primary may be driven by a radio frequency power supply. The plasma may be a closed loop which acts at as a secondary of the transformer circuit. The RF frequency is preferably within the range of about 100 Hz to about 100 GHz, more preferably within the range about 1 kHz to about 100 MHz, most preferably within the range of about 13.56 MHz±50 MHz or about 2.4 GHz±1 GHz. In an embodiment, the pulse frequency is of about 0.1 Hz to about 100 MHz, preferably the frequency is within the range of about 10 Hz to about 10 MHz, most preferably the frequency is within the range of about 100 Hz to about 1 MHz. In an embodiment, the duty cycle is about 0.001% to about 95%. Preferably, the duty cycle is about 0.1% to about 10%. The peak power density of the pulses into the plasma may be within the range of about 1 W/cm³ to 1 GW/cm³. More preferably, the peak power density is within the range of about 10 W/cm³ to 10 MW/cm³. Most preferably, the peak power density is within the range of about 100 W/cm³ to 10 kW/cm³. The average power density into the plasma may be within the range of about 0.001 W/cm³ to 1 kW/cm³. More preferably, the average power density is within the range of about 0.1 W/cm³ to 100 W/cm³. Most preferably, the average power density is within the range of about 1 W/cm³ to 10 W/cm³.

In the case of the discharge cell, the discharge voltage may be within the range of about 1000 to about 50,000 volts. The current may be within the range of about 1 μA to about 1 A, preferably about 1 mA. The discharge current may be intermittent or pulsed. Pulsing may be used to reduce the input power, and it may also provide a time period wherein the field is set to a desired strength by an offset voltage which may be below the discharge voltage. One application of controlling the field during the nondischarge period is to optimize the energy match between the catalyst and the atomic hydrogen. In an embodiment, the offset voltage is between, about 0.5 to about 500 V. In another embodiment, the offset voltage is set to provide a field of about 0.1 V/cm to about 50 V/cm. Preferably, the offset voltage is set to provide a field between about 1 V/cm to about 10 V/cm. The peak voltage may be within the range of about 1 V to 10 MV. More preferably, the peak voltage is within the range of about 10 V to 100 kV. Most preferably, the voltage is within the range of about 100 V to 500 V. The pulse frequency and duty cycle may also be adjusted. An application of controlling the pulse frequency and duty cycle is to optimize the power balance. In an embodiment, this is achieved by optimizing the reaction rate versus the input power. The amount of catalyst and atomic hydrogen generated by the discharge decay during the nondischarge period. The reaction rate may be controlled by controlling the amount of catalyst generated by the discharge such as Ar⁺ and the amount of atomic hydrogen wherein the concentration is dependent on the pulse frequency, duty cycle, and the rate of decay. In an embodiment, the pulse frequency is of about 0.1 Hz to about 100 MHz. In another embodiment, the pulse frequency is faster than the time for substantial atomic hydrogen recombination to molecular hydrogen. Based on anomalous plasma afterglow duration studies [R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, in press; R. Mills, “Temporal Behavior of Light-Emission in the Visible Spectral Range from a Ti-K2CO3-H-Cell”, Int. J. Hydrogen Energy, Vol. 26, No. 4, (2001), pp. 327-332], preferably the frequency is within the range of about 1 to about 200 Hz. In an embodiment, the duty cycle is about 0.1% to about 95%. Preferably, the duty cycle is about 1% to about 50%.

In another embodiment, the power may be applied as an alternating current (AC). The frequency may be within the range of about 0.001 Hz to 1 GHz. More preferably the frequency is within the range of about 60 Hz to 100 MHz. Most preferably, the frequency is within the range of about 10 to 100 MHz. The system may comprises two electrodes wherein one or more electrodes are in direct contact with the plasma; otherwise, the electrodes may be separated from the plasma by a dielectric barrier. The peak voltage may be within the range of about 1 V to 10 MV. More preferably, the peak voltage is within the range of about 10 V to 100 kV. Most preferably, the voltage is within the range of about 100 V to 500 V.

In the case of a barrier electrode plasma cell, the frequency is preferably within the range of about 100 Hz to about 10 GHz, more preferably, about 1 kHz to about 1 MHz, most preferably about 5-10 kHz. The voltage is preferably within the range of about 100 V to about 1 MV, more preferably about 1 kV to about 100 kV, and most preferably about 5 to about 10 kV.

In the case of the plasma electrolysis cell, the discharge voltage may be within the range of about 1000 to about 50,000 volts. The current into the electrolyte may be within the range of about 1 μA/cm³ to about 1 A/cm³, preferably about 1 mA/cm³. In an embodiment, the offset voltage is below that which causes electrolysis such as within the range of about 0.001 to about 1.4 V. The peak voltage may be within the range of about 1 V to 10 MV. More preferably, the peak voltage is within the range of about 2 V to 100 kV. Most preferably, the voltage is within the range of about 2 V to 1 kV. In an embodiment, the pulse frequency is within the range of about 0.1 Hz to about 100 MHz. Preferably the frequency is within the range of about 1 to about 200 Hz. In an embodiment, the duty cycle is about 0.1% to about 95%. Preferably, the duty cycle is about 1% to about 50%.

In the case of the filament cell, the field from the filament may alternate from a higher to lower value during pulsing. The peak field may be within the range of about 0.1 V/cm to 1000 V/cm. Preferably, the peak field maybe within the range of about 1 V/cm to 10 V/cm. The off-peak field may be within the range of about 0.1 V to 100 V/cm. Preferably, the off-peak field maybe within the range of about 0.1 V to 1 V/cm. In an embodiment, the pulse frequency is within the range of about 0.1 Hz to about 100 MHz. Preferably the frequency is within the range of about 1 to about 200 Hz. In an embodiment, the duty cycle is about 0.1% to about 95%. Preferably, the duty cycle is about 1% to about 50%.

### 7. Diamond Synthesis

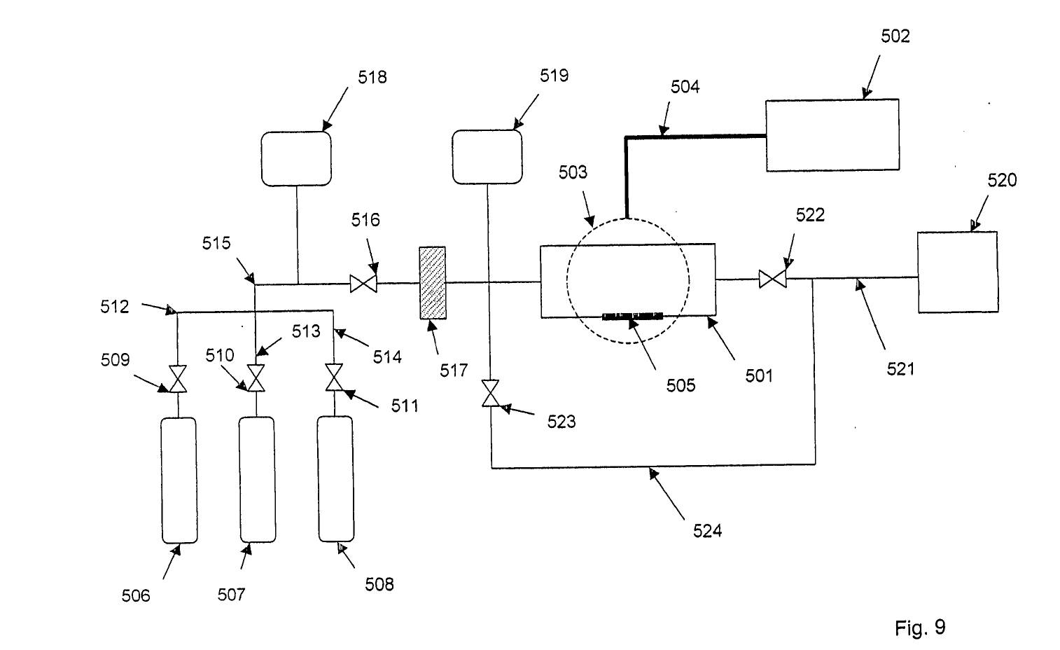

The present invention comprises a cell, system, and methods to form diamond from carbon in a plasma formed or assisted by the catalysis of atomic hydrogen to lower energy states. The mechanism of diamond formation may be based on at least one of the favorable energetics of the plasma or reactions and/or products of the lower-energy hydrogen with carbon. An embodiment of the diamond synthesis reactor of the present invention comprises a reactor of the present invention to catalyze atomic hydrogen to lower-energy states such as an rt-plasma cell and a plasma electrolysis reactor, a barrier electrode reactor, an RF plasma reactor, a pressurized gas energy reactor, a gas discharge energy reactor, a microwave cell energy reactor, and a combination of a glow discharge cell and a microwave and or RF plasma reactor. An embodiment of a diamond reactor shown in FIG. 9 comprises a plasma cell 501 that is a reactor such as a quartz tube and means to maintain a catalyst-hydrogen-carbon source plasma in the cavity such a microwave generator 502, a microwave cavity 503, and a coaxial cable 504. The microwave cavity preferably maintains an E mode such as an Evenson cavity which is a reentrant cavity. A substrate 505 may be placed in the cell and coated with diamond and related materials. The source of catalysts, hydrogen, and carbon may be reservoirs such as catalyst, hydrogen, and carbon-source gas tanks, 506, 507, and 508, respectively, with a corresponding valves 509, 510, and 511 and supply lines 512, 513, 514, and 515 to the cell 501. The flow may be controlled by a valve 516 and a mass flow controller 517. The pressure may be read with a pressure gauges 518 and 519. The plasma gases may be flowed through the cell to a vacuum pump 520 through vacuum line 521 and valve 522 which also maintains the pressure in the cell with the valve 516 and mass flow controller 517. The gas lines 512,513,514, and 515 before the cell 501 may be evacuated using valves 522 and 523 with line 524. A plasma of catalyst-hydrogen-carbon source is maintained in the reactor to form a diamond and related materials on the reactor wall or a substrate 505.

A reactor of the present invention for the synthesis of diamond, hydrogenated diamond, diamond-like carbon, hydrogenated diamond-like carbon or related materials in crystalline form or as thin films comprises a hydrino hydride reactor and a source of carbon. The carbon source may be at least one of the group of glassy carbon, graphitic carbon, pyrolytic carbon, atomic carbon, or hydrocarbons. In an embodiment, the carbon or carbon precursor is supplied to the reactor as a solid. The solid may be placed in the reactor, and the hydrogen catalysis reaction is carried with the carbon present. In another embodiment, carbon is vapor deposited on a desired target such as a substrate in the presence of the hydrogen catalysis reaction. Carbon and carbon precursors may supplied to the hydrogen catalysis reaction to form diamond by methods known to those skilled in the art such as by ion implantation, epitaxy, or vacuum deposition. Apparatus and methods of ion implantation, epitaxy, and vacuum deposition such as those used by persons skilled in the art are described in the following references which are incorporated herein by reference: Fadei Komarov, Ion Beam Modification of Metals, Gordon and Breach Science Publishers, Philadelphia, 1992, especially pp.-1-37.; Emanuele Rimini, Ion Implantation: Basics to Device Fabrication, Kluwer Academic Publishers, Boston, 1995, especially pp. 33-252; 315-348; 173-212; J. F. Ziegler, Editor), Ion Implantation Science and Technology, Second Edition, Academic Press, Inc., Boston, 1988, especially pp. 219-377. In an embodiment, the carbon or carbon precursor deposition rate is in the range of about 1 Å/hr to 100 cm/hr. More preferably, the carbon or carbon precursor deposition rate is in the range of about 10 Å/hr to 10 cm/hr. Most preferably, the carbon or carbon precursor deposition rate is in the range of about 100 Å/hr to 1 mm/hr. The catalyst, hydrogen, and cell parameters are as disclosed previously for production of increased binding energy compounds.

In another embodiment, the source of carbon is supplied as a gas from a gas supply line. The source of carbon may be a hydrocarbon such as methane, propane, butane, pentane, hexane, and longer chain hydrocarbons wherein the number of carbons is less than 100. The hydrocarbon may also contain functional groups such as alcohol, aldehyde, ketone, carboxylic acid, ether, amine, amide, halogens, double bonds, triple bonds, heterocyclic rings, aromatics, and mixtures thereof. In a preferred embodiment, the hydrocarbon is methane.

The hydrocarbon, molecular and atomic hydrogen partial pressures, as well as the catalyst partial pressure, is preferably maintained in the range of about 1 mtorr to about 100 atm. Preferably, the pressure is in the range of about 100 mtorr to about 1 atm, more preferably the pressure is about 100 mtorr to about 20 torr. The catalyst gas may be selected from neon, argon, helium, or mixtures thereof. The flow rate of the catalyst gas, catalyst-hydrogen gas mixture, hydrocarbon gas, hydrogen-hydrocarbon gas mixture, catalyst-hydrogen-hydrocarbon gas mixture, or catalyst-hydrocarbon gas mixture is preferably maintained within the range of about 0.0001-1 standard liters per minute per cm³ of vessel volume, and more preferably about 0.001-10 sccm per cm³ of vessel volume.

In an embodiment, the plasma gas comprises catalyst gas, hydrogen gas, and hydrocarbon gas. The catalyst/hydrogen/hydrocarbon gas composition may be maintained in the composition range of about 0.1-99%/0.1-99%o/0.1-99%. Preferably, the catalyst/hydrogen/hydrocarbon gas composition may be maintained in the composition range of about 1-99%/1-99%/0.1-50%. More preferably, the catalyst/hydrogen/hydrocarbon gas composition may be maintained in the composition range of about 10-900%/10-900%/0.1-10%. Most preferably, the catalyst/hydrogen/hydrocarbon gas composition may be maintained in the composition range of about 20-90%/20-90%o/0.1-5%.

In an embodiment, the plasma gas is a mixture of a catalyst gas/hydrogen gas mixture and hydrocarbon gas. In an embodiment, the catalyst gas/hydrogen gas mixture is 1-99% of the plasma gas and the ratio of the mole fraction of catalyst gas to hydrogen gas is within the range of about 0.01 to 100. More preferably, the ratio of the mole fraction of catalyst gas to hydrogen gas is within the range of about 0.1 to 10. Most preferably, the ratio of the mole fraction of catalyst gas to hydrogen gas is within the range of about 0.2 to 5.

In another embodiment wherein the plasma gas is a mixture of a catalyst gas/hydrogen gas mixture and hydrocarbon gas, the catalyst gas/hydrogen gas mixture is 10-99% of the plasma gas and the ratio of the mole fraction of catalyst gas to hydrogen gas is within the range of about 0.01 to 100. More preferably, the ratio of the mole fraction of catalyst gas to hydrogen gas is within the range of about 0.1 to 10. Most preferably, the ratio of the mole fraction of catalyst gas to hydrogen gas is within the range of about 0.2 to 5.

In another embodiment wherein the plasma gas is a mixture of a catalyst gas/hydrogen gas mixture and hydrocarbon gas, the catalyst gas/hydrogen gas mixture is 50-99% of the plasma gas and the ratio of the mole fraction of catalyst gas to hydrogen gas is within the range of about 0.01 to 100. More preferably, the ratio of the mole fraction of catalyst gas to hydrogen gas is within the range of about 0.1 to 10. Most preferably, the ratio of the mole fraction of catalyst gas to hydrogen gas is within the range of about 0.2 to 5.

In an embodiment, the hydrocarbon gas is the composition range of about 1-99% and the balance is due to catalyst/hydrogen gas mixture which is present in the molar ratios that achieves hydrogen catalysis as disclosed previously such as a catalyst gas to hydrogen gas molar ratio within the range of about 0.1 to 10. More preferably, the hydrocarbon gas is within the composition range of about 1-10% and the balance is due to catalyst/hydrogen gas such as a catalyst gas to hydrogen gas molar ratio within the range of about 0.1 to 10. Most preferably, the hydrocarbon gas composition is within the range of about 1-10% and the balance is due to catalyst/hydrogen gas mixture such as a catalyst gas to hydrogen gas molar ratio within the range of about 0.2 to 5.

In an embodiment of an argon-hydrogen-methane or helium-hydrogen-methane mixture, helium or argon is within the range of about 99 to about 1%, more preferably about 99 to about 60%, and hydrogen and methane make up the balance. The power density of the source of plasma power is preferably in the range of about 0.01 W to about 100 W/cm³ vessel volume.

An exemplary catalyst gas for the microwave cell reactor is helium, neon, or argon. Exemplary flow rates are about 0.1-1 standard liters per minute (slm) hydrogen, about 0.1-1 slm methane, and about 1-10 slm helium, neon, or argon. An exemplary microwave input power for 10 cm of plasma reaction volume is 10-100 W, and an exemplary pressure range is 100 mTorr-10 Torr.

Substrates such as silicon wafers, metals, plastics, aluminum, some glasses, nickel, steel and electronics materials such as GaAs may be coated by placing the substrate in the reactor during diamond formation such that the diamond material is deposited onto the substrate.

Since an energetic diamond-producing plasma forms from the catalysis of atomic hydrogen to lower-energy states, the temperature of the substrate may be low. In an embodiment, the substrate temperature is maintained within the range of about 0 to 10,000° C., preferably the substrate temperature is maintained within the range of about 25° C. to 1000° C., more preferably, the substrate temperature is maintained within the range of about 25° C. to 500° C., and most preferably, the substrate temperature is maintained within the range of about 100° C. to 500° C.

A method of synthesis of diamond of the present invention comprises the steps of supplying carbon atoms to a hydrogen catalysis reaction such that at least one of the unique condition caused by the hydrogen catalysis reaction or the reaction of lower-energy hydrogen species with carbon results in the formation of diamond. In the previously developed CH₄—H₂-system and variations thereof, diamond formation occurs within a small domain about the C—H—O tie line. Stringent conditions of a large excess of hydrogen, diamond seeding, and an elevated temperature are required. Similarly, in the CO₂/CH₄ system, diamond only formed within a range of a few percent from a 50/50% mixture. Polycrystalline diamond films were synthesized on silicon substrates without diamond seeding by a very low power (˜40-80 W) microwave plasma continuous vapor deposition (MPCVD) reaction of a mixture of helium-hydrogen-methane (48.2/48.2/3.6%) or argon-hydrogen-methane (17.5/80/2.5%) [R. Mills, J. Sankar, A. Voigt, J. He, P. Ray, B. Dhandapani, “Role of Atomic Hydrogen Density and Energy in Low Power CVD Synthesis of Diamond Films”, JACS, to be submitted; R. Mills, J. Sankar, A. Voigt, J. He, P. Ray, B. Dhandapani, “Synthesis and Characterization of Diamond Films from MPCVD of an Energetic Argon-Hydrogen Plasma and Methane”, J. of Materials Research, to be submitted; R. L. Mills, J. Sankar, A. Voigt, J. He, B. Dhandapani, “Spectroscopic Characterization of the Atomic Hydrogen Energies and Densities and Carbon Species During Helium-Hydrogen-Methane Plasma CVD Synthesis of Diamond Films”, Chemistry of Materials, Vol. 15, (2003), pp. 1313-1321 which are incorporated by reference in their entirety]. The films were characterized by time of flight secondary ion mass spectroscopy (ToF-SIMS), X-ray photoelectron spectroscopy (XPS), Raman spectroscopy, scanning electron microscopy (SEM), and X-ray diffraction (XRD). In an embodiment, each of He⁺ and Ar⁺ serve as a catalyst with atomic hydrogen to form an energetic plasma since only plasmas having these ions in the presence of atomic hydrogen showed significantly broadened H α lines corresponding to an average hydrogen atom temperature of >100 eV as reported previously [R. L. Mills, P. Ray, B. Dhandapani, R. M. Mayo, J. He, “Comparison of Excessive Balmer α Line Broadening of Glow Discharge and Microwave Hydrogen Plasmas with Certain Catalysts”, J. of Applied Physics, (2002), Vol. 92, No. 12, pp. 7008-7022]. It was found that not only the energy, but also the H density uniquely increases in He—H₂ and Ar—H₂ plasmas. In an embodiment, bombardment of the carbon surface by highly energetic hydrogen formed by the catalysis reaction results in the formation of diamond. Then, by this novel pathway, the relevance of the CO tie line is eliminated along with other stringent conditions to and complicated and inefficient techniques which limit broad application of the versatility and superiority of diamond thin film technology.

In another embodiment, a novel diamond-like carbon film terminated with CH(1/p) (H^{*}DLC) comprising high binding energy hydride ions is synthesized from solid carbon by a microwave plasma reaction of a mixture of 10-30% hydrogen and 90-70% helium wherein He⁺ served as a catalyst with atomic hydrogen to form the highly stable hydride ions [R. L. Mills, J. Sankar, A. Voigt, J. He, B. Dhandapani, “Synthesis of HDLC Films from Solid Carbon”, Thin Solid Films, submitted which is herein incorporated by reference in its entirety]. H* DLC was identified by time of flight secondary ion mass spectroscopy (ToF-SIMS) and X-ray photoelectron spectroscopy (XPS). TOF-SIMS identified the coatings as hydride by the large H⁺ peak in the positive spectrum and the dominant H⁻ in the negative spectrum. The XPS identification of the H content of the CH coatings as hydride ion H⁻( 1/10) corresponding to a peak at 49 eV indicted that the mechanism of the diamond-like carbon formation involves at least one of selective etching of graphitic carbon and the activation of surface carbon by the hydrogen catalysis product. Thus, a novel H intermediate formed by the plasma catalysis reaction may serve the role of H, oxygen species, CO, or halogen species used in past systems. Bombardment of the diamond surface by observed, highly energetic species formed by the catalysis reaction may also form DLC or diamond.

In another embodiment, diamond formation is based on energetic species formed in the plasma caused by or enhanced by the catalysis of atomic hydrogen called an rt-plasma Diamond-like carbon (DLC) is a metastable material; thus, continuous bombardment of the surface with energetic species that produce thermal and pressure spikes at the growth surface is required for deposition of DLC and related films. The formation of fast H in rt-plasmas is disclosed in previous publications such as R. L. Mills, P. Ray, E. Dayalan, B. Dhandapani, J. He, “Comparison of Excessive Balmer α Line Broadening of Inductively and Capacitively Coupled RF, Microwave, and Glow Discharge Hydrogen Plasmas with Certain Catalysts”, IEEE Transactions on Plasma Science, June, (2003); R. L. Mills, P. Ray, B. Dhandapani, R. M. Mayo, J. He, “Comparison of Excessive Balmer α Line Broadening of Glow Discharge and Microwave Hydrogen Plasmas with Certain Catalysts”, J. of Applied Physics, (2002), Vol. 92, No. 12, pp. 7008-7022; R. Mills and M. Nansteel, P. Ray, “Bright Hydrogen-Light Source due to a Resonant Energy Transfer with Strontium and Argon Ions”, New Journal of Physics, Vol. 4, (2002), pp. 70.1-70.28; R. L. Mills, P. Ray, “Substantial Changes in the Characteristics of a Microwave Plasma Due to Combining Argon and Hydrogen”, New Journal of Physics, www.njp.org, Vol. 4, (2002), pp. 22.1-22.17; R. Mills and M. Nansteel, P. Ray, “Argon-Hydrogen-Strontium Discharge Light Source”, IEEE Transactions on Plasma Science, Vol. 30, No. 2, (2002), pp. 639-653; R. L. Mills, P. Ray, “Spectroscopic Characterization of Stationary Inverted Lyman Populations and Free-Free and Bound-Free Emission of Lower-Energy State Hydride Ion Formed by a Catalytic Reaction of Atomic Hydrogen and Certain Group I Catalysts”, Journal of Quantitative Spectroscopy and Radiative Transfer, in press; R. Mills, P. Ray, R. M. Mayo, “CW HI Laser Based on a Stationary Inverted Lyman Population Formed from Incandescently Heated Hydrogen Gas with Certain Group I Catalysts”, IEEE Transactions on Plasma Science, in press; R. Mills, P. Ray, R. M. Mayo, “Stationary Inverted Balmer and Lyman Populations for a CW HI Water-Plasma Laser”, IEEE Transactions on Plasma Science, submitted which are herein incorporated by reference in their entirety. The plasma may be a catalyst-hydrogen plasma. The plasma cell may be a microwave cell, RF cell, glow discharge cell, barrier electrode, or filament cell. The source of carbon may be by sputter vapor deposition from a solid source by the plasma of a microwave cell, RF cell, glow discharge cell, or a barrier electrode cell. In an embodiment, the formation of diamond, diamond films, and related materials may be by vapor deposition of carbon in the presence of a neon-hydrogen plasma, helium-hydrogen plasma, or an argon-hydrogen plasma wherein Ne⁺, He⁺, or Ar⁺ serves as a catalyst, respectively.

In an embodiment, the formation of diamond, diamond films, and related materials may be by the deposition of carbon from a hydrocarbon in the presence of a neon-hydrogen plasma, helium-hydrogen plasma, or an argon-hydrogen plasma wherein Ne⁺, He⁺, or Ar⁺ serves as a catalyst, respectively. Preferably the hydrocarbon is propane. More preferably, the hydrocarbon is butane. Most preferably, the hydrocarbon is methane. The cell may be maintained in normal the pressure range to achieve hydrogen catalysis given previously such as in the range. The

Alternatively, the binding of novel H to carbon such as graphitic carbon causes a conversion to the diamond form. Novel EUV emission lines from microwave and glow discharges of helium with 2% hydrogen with energies of q·13.6 eV where q=1,2,3,4,6,7,8,9,11,12 or these lines inelastically scattered by helium atoms in the excitation of He (1s²) to He (1s¹2p¹) were identified as novel H intermediates [R. L. Mills, P. Ray, B. Dhandapani, M. Nansteel, X. Chen, J. He, “New Power Source from Fractional Quantum Energy Levels of Atomic Hydrogen that Surpasses Internal Combustion”, J Mol. Struct., Vol. 643, No. 1-3, (2002), pp.43-54]. And, novel hydride compounds MH* and MH*₂ wherein M is the alkali or alkaline earth metal and H*comprising a novel high binding energy hydride ions were identified previously [R. Mills, B. Dhandapani, M. Nansteel, J. He, A. “Voigt, Identification of Compounds Containing Novel Hydride Ions by Nuclear Magnetic Resonance Spectroscopy”, Int. J. Hydrogen Energy, Vol. 26, No. 9, September (2001), pp. 965-979; R. Mills, B. Dhandapani, N. Greenig, J. He, “Synthesis and Characterization of Potassium Iodo Hydride”, Int. J. of Hydrogen Energy, Vol. 25, Issue 12, December, (2000), pp. 1185-1203; R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367; R. Mills, P. Ray, B. Dhandapani, W. Good, P. Jansson, M. Nansteel, J. He, A. Voigt, “Spectroscopic and NMR Identification of Novel Hydride Ions in Fractional Quantum Energy States Formed by an Exothermic Reaction of Atomic Hydrogen with Certain Catalysts”, J. Phys. Chem. A, submitted] by a large distinct upfield resonance that showed that the hydride ion was different from the hydride ion of the corresponding known compound of the same composition [R. Mills, B. Dhandapani, M. Nansteel, J. He, A. “Voigt, Identification of Compounds Containing Novel Hydride Ions by Nuclear Magnetic Resonance Spectroscopy”, Int. J. Hydrogen Energy, Vol. 26, No. 9, September (2001), pp. 965-979.]. It was observed that the presence of less than 1% novel hydride in KCl forming some KHCl dramatically changed the water solubility of KCl. In this case, the binding of small amounts of novel hydride ion may have stabilized KCl such that the thermodynamic equilibrium for dissolving into water was reduced. Similarly, in the case of carbon, in an embodiment, novel hydrogen is generated by the hydrogen catalysis reaction and binds to carbon such that the binding of the novel H thermodynamically favors the diamond form of carbon over the graphitic to cause the formation of diamond.

In another embodiment, at least one of carbon nanotubes and fullerenes are formed by the deposition of carbon in the presence of an rt-plasma such as a helium-hydrogen plasma as disclosed herein for the synthesis of diamond and diamond related materials. In an embodiment a high carbon deposition rate is run to favor the formation of at least one of carbon nanotubes and fullerenes over the formation of diamond and diamond related materials.

7.1 Exemplary Diamond Material Synthesis

Diamond films were grown on silicon wafer substrates by their exposure to a low pressure He—H₂—CH₄ microwave plasma as described in R. L. Mills, J. Sankar, A. Voigt, J. He, B. Dhandapani, “Spectroscopic Characterization of the Atomic Hydrogen Energies and Densities and Carbon Species During Helium-Hydrogen-Methane Plasma CVD Synthesis of Diamond Films”, Chemistry of Materials, Vol. 15, (2003), pp. 1313-1321. which is herein incorporated by reference in its entirety. The experimental set up comprising a microwave discharge cell operated under flow conditions is shown in FIG. 1 of R. L. Mills, J. Sankar, A. Voigt, J. He, B. Dhandapani, “Spectroscopic Characterization of the Atomic Hydrogen Energies and Densities and Carbon Species During Helium-Hydrogen-Methane Plasma CVD Synthesis of Diamond Films”, Chemistry of Materials, Vol. 15, (2003), pp. 1313-1321. A silicon wafer substrate (0.5×0.5×0.05 cm, Silicon Quest International, silicon (100), boron doped) cleaned by heating to 700° C. under vacuum was placed about 2 cm off center inside of a quartz tube (1.2 cm in diameter by 25 cm long) with vacuum valves at both ends. The tube was center-fitted with an Opthos coaxial microwave cavity (Evenson cavity) and connected to the gas/vacuum line. The quartz tube and vacuum line were evacuated for 2 hours to remove any trace moisture or oxygen and residual gases. Premixed He—H₂ (50/50%) was further mixed with CH₄ such that a He—H₂—CH₄ (48.2/48.2/3.60%) gas mixture was introduced through the quartz tube reactor at a total pressure of 3 Torr as monitored by an absolute pressure gauge. The corresponding gas flow rates controlled by mass flow controllers were maintained at 60 sccm and 2.25 sccm for He—H₂ and CH₄, respectively. In separate experiments, the helium-hydrogen premixed gas was varied from (90/10%) to (50/50%). Since the best diamond film results were obtained with the (50/50%) mixture, only these results will be presented.

The microwave generator shown in FIG. 1 was an Opthos model MPG4M generator (Frequency 2450 MHz). The microwave plasma was maintained with a 40 W (forward)/2 W (reflected) power for about 12-16 hrs. The substrate was at the cool edge of the plasma glow region. The wall temperature at this position measured with a contacting thermocouple was about 300° C. A thick (˜100 μm ) crystalline, shiny coating formed on the substrate and the wall of the quartz reactor.

Diamond films were grown on silicon wafer substrates by their exposure to a low pressure Ar—H₂—CH₄ microwave plasmas described in R. Mills, J. Sankar, A. Voigt, J. He, P. Ray, B. Dhandapani, “Synthesis and Characterization of Diamond Films from MPCVD of an Energetic Argon-Hydrogen Plasma and Methane”, J. of Materials Research, to be submitted which is herein incorporated by reference in its entirety. The experimental set up comprising a microwave discharge cell operated under flow conditions is shown in FIG. 1 of R. Mills, J. Sankar, A. Voigt, J. He, P. Ray, B. Dhandapani, “Synthesis and Characterization of Diamond Films from MPCVD of an Energetic Argon-Hydrogen Plasma and Methane”, J. of Materials Research, to be submitted. A silicon wafer substrate (0.5×0.5×0.05 cm, Silicon Quest International, silicon (100), boron doped) was cleaned by using 2% HF, rinsed with ultrapure water and placed inside the reactor tube heating, evacuated and heated to 500° C. under vacuum for 30 minutes. The wafer was placed about 2 cm off center inside of a quartz tube (1.2 cm in diameter by 25 cm long) with vacuum valves at both ends. The tube was center-fitted with an Opthos coaxial microwave cavity (Evenson cavity) and connected to the gas/vacuum line. The quartz tube and vacuum line were evacuated for 2 hours to remove any trace moisture or oxygen and residual gases. The precursor reactant gases CH₄, H₂, and Ar were introduced through the quartz tube reactor at a total pressure of 2.5 Torr as monitored by an absolute pressure gauge. The corresponding gas flow rates controlled by mass flow controllers were maintained at 2, 65 and 15 sccm for CH₄, H₂, and Ar, respectively.

The microwave generator was an Opthos model MPG-4M generator (Frequency: 2450 MHz). The microwave plasma was maintained with a 82 W (forward)/2 W (reflected) power for about 12-15 hrs. The substrate was at the cool edge of the plasma glow region. The wall temperature at this position measured with a contacting thermocouple was about 350° C. A thick (˜10 μm ) crystalline, shiny coating formed on the substrate.

H*DLC films were grown on silicon wafer substrates by their exposure to a low pressure He/H₂ microwave plasma with 0.1 g of solid glassy carbon foil (0.5×0.5×0.1 cm, Alpha Aesar 99.99%) or graphite foil (1×1×0.1 cm, Alpha Aesar 99.99%) [R. L. Mills, J. Sankar, A. Voigt, J. He, B. Dhandapani, “Synthesis of HDLC Films from Solid Carbon”, Thin Solid Films, submitted which is herein incorporated by reference in its entirety]. The experimental set up comprising a microwave discharge cell operated under flow conditions is shown in FIG. 1 of R. L. Mills, J. Sankar, A. Voigt, J. He, B. Dhandapani, “Synthesis of HDLC Films from Solid Carbon”, Thin Solid Films, submitted which is herein incorporated by reference in its entirety. The carbon source was placed in the center of the microwave cavity, and a silicon wafer substrate (0.5×0.5×0.05 cm, Alfa Aesar 99+%) cleaned by heating to 700° C. under vacuum was placed about 2 cm off center inside of a quartz tube (1.2 cm in diameter by 25 cm long) with vacuum valves at both ends. The tube was center-fitted with an Opthos coaxial microwave cavity (Evenson cavity) and connected to the gas/vacuum line. The quartz tube and vacuum line were evacuated for 2 hours to remove any trace moisture or oxygen and residual gases. A premixed He (90-70%)/H₂ (10-30%) plasma gas was flowed through the quartz tube at a total pressure of 1.5 Torr maintained with a gas flow rate of 40 sccm controlled by a mass flow controller with a readout. The cell pressure was monitored by an absolute pressure gauge. The microwave generator was an Opthos model MPG-4M generator (Frequency: 2450 MHz). The microwave plasma was maintained with a 65 W (forward)/4 W (reflected) power for about 12-16 hrs. The carbon source was located in the center of the plasma, and the substrate was at the cool edge of the plasma glow region. The wall temperature at this position was about 300° C. A thick (˜100 μm) translucent, golden-yellow, shiny coating formed on the substrate and the wall of the quartz reactor. The quartz tube was removed and transferred to a drybox with the samples inside by closing the vacuum valves at both ends and detaching the tube from the vacuum/gas line. The coating on the inside of the wall of the reactor tube was collected by etching the tube for 5-10 minutes with 1% dilute hydrofluoric acid. The coating was then detached from the surface and peeled off as a 3 cm long unsupported transparent thin film.

1. A reactor for producing diamond, hydrogenated diamond, diamond-like carbon, hydrogenated diamond-like carbon or related materials in crystalline form or as thin films comprising:
a plasma forming cell for the catalysis of atomic hydrogen to lower-energy hydrogen producing an energetic plasma which forms a diamond, hydrogenated diamond, diamond-like carbon, hydrogenated diamond-like carbon or related materials in crystalline form or as thin films,
a source of catalyst for catalyzing the reaction of atomic hydrogen to lower-energy hydrogen,
a source of atomic hydrogen, and
a source of carbon.

2. A reactor of claim 1 further comprising a substrate to be coated with the diamond, hydrogenated diamond, diamond-like carbon, hydrogenated diamond-like carbon or related materials in crystalline form or as thin films.

3. A reactor of claim 1 wherein the substrate is selected from at least one of the group of silicon wafers, metals, plastics, aluminum, some glasses, nickel, steel and electronics materials such as GaAs.

4. A reactor of claim 1 wherein the carbon source comprises at least one of the group of glassy carbon, graphitic carbon, pyrolytic carbon, atomic carbon, or hydrocarbons.

5. A reactor of claim 1 wherein the carbon source comprises carbon or carbon precursor that is supplied to the reactor as a solid.

6. A reactor of claim 1 further comprising at least one gas supply wherein the source of carbon is a gas.

7. A reactor of claim 1 wherein the source of carbon of comprises a hydrocarbon.

8. A reactor according to claim 7 wherein the hydrocarbon comprises at least one selected from methane, propane, butane, pentane, hexane, and longer chain hydrocarbons wherein the number of carbons is less than 100.

9. A reactor according to claim 8 wherein the hydrocarbon contains at least one functional group selected from alcohol, aldehyde, ketone, carboxylic acid, ether, amine, amide, halogens, double bonds, triple bonds, heterocyclic rings, aromatics, and mixtures thereof.

10. A reactor according to claim 1 wherein the source of catalyst comprises at least one of neon, argon, helium, or mixtures thereof.

11. A reactor according to claim 10 wherein the catalyst from the source of catalysts comprises at least one of He⁺, Ne⁺, or Ar⁺.

12. A reactor according to claim 1 wherein the plasma gas comprises catalyst gas, hydrogen gas, and hydrocarbon gas.

13. A reactor according to claim 12 wherein the catalyst/hydrogen/hydrocarbon gas composition is maintained in the composition range of about 0.1-99%/0.1-99%/0.1-99%.

14. A reactor according to claim 12 wherein the catalyst/hydrogen/hydrocarbon gas composition is maintained in the composition range of about 1-99%/1-99%/0.1-50%.

15. A reactor according to claim 12 wherein the catalyst/hydrogen/hydrocarbon gas composition is maintained in the composition range of about 10-90%/10-90%/0.1-10%.

16. A reactor according to claim 12 wherein the catalyst/hydrogen/hydrocarbon gas composition is maintained in the composition range of about 20-90%/20-90%/0.1-5%.

17. A reactor of claim 1 wherein the plasma gas is a mixture of a catalyst gas/hydrogen gas mixture and hydrocarbon gas.

18. A reactor of claim 17 wherein the catalyst gas/hydrogen gas mixture is 1-99% of the plasma gas and the ratio of the mole fraction of catalyst gas to hydrogen gas is within the range of about 0.01 to 100; more preferably, the ratio of the mole fraction of catalyst gas to hydrogen gas is within the range of about 0.1 to 10, and most preferably, the ratio of the mole fraction of catalyst gas to hydrogen gas is within the range of about 0.2 to 5.

19. A reactor of claim 17 wherein the catalyst gas/hydrogen gas mixture is 10-99% of the plasma gas and the ratio of the mole fraction of catalyst gas to hydrogen gas is within the range of about 0.01 to 100; more preferably, the ratio of the mole fraction of catalyst gas to hydrogen gas is within the range of about 0.1 to 10, and most preferably, the ratio of the mole fraction of catalyst gas to hydrogen gas is within the range of about 0.2 to 5.

20. A reactor of claim 17 wherein the catalyst gas/hydrogen gas mixture is 50-99% of the plasma gas and the ratio of the mole fraction of catalyst gas to hydrogen gas is within the range of about 0.01 to 100; more preferably, the ratio of the mole fraction of catalyst gas to hydrogen gas is within the range of about 0.1 to 10, and most preferably, the ratio of the mole fraction of catalyst gas to hydrogen gas is within the range of about 0.2 to 5.

21. A reactor of claim 12 wherein the hydrocarbon gas is the composition range of about 1-99% and the balance is due to catalyst/hydrogen gas mixture which is present in the molar ratios that achieves hydrogen catalysis.

22. A reactor of claim 12 wherein the hydrocarbon gas is the composition range of about 1-99% and the balance is due to catalyst/hydrogen gas mixture such that the catalyst gas to hydrogen gas molar ratio is within the range of about 0.1 to 10.

23. A reactor of claim 12 wherein the hydrocarbon gas is the composition range of about 1-10% and the balance is due to catalyst/hydrogen gas mixture such that the catalyst gas to hydrogen gas molar ratio is within the range of about 0.1 to 10.

24. A reactor of claim 12 wherein the hydrocarbon gas is the composition range of about 1-10% and the balance is due to catalyst/hydrogen gas mixture such that the catalyst gas to hydrogen gas molar ratio is within the range of about 0.2 to 5.

25. A reactor of claim 17 wherein at least one of helium, neon, and argon is the catalyst gas and at least one of methane, butane, propane, and butane is the hydrocarbon gas.

26. A reactor of claim 25 comprising an argon-hydrogen-hydrocarbon or helium-hydrogen-methane mixture wherein helium or argon is within the range of about 99 to about 1%, more preferably about 99 to about 60%, and hydrogen and hydrocarbon gas make up the balance.

27. A reactor of claim 26 wherein the power density of the source of plasma power is at least one of within a range of about 0.01 W to about 100 W/cm³ vessel volume and about 1 to 10 W/cm³ vessel volume.

28. A reactor of claim 17 wherein the plasma cell is a microwave cell, the catalyst gas is at least one of helium, neon, and argon, the hydrocarbon gas is methane, the plasma gas flow rate is about 0.1-1 standard liters per minute (slm) hydrogen, about 0.1-1 slm methane, and about 1-10 slm helium, neon, or argon, the microwave input power for 10 cm of plasma reaction volume is 10-100 W, and the plasma gas pressure range is 100 mTorr-10 Torr.

29. A reactor of claim 1 wherein the energetic plasma is formed by at least one of the catalysts He⁺ and Ar⁺ reacting with atomic hydrogen to form increased-biding-energy hydrogen.

30. A reactor of claims 1 and 29 wherein the catalysis of atomic hydrogen forms an energetic plasma having broadened H α lines corresponding to an average hydrogen atom temperature of >100 eV.

31. A reactor of claims 1 and 29 wherein the catalysis of atomic hydrogen forms an energetic plasma having broadened H α lines corresponding to an average hydrogen atom temperature that is greater than that in the absence of the catalyst.

32. A reactor of claims 1 and 29 wherein the catalysis of atomic hydrogen forms an energetic plasma having broadened H α lines corresponding to an average hydrogen atom temperature within the range of about 5 eV to 200 eV.

33. A reactor of claim 2 wherein carbon is deposited on a substrate in the presence of the plasma and is converted to diamond.

34. A reactor of claim 33 wherein the carbon or carbon precursor deposition rate is at least one of within the range of about 1 Å/hr to 100 cm/hr, about 10 Å/hr to 10 cm/hr, and about 100 Å/hr to 1 mm/hr.

35. A reactor of claim 1 wherein novel hydrogen species and compositions of matter comprising new forms of hydrogen comprise novel diamond-like carbon film terminated with CH(1/p) (H*DLC) wherein the hydrogen comprises at least one of high binding energy hydride ions and high-binding energy hydrogen atoms.

36. A reactor of claim 35, wherein the CH(1/p) is synthesized from solid carbon by a microwave plasma reaction of a mixture of 10-30% hydrogen and 90-70% helium wherein He⁺ served as a catalyst with atomic hydrogen to form the highly stable hydride ions.

37. A reactor of claim 1 wherein novel hydrogen species and compositions of matter comprising new forms of hydrogen of comprise a novel H intermediate formed by the plasma catalysis reaction that serves the role of H, oxygen species, CO, or halogen species and other such species that provide selective etching of graphitic carbon.

38. A reactor of claim 1 wherein novel hydrogen species and compositions of matter comprise new forms of hydrogen comprising at least one novel H intermediate to form diamond by selective etching of graphitic carbon.

39. A reactor of claim 1 wherein novel hydrogen species and compositions of matter comprising new forms of hydrogen comprise at least one novel H intermediate that forms diamond by its activation of surface carbon such that diamond and related materials are thermodynamically or kinetically formed over graphitic carbon.

40. A reactor of claim 2 wherein bombardment of a carbon surface deposited on a substrate by highly energetic species formed by the catalysis reaction forms DLC or diamond.

41. A reactor of claim 1 wherein fast hydrogen atoms are formed by the catalysis of atomic hydrogen to lower-energy states with energy levels of about
$$\frac{13.6 eV}{{( \frac{1}{p} )}^{2}}$$
where p is an integer, and fast H bombardment of carbon forms diamond and related materials such as diamond-like carbon.

42. A reactor of claim 1 wherein the power density to form a diamond-forming-plasma is low.

43. A reactor of claim 1 wherein the voltage to the cell to form a diamond-forming-plasma is low.

44. A reactor of claim 1 wherein the substrate temperature to form diamond is low.

45. A reactor of claim 2 further comprising means to maintain the temperature of the substrate.

46. A reactor of claim 45 wherein since an energetic diamond-producing plasma forms from the catalysis of atomic hydrogen to lower-energy states, the temperature of the substrate may be low.

47. A reactor of claim 46 wherein the substrate temperature is maintained within the range of about 0 to 10,000° C., preferably the substrate temperature is maintained within the range of about 25° C. to 1000° C., more preferably, the substrate temperature is maintained within the range of about 25° C. to 500° C., and most preferably, the substrate temperature is maintained within the range of about 100° C. to 500° C.

48. A reactor of claim 1 wherein polycrystalline diamond films a synthesized on silicon substrates without diamond seeding by a very low power (˜40-80 W) microwave plasma continuous vapor deposition (MPCVD) reaction of a mixture of helium-hydrogen-methane (48.2/48.2/3.6%) or argon-hydrogen-methane (17.5/80/2.5%).

49. A reactor of claim 1 wherein the total plasma gas pressure is maintained in the range of about of 0.1 mTorr to 10,000 Torr, preferably the pressure of plasma gas is in the range of 10 mTorr to 100 Torr, more preferably, the pressure of plasma gas is in the range of 10 mTorr to 10 Torr; most preferably, the pressure of plasma gas is in the range of 10 mTorr to 1 Torr, and the plasma gas flow rate is preferably about 0-1 standard liters per minute per cm³ of vessel volume and more preferably about 0.001-10 sccm per cm³ of vessel volume.

50. A reactor of claim 12 wherein the flow rate of the catalyst gas, catalyst-hydrogen gas mixture, hydrocarbon gas, hydrogen-hydrocarbon gas mixture, catalyst-hydrogen-hydrocarbon gas mixture, or catalyst-hydrocarbon gas mixture is maintained in at least one of the ranges of about 0.0001-1 standard liters per minute per cm³ of vessel volume, about 0.001-10 sccm per cm³ of vessel volume.

51. A reactor of claim 1 wherein the power density of the source of plasma power is in the range of about 0.01 W to about 100 W/cm³ vessel volume; preferably in the range of about 1 to 10 W/cm³ vessel volume.

52. A reactor of claim 1 wherein the energetic plasma causes at least one of carbon nanotubes and fullerenes to formed by the deposition of carbon in the presence the plasma.

53. A reactor of claim 52 wherein the source of catalyst is helium, neon, or argon.

54. A method of synthesis of diamond, hydrogenated diamond, diamond-like carbon, hydrogenated diamond-like carbon or related materials of claim comprising the step of supplying solid carbon to the diamond reactor of claim 1 in the presence of the plasma.

55. A method of claim 54 wherein carbon is vapor deposited on a desired target such as a substrate in the presence of the hydrogen catalysis reaction.

56. A method of claim 54 comprising depositing carbon on a target comprising at least one of the group of ion implantation, epitaxy, or vacuum deposition.

57. A method of coating a substrate comprising the steps of placing the substrate in the reactor of claim 1 wherein the substrate comprises at least one of silicon wafers, metals, plastics, aluminum, some glasses, nickel, steel and electronics materials such as GaAs.

58. A method of the forming at least one of carbon nanotubes and fullerene in a reactor of claim 1 comprising providing a high carbon deposition rate to favor the formation of at least one of carbon nanotubes and fullerenes over the formation of diamond and diamond related materials.

59. A method of claim 58 wherein the source of catalyst is helium, neon, or argon.

60. A method of claim 54 further comprising the steps of flowing a plasma gas that is a source of catalyst into the vessel.

61. A method of claim 54 comprising controlling the power by controlling the amount of gaseous catalyst.

62. A method of claim 61 comprising controlling the amount of gaseous catalyst by controlling the plasma gas flow rate.

63. A method of claim 54 comprising controlling the power by controlling the amount of hydrogen.

64. A method of claim 63 comprising controlling the power by controlling the flow of hydrogen from the source of hydrogen.

65. A method of claim 64 comprising controlling the power by controlling the flow of hydrogen and plasma gas and the ratio of hydrogen to plasma gas in a mixture.

66. A method of claim 61 wherein the source of catalyst is at least one selected from the group of helium, neon, argon, water vapor, or ammonia which provides catalysts He⁺, Ne⁺, Ar⁺, O₂, and N₂, respectively.

67. A method of claim 54 comprising controlling the power by controlling the hydrogen flow rate, plasma gas flow rate, and hydrogen-plasma-gas flow rate with at least one of the group of a flow regulator, a hydrogen-plasma-gas mixer, flow rate controllers, and valves.

68. A method of claim 54 comprising controlling the power controlling the temperature of the plasma with the power supplied by a source of microwave power.

69. A method of claim 54 further comprising the steps of providing a source of catalyst from a catalyst reservoir.

70. A method of claim 69 comprising the steps of controlling the temperature of the catalyst from a catalyst reservoir to control its vapor pressure.

71. A method of claim 54 further comprising the steps of providing a source of catalyst from a catalyst boat.

72. A method of claim 54 comprising the steps of controlling the temperature of the catalyst from a catalyst boat to control its vapor pressure.

73. A reactor of claim 1 wherein the catalyst comprises a chemical or physical process that provides a net enthalpy of m·27.2±0.5 eV where m is an integer or m/2·27.2±0.5 eV where m is an integer greater than one.

74. A reactor of claim 1 wherein the catalyst provides a net enthalpy of m·27.2±0.5 eV where m is an integer or m/2·27.2±0.5 eV where m is an integer greater than one corresponding to a resonant state energy level of the catalyst that is excited to provide the enthalpy.

75. A reactor of claim 1 wherein a catalytic system is provided by the ionization of t electrons from a participating species such as an atom, an ion, a molecule, and an ionic or molecular compound to a continuum energy level such that the sum of the ionization energies of the t electrons is approximately m·27.2±0.5 eV where m is an integer or m/2·27.2±0.5 eV where m is an integer greater than one and t is an integer.

76. A reactor of claim 1 wherein the catalyst is provided by the transfer of t electrons between participating ions; the transfer of t electrons from one ion to another ion provides a net enthalpy of reaction whereby the sum of the ionization energy of the electron donating ion minus the ionization energy of the electron accepting ion equals approximately m·27.2±0.5 eV where m is an integer or m/2·27.2±0.5 eV where m is an integer greater than one and t is an integer.

77. A reactor of claims 73-76 wherein m is an integer less than 400.

78. A reactor of claim 1 wherein the catalyst comprises He⁺ which absorbs 40.8 eV during the transition from the n=1 energy level to the n=2 energy level which corresponds to 3/2·27.2 eV (m=3) that serves as a catalyst for the transition of atomic hydrogen from the n=1 (p=1) state to the n=½ (p=2) state.

79. A reactor of claim 1 wherein the catalyst comprises Ar²⁺ which absorbs 40.8 eV and is ionized to Ar³⁺ which corresponds to 3/2·27.2 eV (m=3) during the transition of atomic hydrogen from the n=1 (p=1) energy level to the n=½ (p=2) energy level.

80. A reactor of claim 1 wherein the catalyst is selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Sr⁺, Fe³⁺, Mo²⁺, Mo⁴⁺, and In³⁺.

81. A reactor of claim 1 wherein the catalyst comprises atomic hydrogen capable of providing a net enthalpy of m·27.2±0.5 eV where m is an integer or m/2·27.2±0.5 eV where m is an integer greater than one and capable of forming a hydrogen atom having a binding energy of about
$$\frac{13.6 eV}{{( \frac{1}{p} )}^{2}}$$
where p is an integer wherein the net enthalpy is provided by the breaking of a molecular bond of the catalyst and the ionization of t electrons from an atom of the broken molecule each to a continuum energy level such that the sum of the bond energy and the ionization energies of the t electrons is approximately m·27.2±0.5 eV where m is an integer or m/2·27.2±0.5 eV where m is an integer greater than one.

82. A reactor of claim 1 wherein the catalyst comprises at least one of C₂, N₂, O₂, CO₂, NO₂, and NO₃.

83. A reactor of claim 1 wherein the catalyst comprises a molecule in combination with an ion or atom catalyst.

84. A reactor of claim 83 wherein the catalyst comprises at least one molecule selected from the group of C₂, N₂, O₂, CO₂, NO₂, and NO₃ in combination with at least one atom or ion selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Sr⁺, Fe³⁺, Mo²⁺, Mo⁴⁺, In³⁺, He⁺, Ar⁺, Xe⁺, Ar²⁺ and H⁺, and Ne⁺ and H⁺.

85. A reactor of claim 1 wherein the catalyst comprises a helium excimer, Ne₂*, which absorbs 27.21 eV and is ionized to 2Ne⁺, to catalyze the transition of atomic hydrogen from the (p) energy level to the (p+1) energy level given by
$$27.21 eV + {Ne}_{2}^{*} + H [ \frac{{a}_{H}}{p} ] -> 2 {Ne}^{+} + H [ \frac{{a}_{H}}{( p + 1 )} ] + [ {( p + 1 )}^{2} - {p}^{2} ] X13 .6 eV$$
$$2 {Ne}^{+} -> {Ne}_{2}^{*} + 27.21 eV$$
And, the overall reaction is
$$H [ \frac{{a}_{H}}{p} ] -> H [ \frac{{a}_{H}}{( p + 1 )} ] + [ {( p + 1 )}^{2} - {p}^{2} ] \times 13.6 eV$$

86. A reactor of claim 1 wherein the catalyst comprises helium excimer, He₂*, which absorbs 27.21 eV and is ionized to 2He⁺, to catalyze the transition of atomic hydrogen from the (p) energy level to the (p+1) energy level given by
$$27.21 eV + {He}_{2}^{*} + H [ \frac{{a}_{H}}{p} ] -> 2 {He}^{+} + H [ \frac{{a}_{H}}{( p + 1 )} ] + [ {( p + 1 )}^{2} - {p}^{2} ] \times 13.6 eV$$
2He⁺→He₂*+27.21 eV
And, the overall reaction is
$$H [ \frac{{a}_{H}}{p} ] -> H [ \frac{{a}_{H}}{( p + 1 )} ] + [ {( p + 1 )}^{2} - {p}^{2} ] \times 13.6 eV$$

87. A reactor of claim 1 wherein the catalyst comprises two hydrogen atoms which absorbs 27.21 eV and is ionized to 2H⁺, to catalyze the transition of atomic hydrogen from the (p) energy level to the (p+1) energy level given by
$$27.21 eV + 2 H [ \frac{{a}_{H}}{1} ] + H [ \frac{{a}_{H}}{p} ] -> 2 {H}^{+} + 2 {e}^{-} + H [ \frac{{a}_{H}}{( p + 1 )} ] + [ {( p + 1 )}^{2} - {p}^{2} ] \times 13.6 eV$$
$$2 {H}^{+} + 2 {e}^{-} -> 2 H [ \frac{{a}_{H}}{1} ] + 27.21 eV$$
And, the overall reaction is
$$H [ \frac{{a}_{H}}{p} ] -> H [ \frac{{a}_{H}}{( p + 1 )} ] + [ {( p + 1 )}^{2} - p ] \times 13.6 eV$$

88. A reactor of claim 1 wherein the catalyst comprises a catalytic disproportionation reaction of atomic hydrogen wherein lower-energy hydrogen atoms, hydrinos, can act as catalysts because each of the metastable excitation, resonance excitation, and ionization energy of a hydrino atom is m×27.2 eV.

89. A reactor of claim 88 wherein a first hydrino atom to a lower energy state affected by a second hydrino atom involves the resonant coupling between the atoms of m degenerate multipoles each having 27.21 eV of potential energy.

90. A reactor of claim 88 wherein the energy transfer of m×27.2 eV from the first hydrino atom to the second hydrino atom causes the central field of the first atom to increase by m and its electron to drop m levels lower from a radius of
$$\frac{{a}_{H}}{p}$$
to a radius of
$$\frac{{a}_{H}}{p + m} .$$

91. A reactor of claim 88 wherein the second interacting lower-energy hydrogen is either excited to a metastable state, excited to a resonance state, or ionized by the resonant energy transfer.

92. A reactor of claim 88 wherein the resonant transfer may occur in multiple stages.

93. A reactor of claim 92 wherein a nonradiative transfer by multipole coupling may occur wherein the central field of the first increases by m, then the electron of the first drops m levels lower from a radius of
$$\frac{{a}_{H}}{p}$$
to a radius of
$$\frac{{a}_{H}}{p + m}$$
with further resonant energy transfer.

94. A reactor of claim 88 wherein the energy transferred by multipole coupling may occur by a mechanism that is analogous to photon absorption involving an excitation to a virtual level.

95. A reactor of claim 88 wherein the energy transferred by multipole coupling during the electron transition of the first hydrino atom may occur by a mechanism that is analogous to two photon absorption involving a first excitation to a virtual level and a second excitation to a resonant or continuum level.

96. A reactor of claim 1 wherein a catalytic reaction with hydrino catalysts for the transition of
$$H [ \frac{{a}_{H}}{p} ] to H [ \frac{{a}_{H}}{p + m} ]$$
induced by a multipole resonance transfer of m·27.21 eV and a transfer of [(p′)²−(p′−m′)²]×13.6 eV −m·27.2 eV with a resonance state of
$$H [ \frac{{a}_{H}}{{p}^{′} - {m}^{′}} ]$$
excited in
$$H [ \frac{{a}_{H}}{{p}^{′}} ]$$
is represented by
$$H [ \frac{{a}_{H}}{{p}^{′}} ] + H [ \frac{{a}_{H}}{p} ] -> \\ H [ \frac{{a}_{H}}{{p}^{′} - {m}^{′}} ] + H [ \frac{{a}_{H}}{p + m} ] + [ ( {( p + m )}^{2} - {p}^{2} ) - ( {p}^{′2} - {( {p}^{′} - {m}^{′} )}^{2} ) ] X13 .6 eV$$
where p, p′, m, and m′ are integers.

97. A reactor according to claim 1 wherein a catalytic reaction with hydrino catalysts wherein a hydrino atom with the initial lower-energy state quantum number p and radius
$$\frac{{a}_{H}}{p}$$
may undergo a transition to the state with lower-energy state quantum number (p+m) and radius
$$\frac{{a}_{H}}{( p + m )}$$
by reaction with a hydrino atom with the initial lower-energy state quantum number m′, initial radius
$$\frac{{a}_{H}}{{m}^{′}} ,$$
and final radius α_{H} that provides a net enthalpy of m·27.2±0.5 eV where m is an integer or m/2·27.2±0.5 eV where m is an integer greater than one.

98. A reactor of claim 97 wherein a catalytic reaction of hydrogen-type atom,
$$H [ \frac{{a}_{H}}{p} ] ,$$
with the hydrogen-type atom,
$$H [ \frac{{a}_{H}}{{m}^{′}} ] ,$$
that is ionized by the resonant energy transfer to cause a transition reaction is represented by
$$mX 27.21 eV + H [ \frac{{a}_{H}}{{m}^{′}} ] + H [ \frac{{a}_{H}}{p} ] -> \\ {H}^{+} + {ⅇ}^{-} + H [ \frac{{a}_{H}}{( p + m )} ] + [ {( p + m )}^{2} - {p}^{2} - ( {m}^{′2} - 2 m ) ] X13 .6 eV$$
$${H}^{+} + {ⅇ}^{-} -> H [ \frac{{a}_{H}}{1} ] + 13.6 eV$$
And, the overall reaction is
$$H [ \frac{{a}_{H}}{{m}^{′}} ] + H [ \frac{{a}_{H}}{p} ] -> \\ H [ \frac{{a}_{H}}{1} ] + H [ \frac{{a}_{H}}{( p + m )} ] + [ 2 pm + {m}^{2} - {m}^{′2} ] X13 .6 eV + 13.6 eV$$

99. A reactor of claim 1 wherein the catalyst comprises a mixture of a first catalyst and a source of a second catalyst.

100. A reactor of claim 99 wherein the first catalyst produces the second catalyst from the source of the second catalyst.

101. A reactor of claim 99 wherein the energy released by the catalysis of hydrogen by the first catalyst produces a plasma in the energy cell.

102. A reactor of claim 99 wherein the energy released by the catalysis of hydrogen by the first catalyst ionizes the source of the second catalyst to produce the second catalyst.

103. A reactor of claim 102 wherein the second catalyst is selected from the group of helium, neon, argon, water vapor, or ammonia and the second catalyst of claim 11 is selected from the group of He⁺, Ne⁺, Ar⁺, O₂, and N₂ wherein the catalyst ion is generated from the corresponding atom by a plasma created by catalysis of hydrogen by the first catalyst.

104. A reactor of claim 1 wherein the cell comprises at least on of the group of an rt-plasma cell and a plasma electrolysis reactor, a barrier electrode reactor, an RF plasma reactor, a pressurized gas energy reactor, a gas discharge energy reactor, a microwave cell energy reactor, and a combination of a glow discharge cell and a microwave and or RF plasma reactor.

105. A reactor of claim 1 comprising a vessel having a chamber capable of containing a vacuum or pressures greater than atmospheric, a source of atomic hydrogen comprising a means to dissociate molecular hydrogen to atomic hydrogen, and a means to heat the source of catalyst capable of providing a net enthalpy of m·27.2±0.5 eV where m is an integer or m/2·27.2±0.5 eV where m is an integer greater than one.

106. A reactor of claim 1 wherein a plasma forming energy cell for the catalysis of atomic hydrogen to form novel hydrogen species and compositions of matter comprising new forms of hydrogen, a catalyst, a source of atomic hydrogen, and a source of carbon.

107. A reactor of claim 1 further comprising a hydrogen dissociator.

108. A reactor of claim 107 wherein the hydrogen dissociator comprises a filament.

109. A reactor of claim 108 wherein the filament comprises a tungsten filament.

110. A reactor of claim 1 wherein the filament also comprises a heater to heat the catalyst to form a gaseous catalyst.

111. A reactor of claim 110 wherein the catalyst comprises at least one of potassium, rubidium, cesium and strontium metal, nitrate, or carbonate.

112. A reactor of claim 1 further comprising a hydrogen supply tube and a hydrogen supply passage to supply hydrogen gas to the vessel.

113. A reactor of claim 1 further comprising a hydrogen flow of hydrogen flow controller and valve to control the flow of hydrogen to the chamber.

114. A reactor of claim 1 comprising a plasma gas, a plasma gas supply, and a plasma gas passage.

115. A reactor of claim 1 comprising lines, valves, and flow regulators such that the plasma gas flows from the plasma gas supply via the plasma gas passage into the vessel.

116. A reactor of claim 1 wherein a plasma gas flow controller and control valve control the flow of plasma gas into the vessel.

117. A reactor of claim 1 further comprising a hydrogen-plasma-gas mixer and mixture flow regulator.

118. A reactor of claim 1 further comprising a hydrogen-plasma-gas mixture, a hydrogen-plasma-gas mixer, and a mixture flow regulator which control the composition of the mixture and the its flow into the vessel.

119. A reactor of claim 1 further comprising a passage for the flow of the hydrogen-plasma-gas mixture into the vessel.

120. A reactor of claim 119, wherein the plasma gas comprises at least one of the group of helium, neon, argon, water vapor, or ammonia.

121. A reactor of claim 119 wherein the plasma gas is a source of the catalyst selected from the group of He⁺, Ne⁺, Ar⁺, O₂, and N₂.

122. A reactor of claim 1 wherein the plasma gas is a source of catalyst and the hydrogen-plasma-gas mixture flows into the plasma and becomes catalyst and atomic hydrogen in the vessel.

123. A reactor of claim 1 further comprising a vacuum pump and vacuum lines in communication with the vessel for evacuating the vessel.

124. A reactor of claim 1 further comprising a gas flow means to provide that the reactor is operated under flow conditions with the hydrogen and the catalyst supplied continuously from the catalyst source and the hydrogen source.

125. A reactor of claim 1 further comprising a catalyst reservoir and a catalyst supply passage for the passage of the gaseous catalyst from the reservoir to the vessel.

126. A reactor of claim 1 further comprising a catalyst reservoir heater and a power supply to heat the catalyst in the catalyst reservoir to provide the gaseous catalyst.

127. A reactor of claim 126 wherein the catalyst reservoir heater comprises a temperature control means wherein the vapor pressure of the catalyst is controlled by controlling the temperature of the catalyst reservoir.

128. A reactor of claim 1 wherein the catalysts is one selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Sr⁺, Fe³⁺, Mo²⁺, Mo⁴⁺, and In³⁺.

129. A reactor of claim 1 further comprising a chemically resistant open container such as a ceramic boat located inside the vessel which contains the catalyst.

130. A reactor of claim 1 further comprising a heater to maintain an elevated cell temperature such that the catalyst in the boat is sublimed, boiled, or volatilized into the gas phase.

131. A reactor of claim 130 wherein the catalyst boat further comprising a boat heater, and a power supply that heats the catalyst in the catalyst boat to provide the gaseous catalyst to the vessel.

132. A reactor of claim 131 wherein the catalyst boat heater comprises a temperature control means wherein the vapor pressure of the catalyst is controlled by controlling the temperature of the catalyst boat.

133. A reactor of claim 1 wherein the catalysts is one selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Sr⁺, Fe³⁺, Mo²⁺, Mo⁴⁺, and In³⁺.

134. A reactor of claim 1 further comprising a lower-energy hydrogen species and lower-energy hydrogen compound trap.

135. A reactor of claim 1 further comprising a vacuum pump in communication with the trap to cause a pressure gradient from the vessel to the trap to cause gas flow and transport of the lower-energy hydrogen species or lower-energy hydrogen compound.

136. A reactor of claim 1 further comprising a passage from the vessel to the trap and a vacuum line from the trap to the pump, and further comprising valves to and from the trap.

137. A reactor of claim 1 wherein the vessel comprises a stainless steel alloy cell, a molybdenum cell, a tungsten cell, a glass, quartz, or ceramic cell.

138. A reactor of claim 1 further comprising at least on of the group of an aspirator, atomizer, or nebulizer to form an aerosol of the source of catalyst.

139. A reactor of claim 1 wherein the aspirator, atomizer, or nebulizer injects the source of catalyst or catalyst directly into the plasma.

140. A reactor of claim 1 further comprising a plasma gas and a catalyst that is agitated from a source and supplied to the vessel through a flowing gas stream.

141. A reactor of claim 140 wherein the flowing gas stream comprises hydrogen gas or plasma gas which may be an additional source of catalyst.

142. A reactor of claim 141 wherein the additional source of catalyst comprises helium, neon, argon, water vapor, or ammonia.

143. A reactor of claim 1 wherein the catalyst is dissolved or suspended in a liquid medium such as water and solution or suspension is aerosolized.

144. A reactor of claim 143 wherein the medium is contained in the catalyst reservoir.

145. A reactor of claim 143 wherein the solution or suspension containing catalyst is transported to the vessel by a carrier gas.

146. A reactor of claim 145 wherein the carrier gas comprises at least one of the group of hydrogen, helium, neon, argon, water vapor, or ammonia.

147. A reactor of claim 145 wherein the carrier gas comprises at least one of the group of helium, neon, argon, water vapor, or ammonia which serves as a source of catalyst and is ionized by the plasma to form at least one of the catalysts He⁺, Ne⁺, and Ar⁺ or decomposed to form at least one of the catalysts O₂ and N₂.

148. A reactor of claim 1 wherein the nonthermal plasma temperature is maintained in the range of 5,000-5,000,000° C.

149. A reactor of claim 1 wherein the cell temperature is maintained above that of the catalyst reservoir which serves as a controllable source of catalyst.

150. A reactor of claim 1 wherein the cell temperature is maintained above that of the catalyst boat which serves as a controllable source of catalyst.

151. A reactor of claim 1 wherein a stainless steel alloy cell is preferably maintained in the temperature range of 0-1200° C.

152. A reactor of claim 1 wherein a molybdenum cell is preferably maintained in the temperature range of 0-1800° C.

153. A reactor of claim 1 wherein a tungsten cell is preferably maintained in the temperature range of 0-3000° C.

154. A reactor of claim 1 wherein a glass, quartz, or ceramic cell is preferably maintained in the temperature range of 0-1800° C.

155. A reactor of claim 1 wherein molecular and atomic hydrogen partial pressures in the vessel is maintained in the range of 1 mtorr to 100 atm.

156. A reactor of claim 1 wherein molecular and atomic hydrogen partial pressures in the vessel is maintained in the range of 100 mtorr to 20 torr.

157. A reactor of claim 1 wherein catalyst partial pressure in the vessel is maintained in the range of 1 mtorr to 100 atm.

158. A reactor of claim 1 wherein the catalyst partial pressure in the vessel is maintained in the range of 100 mtorr to 20 torr.

159. A reactor of claim 1 wherein the flow rate of the plasma gas is 0-1 standard liters per minute per cm³ of vessel volume.

160. A reactor of claim 1 wherein the flow rate of the plasma gas is 0.001-10 sccm per cm³ of vessel volume.

161. A reactor of claim 1 wherein the flow rate of the hydrogen gas is 0-1 standard liters per minute per cm³ of vessel volume.

162. A reactor of claim 1 wherein the flow rate of the hydrogen gas is 0.001-10 sccm per cm³ of vessel volume.

163. A reactor of claim 122 wherein the hydrogen-plasma-gas mixture comprises one selected from helium, neon, and argon comprising a composition of the plasma gas in the range of 99 to 1%.

164. A reactor of claim 122 wherein the hydrogen-plasma-gas mixture comprises one selected from helium, neon, and argon comprising a composition of the plasma gas in the range of 99 to 95%.

165. A reactor of claim 122 wherein the flow rate of the hydrogen-plasma-gas mixture is 0-1 standard liters per minute per cm³ of vessel volume.

166. A reactor of claim 122 wherein the flow rate of the hydrogen-plasma-gas mixture is 0.001-10 sccm per cm³ of vessel volume.

167. A reactor of claim 1 further comprising a selective valve for removal of lower-energy hydrogen products.

168. A reactor of claim 167 wherein the selectively removed lower-energy hydrogen products comprise dihydrino molecules.

169. A reactor of claim 1 further comprising a cold wall or cryotrap to which at least one of increased binding energy hydrogen compounds and dihydrino gas are cryopumped.

170. A reactor of claim 1 comprising at least one of the group of an rt-plasma cell and a plasma electrolysis reactor, a barrier electrode reactor, an RF plasma reactor, a pressurized gas energy reactor, a gas discharge energy reactor, a microwave cell energy reactor, and a combination of a glow discharge cell and a microwave and or RF plasma reactor wherein the power supplied to the cell is pulsed or intermittent.

171. A reactor of claim 170 wherein the frequency of alternating power may be within the range of about 0.001 Hz to 100 GHz.

172. A reactor of claim 170 wherein the frequency of alternating power may be within the range of about 60 Hz to 10 GHz

173. A reactor of claim 170 wherein the frequency of alternating power may be within the range of about 10 MHz to 10 GHz.

174. A reactor of claim 170 that comprises two electrodes wherein one or more electrodes are at least one of in direct contact with the plasma and the electrodes may be separated from the plasma by a dielectric barrier wherein the peak voltage may be within the range of about 1 V to 10 MV.

175. A reactor of claim 170 that comprises two electrodes wherein one or more electrodes are at least one of in direct contact with the plasma and the electrodes may be separated from the plasma by a dielectric barrier wherein the peak voltage may be within the range of about 10 V to 100 kV.

176. A reactor of claim 170 that comprises two electrodes wherein one or more electrodes are at least one of in direct contact with the plasma and the electrodes may be separated from the plasma by a dielectric barrier wherein the peak voltage may be within the range of about 100 V to 500 V.

177. A reactor of claim 170 that comprises at least one antenna to deliver power to the plasma.

178. A reactor of claim 1 wherein the cell comprises a glow discharge cell comprising a vessel having a chamber capable of containing a vacuum or pressures greater than atmospheric, a source of atomic hydrogen, a cathode, an anode, a discharge power source to produce a glow discharge plasma, a source of atomic hydrogen, a source of catalyst, and a vacuum pump.

179. A reactor of claim 178 wherein the discharge current is intermittent or pulsed.

180. A reactor of claim 179 wherein an offset voltage is between 0.5 and 500 V or the offset voltage is set to provide a field between 1 V/cm to 10 V/cm.

181. A reactor of claim 179 wherein the pulse frequency is between 0.1 Hz and 100 MHz and a duty cycle is between 0.1% and 95%.

182. A reactor of claim 178 wherein the cathode comprises a hollow cathode comprising a compound electrode comprising multiple electrodes in series or parallel that may occupy a substantial portion of the volume of the reactor.

183. A reactor of claim 182 wherein the compound electrode comprises multiple hollow cathodes in parallel so that a desired electric field is produced in a large volume to generate a substantial power level.

184. A reactor of claim 183 wherein the compound electrode comprises an anode and at least one of the group of multiple concentric hollow cathodes each electrically isolated from the common anode and multiple parallel plate electrodes connected in series.

185. A reactor of claim 178 wherein the discharge voltage is at least one of within the range of about 1000 to about 50,000 volts and the current is at least one of within the range of about 1 μA to about 1 A and about 1 mA.

186. A rector of claim 178 wherein the power is applied as an alternating current (AC).

187. A reactor of claim 186 wherein the frequency is at least within the range of about 0.001 Hz to 1 GHz.

188. A reactor of claim 186 wherein the frequency is at least within the range of about 60 Hz to 100 MHz.

189. A reactor of claim 186 wherein the frequency is at least within the range of about 10 to 100 MHz.

190. A reactor of claim 186 comprising two electrodes wherein one or more electrodes are in direct contact with the plasma.

191. A reactor of claim 190 wherein the peak voltage is within the range of about 1 V to 10 MV.

192. A reactor of claim 190 wherein the peak voltage is within the range of about 10 V to 100 kV.

193. A reactor of claim 190 wherein the peak voltage is within the range of about 100 V to 500 V.

194. A reactor of claim 179 comprising an intermittent or pulsed current wherein the offset voltage is at least one of within the range of about 0.5 to about 500 V, is set to provide a field of about 0.1 V/cm to about 50 V/cm, and is set to provide a field between about 1 V/cm to about 10 V/cm; the peak voltage is within the range of about 1 V to 10 MV, preferably about 10 V to 100 kV, and more preferably about 100 V to 500 V; the pulse frequency is within the range of about 1 to about 200 Hz, and the duty cycle is at least one of within the range of about 0.1% to about 95% and about 1% to about 50%.

195. A reactor of claim 1 wherein the cell comprises a microwave plasma forming gas cell comprising a vessel having a chamber capable of containing a vacuum or pressures greater than atmospheric, a source of atomic hydrogen comprising plasma dissociation of molecular hydrogen, a source of microwave power, and a source of catalyst capable of providing a net enthalpy of m·21.2±0.5 eV where m is an integer or m/2·27.2±0.5 eV where m is an integer greater than one.

196. A reactor of claim 195 wherein the source of microwave power is a microwave generator, a tunable microwave cavity, waveguide, and a RF transparent window.

197. A reactor of claim 195 wherein the source of microwave power is a microwave generator, a tunable microwave cavity, waveguide, and an antenna.

198. A reactor of claim 195 wherein the microwaves are tuned by a tunable microwave cavity, carried by waveguide, and are delivered to the vessel though the RF transparent window.

199. A reactor of claim 195 wherein the microwaves are timed by a tunable microwave cavity, carried by waveguide, and are delivered to the vessel though the antenna.

200. A reactor of claim 196 wherein the waveguide is either inside or outside of the cell.

201. A reactor of claim 196 wherein the antenna is either inside or outside of the cell.

202. A reactor of claim 196 wherein the microwave generator comprises at least one of the group of traveling wave tubes, klystrons, magnetrons, cyclotron resonance masers, gyrotrons, and free electron lasers.

203. A reactor of claim 197 wherein the microwave window comprises an Alumina or quartz window.

204. A reactor of claim 195 wherein the vessel is a microwave resonator cavity.

205. A reactor of claim 195 wherein the cavity is at least one of the group of Evenson, Beenakker, McCarrol, and cylindrical cavity.

206. A reactor of claim 195 comprising a vessel comprising a cavity that is a reentrant microwave cavity and the source of microwave power that excites a plasma in the reentrant cavity.

207. A reactor of claim 206 wherein the reentrant cavity is an Evenson microwave cavity.

208. A reactor of claim 206 wherein the microwave frequency of the source of microwave power is selected to efficiently form atomic hydrogen from molecular hydrogen.

209. A reactor of claim 143 wherein the microwave frequency of the source of microwave power is selected to efficiently form ions that serve as catalysts from a source of catalyst.

210. A reactor of claim 209 wherein the source of catalyst and catalyst comprise at least one of helium, neon, argon, water vapor, and ammonia, and at least one of He⁺, Ne⁺, Ar⁺, O₂ and N₂, respectively.

211. A reactor of claim 143 wherein the microwave frequency of the source of microwave power is in the range of 1 MHz to 100 GHz.

212. A reactor of claim 195 wherein the microwave frequency of the source of microwave power is in the range of 50 MHz to 10 GHz.

213. A reactor of claim 195 wherein the microwave frequency of the source of microwave power is in the range of 75 MHz±50 MHz.

214. A reactor of claim 195 wherein the microwave frequency of the source of microwave power is in the range of 2.4 GHz±1 GHz.

215. A reactor of claim 1 and 195 wherein the catalyst is atomic hydrogen wherein the hydrogen pressure of the hydrogen microwave plasma is within the range of about 1 mtorr to about 100 atm, preferably about 100 mtorr to about 1 atm, and more preferably about 100 m torr to about 10 torr; the microwave power density is within at least one of the range of about 0.01 W to about 100 W/cm³ vessel volume, and the hydrogen flow rate is within at least one of the range of about 0-1 standard liters per minute per cm³ of vessel volume and about 0.001-10 sccm per cm³ of vessel volume.

216. A reactor of claim 195 wherein the power density of the source of plasma power is 0.01 W to 100 W/cm³ vessel volume.

217. A reactor of claim 195 wherein the cell is a microwave resonator cavity.

218. A reactor of claim 195 wherein the source of microwave supplies sufficient microwave power density to the cell to ionize a source of catalyst to form the catalyst.

219. A reactor of claim 218 wherein the source of catalyst comprises as at least one of helium, neon, argon, water vapor, or ammonia to form a catalyst such as He⁺, Ne⁺, Ar⁺, O₂, and N₂, respectively.

220. A reactor of claim 195 wherein the microwave power source forms a nonthermal plasma.

221. A reactor of claim 220 wherein the microwave power source or applicator is an antenna, waveguide, or cavity.

222. A reactor of claim 220 wherein the microwave power source forms a nonthermal plasma.

223. A reactor of claim 221 wherein the microwave power source or applicator is an antenna, waveguide, or cavity.

224. A reactor of claim 223 wherein the species corresponding to the source of catalyst have a higher temperature than that at thermal equilibrium.

225. A reactor of claim 224 wherein the source of catalyst comprises at least one selected from the group of helium, neon, and argon atoms.

226. A reactor of claim 225 wherein higher energy states such as ionized states of the source of catalyst are predominant over that of hydrogen compared to a corresponding thermal plasma wherein excited states of hydrogen are predominant.

227. A reactor of claim 195 comprising a plurality of sources of microwave power.

228. A reactor of claim 227 wherein the plurality of microwave sources are used simultaneously.

229. A reactor of claim 227 wherein the plurality of microwave sources comprise Evenson cavities.

230. A reactor of claim 195 that form a nonthermal plasma maintained by multiple Evenson cavities operated in parallel.

231. A reactor of claim 230 that is cylindrical and comprises a quartz cell with Evenson cavities spaced along the longitudinal axis.

232. A reactor of claim 195 wherein the microwave power is pulsed.

233. A reactor of claim 232 wherein the frequency of the alternating power is within the range of about 100 MHz to 100 GHz, preferably about 100 MHz to 10 GHz, more preferably 1 GHz to 10 GHz and most preferably about 2.4 GHz±1 GHz; the pulse frequency is within the range of about 0.1 Hz to about 100 MHz, preferably about 10 to about 10,000 Hz, and more preferably about 100 to about 1000 Hz; the duty cycle is within the range of about 0.001% to about 95%, preferably 0.1% to 10%; the peak power density of the pulses into the plasma is within the range of about 1 W/cm³ to 1 GW/cm³, preferably about 10 W/cm³ to 10 MW/cm³, and more preferably about 100 W/cm³ to 10 kW/cm³, and the average power density into the plasma is within the range of about 0.001 W/cm³ to 1 kW/cm³, preferably about 0.1 W/cm³ to 100 W/cm³, and more preferably about 1 W/cm³ to 10 W/cm³.

234. A reactor of claim 232 wherein the source microwaves comprise at least one from the group of traveling wave tubes, klystrons, magnetrons, cyclotron resonance masers, gyrotrons, and free electron lasers.

235. A reactor of claim 232 wherein the power is amplified with an amplifier.

236. A reactor of claim 232 wherein the pulsed microwaves power source comprises at least one of a magnetron with a pulsed high voltage to the magnetron and a pulsed magnetron current that may be supplied by a pulse of electrons from an electron source such as an electron gun.

237. A reactor of claim 1 comprising an RF plasma forming gas cell comprising a vessel, a source of atomic hydrogen from RF plasma dissociation of molecular hydrogen, a source of RF power, and a catalyst capable of providing a net enthalpy of m·27.2±0.5 eV where m is an integer or m/2·27.2±0.5 eV where m is an integer greater than one.

238. A reactor of claim 237 wherein the RF power is capacitively or inductively coupled to the cell.

239. A reactor of claim 237 comprising two electrodes.

240. A reactor of claim 239 comprising a coaxial cable connected to the a powered electrode by a coaxial center conductor.

241. A reactor of claim 237 comprising a coaxial center conductor connected to an external source coil which is wrapped around the cell.

242. A reactor of claim 241 wherein the coaxial center conductor connected to an external source coil which is wrapped around the cell terminates without a connection to ground.

243. A reactor of claim 241 wherein the coaxial center conductor connected to an external source coil which is wrapped around the cell is connect to ground.

244. A reactor of claim 239 comprising two electrodes wherein the electrodes are parallel plates.

245. A reactor of claim 244 wherein the one of the parallel plate electrodes is powered and the other is connected to ground.

246. A reactor of claim 237 wherein the cell comprises a Gaseous Electronics Conference (GEC) Reference Cell or modification thereof.

247. A reactor of claim 237 wherein the RF power is at 13.56 MHz

248. A reactor of claim 239 wherein at least one wall of the cell wrapped with the external coil is at least partially transparent to the RF excitation.

249. A reactor of claim 237 wherein the RF frequency is preferably in the range of about 100 Hz to about 100 GHz.

250. A reactor of claim 237 wherein the RF frequency is preferably in the range of about 1 kHz to about 100 MHz.

251. A reactor of claim 237 wherein the RF frequency is preferably in the range of about 13.56 MHz±50 MHz or about 2.4 GHz±1 GHz.

252. A reactor of claim 1 comprising an inductively coupled toroidal plasma cell comprising a vessel, a source of atomic hydrogen comprising RF plasma dissociation of molecular hydrogen, a source of RF power, and a catalyst capable of providing a net enthalpy of m·27.2±0.5 eV where m is an integer or m/2·27.2±0.5 eV where m is an integer greater than one.

253. A reactor of claim 252 comprising the Astron system of Astex Corporation described in U.S. Pat. No. 6,150,628.

254. A reactor of claim 252 comprising a primary of a transformer circuit.

255. A reactor of claim 252 comprising a primary of a transformer circuit driven by a radio frequency power supply.

256. A reactor of claim 252 comprising a primary of a transformer circuit wherein the plasma is a closed loop which acts at as a secondary of the transformer circuit.

257. A reactor of claim 252 wherein the RF frequency is in the range of about 100 Hz to about 100 GHz.

258. A reactor of claim 252 wherein the RF frequency is in the range of about 1 kHz to about 100 MHz.

259. A reactor of claim 252 wherein the RF frequency is in the range of about 13.56 MHz 50 MHz or about 2.4 GHz±1 GHz.

260. A reactor of claims 252 wherein the frequency of the RF power is within the range of about 100 MHz to 100 GHz, preferably about 100 MHz to 10 GHz, more preferably 1 GHz to 10 GHz and most preferably about 2.4 GHz±1 GHz; the pulse frequency is within the range of about 0.1 Hz to about 100 MHz, preferably about 10 to about 10,000 Hz, and more preferably about 100 to about 1000 Hz; the duty cycle is within the range of about 0.001% to about 95%, preferably 0.1% to 10%; the peak power density of the pulses into the plasma is within the range of about 1 W/cm³ to 1 GW/cm³, preferably about 10 W/cm³ to 10 MW/cm³, and more preferably about 100 W/cm³ to 10 kW/cm³, and the average power density into the plasma is within the range of about 0.001 W/cm³ to 1 kW/cm³, preferably about 0.1 W/cm³ to 100 W/cm³, and more preferably about 1 W/cm³ to 10 W/cm³.

261. A reactor of claim 1 wherein the cell comprises a plasma forming electrolytic cell comprising a vessel, a cathode, an anode, an electrolyte, a high voltage electrolysis power supply, and a catalyst capable of providing a net enthalpy of m·27.2±0.5 eV where m is an integer or m/2·27.2±0.5 eV where m is an integer greater than one.

262. A reactor of claim 261 wherein the voltage is in the range 10-50 kV and the current density in the range of 1 to 100 A/cm².

263. A reactor of claim 261 wherein the cathode is tungsten.

264. A reactor of claim 261 wherein the anode is platinum.

265. A reactor of claim 261 wherein the catalyst comprises at least one selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Sr⁺, Fe³⁺, Mo²⁺, Mo⁴⁺, and In³⁺.

266. A reactor of claim 261 wherein the catalyst is formed from a source of catalyst.

267. A reactor of claim 266 wherein the source of catalyst which forms the catalyst comprising at least one selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Sr⁺, Fe³⁺, Mo²⁺, Mo⁴⁺, In³⁺ and K⁺/K⁺.

268. A reactor of claim 261 wherein the plasma electrolysis discharge voltage within the range of about 1000 to about 50,000 volts; the current into the electrolyte is within the range of about 1 μA/cm³ to about 1 A/cm³, preferably about 1 mA/cm³; the offset voltage is below that which causes electrolysis such as within the range of about 0.001 to about 1.4 V; the peak voltage at least one of within the range of about 1 V to 10 MV, preferably about 2 V to 100 kV, and more preferably about 2 V to 1 kV; the pulse frequency is within the range of about 0.1 Hz to about 100 MHz, preferably about 1 to about 200 Hz, and the duty cycle is within the range of about 0.1% to about 95%, preferably about 1% to about 50%.

269. A reactor of claim 1 wherein the cell comprises a radio frequency (RF) barrier electrode discharge cell comprising a vessel, a source of atomic hydrogen from the RF plasma dissociation of molecular hydrogen, a source of RF power, a cathode, an anode, and a catalyst capable of providing a net enthalpy of m·27.2±0.5 eV where m is an integer or m/2·27.2±0.5 eV where m is an integer greater than one.

270. A reactor of claim 269 wherein at least one of the cathode and the anode is shielded by a dielectric barrier.

271. A reactor of claim 270 wherein the dielectric barrier comprises at least one of the group of glass, quartz, Alumina, and ceramic.

272. A reactor of claim 269 wherein the RF power may be capacitively coupled to the cell.

273. A reactor of claim 269 wherein the electrodes are external to the cell.

274. A reactor of claim 270 wherein a dielectric layer separates the electrodes from the cell wall.

275. A reactor of claim 269 wherein the high driving voltage may be AC and may be high frequency.

276. A reactor of claim 269 wherein the RF source of power comprises a driving circuit comprising a high voltage power source which is capable of providing RF and an impedance matching circuit.

277. A reactor of claim 269 wherein the frequency is in the range 100 Hz to 10 GHz.

278. A reactor of claim 269 wherein the frequency is in the range 1 kHz to 1 MHz.

279. A reactor of claim 269 wherein the frequency is in the range 5-10 kHz.

280. A reactor of claim 269 wherein the voltage is in the range 100 V to 1 MV.

281. A reactor of claim 269 wherein the voltage is in the range 1 kV to 100 kV.

282. A reactor of claim 269 wherein the voltage is in the range 5 to 10 kV.

283. A reactor of claim 269 wherein the frequency is within the range of about 100 Hz to about 10 GHz, preferably 1 kHz to about 1 MHz, more preferably about 5-10 kHz; and the voltage is within the range of about 100 V to about 1 MV, preferably about 1 kV to about 100 kV, more preferably about 5 to about 10 kV.
